(19) United States
(12) Patent Application Publication
(10) Pub. No.: US 2026/0253621 A1
(43) Pub. Date: Aug. 27, 2026

(54) THREE-DIMENSIONAL MEMORY DEVICE CONTAINING DIELECTRIC STRUCTURAL SUPPORT ELEMENTS BETWEEN DIELECTRIC WALL STRUCTURES AND METHODS FOR FORMING THE SAME

(71) Applicant: Sandisk Technologies, Inc., Milpitas, CA (US)

(72) Inventors: Akihiro TOBIOKA, Yokkaichi (JP); Kota FUNAYAMA, Yokkaichi (JP); Koichi MATSUNO, Fremont, CA (US)

(21) Appl. No.: 19/064,464

(22) Filed: Feb. 26, 2025

(51) Int. Cl. G11C 5/06; G11C 16/04; H10B 41/10; H10B 41/27; H10B 41/35; H10B 43/10; H10B 43/27; H10B 43/35

(52) U.S. Cl. CPC G11C 5/063; G11C 16/0483; H10B 41/10; H10B 41/27; H10B 41/35; H10B 43/10; H10B 43/27; H10B 43/35

(57) ABSTRACT

A semiconductor structure includes multi-tier layer stacks laterally spaced apart by lateral isolation structures. Each multi-tier layer stack includes a first-tier alternating stack of first insulating layers and first electrically conductive layers, and a second-tier alternating stack of second insulating layers and second electrically conductive layers overlying the first-tier alternating stack. The semiconductor structure also includes a first memory array region and a second memory array region laterally spaced apart by an inter-array region. Memory opening fill structures vertically extend through the multi-tier layer stacks in the memory array regions. One of the lateral isolation structures may include a combination of a dielectric wall structure and at least one second-tier dielectric pillar structure. Alternatively, one of the lateral isolation structures may include a combination of dielectric wall structures, a first-tier retro-stepped dielectric material portion, and a second-tier dielectric material portion.

### FIELD

The present disclosure generally relates to the field of semiconductor devices, and particularly to a three-dimensional memory device containing lateral isolation structures with dielectric structural support elements located between dielectric wall structures and methods for forming the same.

### BACKGROUND

A three-dimensional memory device includes vertical NAND strings which extend through an alternating stacks of word lines and insulating layers.

### SUMMARY

According to an aspect of the present disclosure, a semiconductor structure comprises: multi-tier layer stacks laterally extending along a first horizontal direction and laterally spaced apart from each other along a second horizontal direction by lateral isolation structures, wherein each of the multi-tier layer stacks comprises a first-tier alternating stack of first insulating layers and first electrically conductive layers, and further comprises a second-tier alternating stack of second insulating layers and second electrically conductive layers that overlies the first-tier alternating stack, wherein the semiconductor structure comprises a first memory array region and a second memory array region that are laterally spaced apart from each other along the first horizontal direction by an inter-array region, wherein all layers within of the multi-tier layer stacks are present in the first memory array region and in the second memory array region, and wherein each of the multi-tier layer stacks comprises a respective set of stepped surfaces in the inter-array region; memory openings vertically extending through a respective one of the multi-tier layer stacks and located in a respective one of the first memory array region and the second memory array region; and memory opening fill structures located in a respective one of the memory openings and comprising a vertical semiconductor channel and respective vertical stack of memory elements. A first lateral isolation structure of the lateral isolation structures comprises a combination of a dielectric wall structure and at least one second-tier dielectric material portion; the dielectric wall structure comprises at least one second-tier lateral gap at a second-tier level of the second-tier alternating stacks; each of the at least one second-tier dielectric material portions is located in a respective second-tier lateral gap of the at least one second-tier lateral gaps; and the first lateral isolation structure comprises a continuous dielectric barrier that extends continuously from the first memory array region to the second memory array region through the inter-array region.

According to another aspect of the present disclosure, a method of forming a semiconductor structure comprises: forming a first-tier structure comprising first-tier alternating stacks of first insulating layers and first sacrificial material layers, wherein the first-tier alternating stacks laterally extend along a first horizontal direction and are laterally spaced apart from each other by sacrificial first-tier wall structures; forming a second-tier structure comprising second-tier alternating stacks of second insulating layers and second sacrificial material layers over the first-tier structure, wherein the second-tier alternating stacks laterally extend along the first horizontal direction and are laterally spaced apart from each other by a plurality of sacrificial second-tier wall structures comprising at least one second-tier lateral gap therebetween and at least one second-tier dielectric pillar structure located within a respective one of the at least one second-tier lateral gap; forming memory openings in a first memory array region and in a second memory array region at least through a respective vertical stack of a respective one of the first-tier alternating stacks and through a respective one of the second-tier alternating stacks; forming memory opening fill structures in the memory openings, wherein each of the memory opening fill structures comprises a vertical semiconductor channel and a vertical stack of memory elements; forming lateral isolation trenches by removing at least the plurality of sacrificial second-tier wall structures and the sacrificial first-tier wall structure; and replacing remaining portions of the first sacrificial material layers and remaining portions of the second sacrificial material layers with first electrically conductive layers and second electrically conductive layers, respectively.

According to yet another aspect of the present disclosure, a semiconductor structure comprises: multi-tier layer stacks laterally extending along a first horizontal direction and laterally spaced apart from each other along a second horizontal direction by lateral isolation structures, wherein each of the multi-tier layer stacks comprises a first-tier alternating stack of first insulating layers and first electrically conductive layers, and further comprises a second-tier alternating stack of second insulating layers and second electrically conductive layers that overlies the first-tier alternating stack, wherein the semiconductor structure comprises a first memory array region and a second memory array region that are laterally spaced apart from each other along the first horizontal direction by an inter-array region, wherein all layers within each of the multi-tier layer stacks are present in the first memory array region and in the second memory array region, and wherein each of the multi-tier layer stacks comprises a respective set of stepped surfaces in the inter-array region; memory openings vertically extending through a respective one of the multi-tier layer stacks and located in a respective one of the first memory array region and the second memory array region; and memory opening fill structures located in a respective one of the memory openings and comprising a vertical semiconductor channel and respective vertical stack of memory elements. A first lateral isolation structure of the lateral isolation structures comprises a combination of a first dielectric wall structure, a second dielectric wall structure that is laterally spaced from the first dielectric wall structure by a first lateral gap, a first-tier retro-stepped dielectric material portion located at a first-tier level of the first-tier alternating stacks within the multi-tier layer stacks, and a second-tier retro-stepped dielectric material portion located at a second-tier level of the second-tier alternating stacks within the multi-tier layer stacks; the first-tier retro-stepped dielectric material portion comprises a first-tier staircase dielectric material sub-portion having a first stepped bottom surface and having first variable vertical extents that are less than a first height of the first-tier alternating stacks and further comprises a first-tier full-height dielectric material sub-portion having a same height as the first height of the first-tier alternating stacks and filling an entire volume of the first lateral gap; and the first lateral isolation structure comprises continuous dielectric barrier that extends continuously from the first memory array region to the second memory array region through the inter-array region.

According to still another aspect of the present disclosure, a method of forming a semiconductor structure comprises: forming a first-tier structure comprising first-tier alternating stacks of first insulating layers and first sacrificial material layers, wherein the first-tier alternating stacks laterally extend along a first horizontal direction and are laterally spaced apart from each other by first-tier lateral spacer structures, wherein each of the first first-tier lateral spacer structures comprises a combination of a first sacrificial first-tier wall structure, a second sacrificial first-tier wall structure that is laterally spaced from the first sacrificial first-tier wall structure by a first lateral gap, and a first-tier retro-stepped dielectric material portion which is in contact with the neighboring pair of first-tier alternating stacks and comprises a first-tier staircase dielectric material sub-portion having a first stepped bottom surface and having first variable vertical extents that are less than a first height of the first-tier structure and further comprises a first-tier full-height dielectric material sub-portion having a same height as the first height of the first-tier alternating stacks and filling an entire volume of the first lateral gap; forming a second-tier structure comprising second-tier alternating stacks of second insulating layers and second sacrificial material layers over the first-tier structure, wherein the second-tier alternating stacks laterally extend along the first horizontal direction and are laterally spaced apart from each other by second-tier lateral spacer structures, wherein each of the second-tier lateral spacer structures comprises a combination of a plurality of sacrificial second-tier wall structures and a second-tier retro-stepped dielectric material portion; forming memory openings in a first memory array region and in a second memory array region at least through a respective vertical stack of a respective one of the first-tier alternating stacks and through a respective one of the second-tier alternating stacks; forming memory opening fill structures in the memory openings, wherein each of the memory opening fill structures comprises a vertical semiconductor channel and a vertical stack of memory elements; forming lateral isolation trenches by removing at least the plurality of sacrificial second-tier wall structures, the first sacrificial first-tier wall structure, and the second sacrificial first-tier wall structure; and replacing remaining portions of the first sacrificial material layers and remaining portions of the second sacrificial material layers with first electrically conductive layers and second electrically conductive layers, respectively.

### BRIEF DESCRIPTION OF DRAWINGS

FIG. 1A is a vertical cross-sectional view of a first exemplary structure after formation of a first-tier vertically alternating sequence of first insulating layers and first sacrificial material layers and formation of first-tier stepped cavities according to an embodiment of the present disclosure. FIG. 1B is a top-down view of the first exemplary structure of FIG. 1A. The vertical plane A-A′ is the cut plane of FIG. 1A.

FIG. 2A-2C are sequential vertical cross-sectional views of a region of the first exemplary structure during thickening of physically-exposed portions of the first sacrificial material layers according to an embodiment of the present disclosure.

FIG. 3A-3E are sequential vertical cross-sectional views of a region of the first exemplary structure during a sequence of processing steps that may be employed to locally thicken the physically-exposed portions of the first sacrificial material layers according to an embodiment of the present disclosure.

FIG. 4 is a vertical cross-sectional view of the first exemplary structure after local thickening of the physically exposed portions of the first sacrificial material layers according to an embodiment of the present disclosure.

FIG. 5A a vertical cross-sectional view of the first exemplary structure after formation of first-tier retro-stepped dielectric material portions according to an embodiment of the present disclosure. FIG. 5B is a top-down view of the first exemplary structure of FIG. 5A. The vertical plane A-A′ in FIG. 5B is the cut plane of the vertical cross-sectional view of FIG. 5A. FIG. 5C is a vertical cross-sectional view of the first exemplary structure along the vertical plane C-C′ of FIG. 5B.

FIG. 6A is a vertical cross-sectional view of the first exemplary structure after formation of various first-tier openings and various sacrificial first-tier opening fill structures according to an embodiment of the present disclosure. FIG. 6B is a top-down view of the first exemplary structure of FIG. 6A. The vertical plane A-A′ in FIG. 6B is the cut plane of the vertical cross-sectional view of FIG. 6A. FIG. 6C is a vertical cross-sectional view of the first exemplary structure along the vertical plane C-C′ of FIG. 6B.

FIG. 7A is a vertical cross-sectional view of the first exemplary structure after formation of a second-tier vertically alternating sequence of second insulating layers and second sacrificial material layers, second-tier retro-stepped dielectric material portions, and second-tier dielectric pillar structures according to an embodiment of the present disclosure. FIG. 7B is a top-down view of the first exemplary structure of FIG. 7A. The vertical plane A-A′ in FIG. 7B is the cut plane of the vertical cross-sectional view of FIG. 7A. FIG. 7C is a vertical cross-sectional view of the first exemplary structure along the vertical plane C-C′ of FIG. 7B.

FIG. 8A is a vertical cross-sectional view of the first exemplary structure after formation of various second-tier openings and various sacrificial second-tier opening fill structures according to an embodiment of the present disclosure. FIG. 8B is a top-down view of the first exemplary structure of FIG. 8A. The vertical plane A-A′ in FIG. 8B is the cut plane of the vertical cross-sectional view of FIG. 8A. FIG. 8C is a vertical cross-sectional view of the first exemplary structure along the vertical plane C-C′ of FIG. 8B.

FIG. 9A is a vertical cross-sectional view of the first exemplary structure after formation of a third-tier vertically alternating sequence of third insulating layers and third sacrificial material layers, third-tier retro-stepped dielectric material portions, and third-tier dielectric pillar structures according to an embodiment of the present disclosure. FIG. 9B is a top-down view of the first exemplary structure of FIG. 9A. The vertical plane A-A′ in FIG. 9B is the cut plane of the vertical cross-sectional view of FIG. 9A. FIG. 9C is a vertical cross-sectional view of the first exemplary structure along the vertical plane C-C′ of FIG. 9B.

FIG. 10A is a vertical cross-sectional view of the first exemplary structure after formation of various third-tier openings and various sacrificial third-tier opening fill structures according to an embodiment of the present disclosure. FIG. 10B is a top-down view of the first exemplary structure of FIG. 10A. The vertical plane A-A′ in FIG. 10B is the cut plane of the vertical cross-sectional view of FIG. 10A. FIG. 10C is a vertical cross-sectional view of the first exemplary structure along the vertical plane C-C′ of FIG. 10B.

FIG. 11A is a vertical cross-sectional view of the first exemplary structure after formation of cavities in inter-tier memory openings according to an embodiment of the present disclosure. FIG. 11B is a top-down view of the first exemplary structure of FIG. 11A. The vertical plane A-A′ in FIG. 11B is the cut plane of the vertical cross-sectional view of FIG. 11A. FIG. 11C is a vertical cross-sectional view of the first exemplary structure along the vertical plane C-C′ of FIG. 11B.

FIG. 12A-12D illustrate sequential vertical cross-sectional views of a memory opening during formation of a memory opening fill structure according to an embodiment of the present disclosure.

FIG. 13A is vertical cross-sectional view of the first exemplary structure after formation of memory opening fill structures in each memory opening according to an embodiment of the present disclosure. FIG. 13B is a top-down view of the exemplary structure of FIG. 13A. The vertical plane A-A′ in FIG. 13B is the cut plane of the vertical cross-sectional view of FIG. 13A. FIG. 13C is a vertical cross-sectional view of the exemplary structure along the hinged vertical cut plane C-C′ in FIG. 13B.

FIG. 14 is a vertical cross-sectional view of the first exemplary structure after formation of cavities in support openings according to an embodiment of the present disclosure.

FIG. 15 is a vertical cross-sectional view of the first exemplary structure after formation of support pillar structures and a contact-level dielectric layer according to an embodiment of the present disclosure.

FIG. 16 is a vertical cross-sectional view of the first exemplary structure after formation of discrete openings through the contact-level dielectric layer according to an embodiment of the present disclosure.

FIG. 17 is a vertical cross-sectional view of the first exemplary structure after removal of sacrificial contact opening fill structures according to an embodiment of the present disclosure.

FIG. 18 is a vertical cross-sectional view of the first exemplary structure after formation of finned contact via cavities according to an embodiment of the present disclosure.

FIG. 19 is a vertical cross-sectional view of the first exemplary structure after formation of annular dielectric isolation fins according to an embodiment of the present disclosure.

FIG. 20 is a vertical cross-sectional view of the first exemplary structure after formation of sacrificial contact via structures according to an embodiment of the present disclosure.

FIG. 21 is a vertical cross-sectional view of the first exemplary structure after formation of line-shaped openings through the contact-level dielectric layer according to an embodiment of the present disclosure.

FIG. 22 is a vertical cross-sectional view of the first exemplary structure after formation of lateral isolation trenches according to an embodiment of the present disclosure.

FIG. 23 is a vertical cross-sectional view of the first exemplary structure after formation of laterally-extending cavities according to an embodiment of the present disclosure.

FIG. 24A is vertical cross-sectional view of the first exemplary structure after formation of electrically conductive layers according to an embodiment of the present disclosure. FIG. 24B is a top-down view of the exemplary structure of FIG. 24A. The vertical plane A-A′ in FIG. 24B is the cut plane of the vertical cross-sectional view of FIG. 24A. FIG. 24C is a vertical cross-sectional view of the exemplary structure along the hinged vertical cut plane C-C′ in FIG. 24B.

FIG. 25A is vertical cross-sectional view of the first exemplary structure after formation of dielectric wall structures according to an embodiment of the present disclosure. FIG. 25B is a top-down view of the exemplary structure of FIG. 25A. The vertical plane A-A′ in FIG. 25B is the cut plane of the vertical cross-sectional view of FIG. 25A. FIG. 25C is a vertical cross-sectional view of the exemplary structure along the hinged vertical cut plane C-C′ in FIG. 25B.

FIG. 26 is a vertical cross-sectional view of the first exemplary structure after removal of sacrificial contact via structures according to an embodiment of the present disclosure.

FIG. 27A is a vertical cross-sectional view of the first exemplary structure after formation of various contact via structures according to an embodiment of the present disclosure. FIG. 27B is a first horizontal cross-sectional view of the first exemplary structure along the horizontal plane B-B′ of FIG. 27A. FIG. 27C is a second horizontal cross-sectional view of the first exemplary structure of FIG. 27A along the horizontal plane C-C′ of FIG. 27A. FIG. 27D is a vertical cross-sectional view of the first exemplary structure along the vertical plane D-D′ of FIG. 27B-27C.

FIG. 28A is a top-down view of a first alternative configuration of the first exemplary structure after formation of a second-tier structure according to an embodiment of the present disclosure. FIG. 28B is a top-down view of the first alternative configuration of the first exemplary structure after formation of a third-tier structure according to an embodiment of the present disclosure. FIG. 28C is a first horizontal cross-sectional view of the first alternative configuration of the first exemplary structure along a horizontal plane including first insulating cap layers after formation of various contact via structures according to an embodiment of the present disclosure. FIG. 28D is a second horizontal cross-sectional view of the first alternative configuration of the first exemplary structure along a horizontal plane including second insulating cap layers after formation of various contact via structures according to an embodiment of the present disclosure. FIG. 28E is a top-down view of the first alternative configuration of the first exemplary structure after formation of various contact via structures according to an embodiment of the present disclosure.

FIG. 29A is a top-down view of a second alternative configuration of the first exemplary structure after formation of a second-tier structure according to an embodiment of the present disclosure. FIG. 29B is a top-down view of the second alternative configuration of the first exemplary structure after formation of a third-tier structure according to an embodiment of the present disclosure. FIG. 29C is a first horizontal cross-sectional view of the second alternative configuration of the first exemplary structure along a horizontal plane including first insulating cap layers after formation of various contact via structures according to an embodiment of the present disclosure. FIG. 29D is a second horizontal cross-sectional view of the second alternative configuration of the first exemplary structure along a horizontal plane including second insulating cap layers after formation of various contact via structures according to an embodiment of the present disclosure. FIG. 29E is a top-down view of the second alternative configuration of the first exemplary structure after formation of various contact via structures according to an embodiment of the present disclosure.

FIG. 30A is a top-down view of a third alternative configuration of the first exemplary structure after formation of a second-tier structure according to an embodiment of the present disclosure. FIG. 30B is a top-down view of the third alternative configuration of the first exemplary structure after formation of a third-tier structure according to an embodiment of the present disclosure. FIG. 30C is a first horizontal cross-sectional view of the third alternative configuration of the first exemplary structure along a horizontal plane including first insulating cap layers after formation of various contact via structures according to an embodiment of the present disclosure. FIG. 30D is a second horizontal cross-sectional view of the third alternative configuration of the first exemplary structure along a horizontal plane including second insulating cap layers after formation of various contact via structures according to an embodiment of the present disclosure. FIG. 30E is a top-down view of the third alternative configuration of the first exemplary structure after formation of various contact via structures according to an embodiment of the present disclosure.

FIG. 31A is a top-down view of a fourth alternative configuration of the first exemplary structure after formation of a second-tier structure according to an embodiment of the present disclosure. FIG. 31B is a top-down view of the fourth alternative configuration of the first exemplary structure after formation of a third-tier structure according to an embodiment of the present disclosure. FIG. 31C is a first horizontal cross-sectional view of the fourth alternative configuration of the first exemplary structure along a horizontal plane including first insulating cap layers after formation of various contact via structures according to an embodiment of the present disclosure. FIG. 31D is a second horizontal cross-sectional view of the fourth alternative configuration of the first exemplary structure along a horizontal plane including second insulating cap layers after formation of various contact via structures according to an embodiment of the present disclosure. FIG. 31E is a top-down view of the fourth alternative configuration of the first exemplary structure after formation of various contact via structures according to an embodiment of the present disclosure.

FIG. 32A is a top-down view of a fifth alternative configuration of the first exemplary structure after formation of a second-tier structure according to an embodiment of the present disclosure. FIG. 32B is a top-down view of the fifth alternative configuration of the first exemplary structure after formation of a third-tier structure according to an embodiment of the present disclosure. FIG. 32C is a first horizontal cross-sectional view of the fifth alternative configuration of the first exemplary structure along a horizontal plane including first insulating cap layers after formation of various contact via structures according to an embodiment of the present disclosure. FIG. 32D is a second horizontal cross-sectional view of the fifth alternative configuration of the first exemplary structure along a horizontal plane including second insulating cap layers after formation of various contact via structures according to an embodiment of the present disclosure. FIG. 32E is a top-down view of the fifth alternative configuration of the first exemplary structure after formation of various contact via structures according to an embodiment of the present disclosure.

FIG. 33A is a top-down view of a sixth alternative configuration of the first exemplary structure after formation of a second-tier structure according to an embodiment of the present disclosure. FIG. 33B is a top-down view of the sixth alternative configuration of the first exemplary structure after formation of a third-tier structure according to an embodiment of the present disclosure. FIG. 33C is a first horizontal cross-sectional view of the sixth alternative configuration of the first exemplary structure along a horizontal plane including first insulating cap layers after formation of various contact via structures according to an embodiment of the present disclosure. FIG. 33D is a second horizontal cross-sectional view of the sixth alternative configuration of the first exemplary structure along a horizontal plane including second insulating cap layers after formation of various contact via structures according to an embodiment of the present disclosure. FIG. 33E is a top-down view of the sixth alternative configuration of the first exemplary structure after formation of various contact via structures according to an embodiment of the present disclosure.

FIG. 34A is a top-down view of a seventh alternative configuration of the first exemplary structure after formation of a second-tier structure according to an embodiment of the present disclosure. FIGS. 34B, 34C, 34D and 34E are vertical cross-sectional views of the exemplary structure of FIG. 34A along the respective vertical planes B-B′, C-C′, D-D′ and E-E′ in FIG. 34A.

FIG. 35 is a vertical cross-sectional view of an alternative configuration of the exemplary structure of FIG. 34E.

FIG. 36A is a first vertical cross-sectional view of a second exemplary structure according to an embodiment of the present disclosure. FIG. 36B is a second vertical cross-sectional view of the second exemplary structure according to an embodiment of the present disclosure. FIG. 36C is a third vertical cross-sectional view of the second exemplary structure according to an embodiment of the present disclosure. FIG. 36D is a top-down view of the second exemplary structure. The vertical plane A-A′ is the cut plane of the first vertical cross-sectional view of FIG. 36A. The vertical plane B-B′ is the cut plane of the second vertical cross-sectional view of FIG. 36B. The vertical plane C-C′ is the cut plane of the third vertical cross-sectional view of FIG. 36C.

FIG. 37A is a first vertical cross-sectional view of an alternative configuration of the second exemplary structure according to an embodiment of the present disclosure. FIG. 37B is a second vertical cross-sectional view of the alternative configuration of the second exemplary structure according to an embodiment of the present disclosure. FIG. 37C is a third vertical cross-sectional view of the alternative configuration of the second exemplary structure according to an embodiment of the present disclosure. FIG. 37D is a top-down view of the second alternative configuration of the exemplary structure. The vertical plane A-A′ is the cut plane of the first vertical cross-sectional view of FIG. 37A. The vertical plane B-B′ is the cut plane of the second vertical cross-sectional view of FIG. 37B. The vertical plane C-C′ is the cut plane of the third vertical cross-sectional view of FIG. 37C.

### DETAILED DESCRIPTION

As discussed above, the embodiments of the present disclosure are directed to a three-dimensional memory device with multi-tier structures incorporating lateral isolation structures containing dielectric filled gaps between dielectric wall structures and methods for forming the same, the various aspects of which are described below. Multi-tier memory structures may include multi-tier alternating stacks of insulating layers and electrically conductive layers that laterally extend horizontally over relatively long distances. As the number of tiers in the multi-tier memory structures increases, maintaining a uniform and stable width for lateral isolation structures between neighboring multi-tier alternating stacks becomes increasingly difficult as the stack height increases. Embodiments of the present disclosure are directed to structures and methods for increasing the structural stability of the lateral isolation trenches that are used to replace sacrificial material layers with electrically conductive layers by using multiple lateral isolation trenches laterally spaced by a dielectric structural support element, such as a dielectric pillar structure or retro-stepped dielectric material portion including a respective full-height dielectric material sub-portion.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements. The same reference numerals refer to the same element or similar element. Unless otherwise indicated, elements having the same reference numerals are presumed to have the same composition and the same function.

Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, an element located “on” a second element can be located on the exterior side of a surface of the second element or on the interior side of the second element. As used herein, an element is located “directly on” a second element if there exist a physical contact between a surface of the element and a surface of the second element. As used herein, an element is “electrically connected to” a second element if there exists a conductive path consisting of at least one conductive material between the element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow. As used herein, a first surface and a second surface are “vertically coincident” with each other if the second surface overlies or underlies the first surface and there exists a vertical plane or a substantially vertical plane that includes the first surface and the second surface. As used herein, removal of a first material is “selective to” a second material if the removal rate of the first material is greater than the removal rate of the second material at least by a factor of 3. Unless otherwise expressly indicated, removal of the first material selectively to the second material implies the possibility of the ratio of the removal rates equal to, or greater than, 3, and/or 10, and/or 100, and/or 1,000.

As used herein, a “memory level” or a “memory array level” refers to the level corresponding to a general region between a first horizontal plane (i.e., a plane parallel to the top surface of the substrate) including topmost surfaces of an array of memory elements and a second horizontal plane including bottommost surfaces of the array of memory elements. As used herein, a “through-stack” element refers to an element that vertically extends through a memory level.

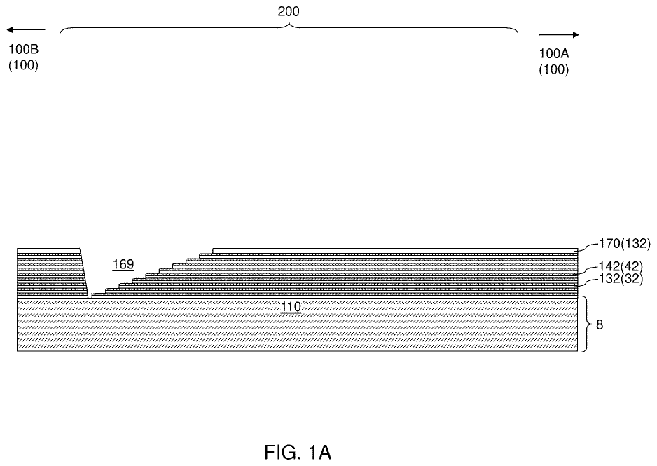

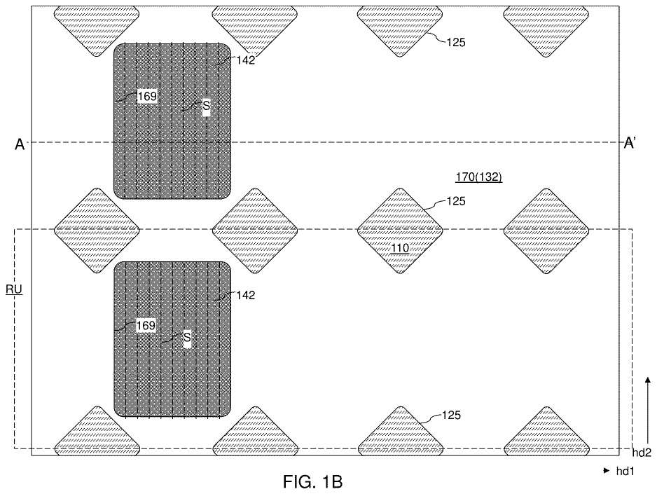

Referring to FIGS. 1A and 1B, a first exemplary structure is illustrated according to an embodiment of the present disclosure. The first exemplary structure includes a substrate 8 which may contain an optional semiconductor material layer 110. Optionally, the substrate may additionally comprise an underlying semiconductor material layer (not illustrated), optional semiconductor devices located on the underlying semiconductor material layer (not illustrated), optional lower level dielectric layers (not illustrated), and optional lower metal interconnect structures (not illustrated) underneath the semiconductor material layer 110. The semiconductor material layer 110 may comprise a polycrystalline semiconductor material layer or a single crystalline semiconductor material layer. For example, the substrate 8 may comprise a single crystalline silicon wafer, and the semiconductor material layer 110 may comprise a doped well in an upper portion of the substrate 8 or an epitaxial silicon layer deposited on the top surface of the substrate 8. Alternatively, the substrate 8 may comprise a silicon on insulator (SOI) substrate, in which the semiconductor material layer 110 comprises a silicon layer located over an insulating portion of the substrate 8. Alternatively, a peripheral (i.e., driver) circuit may be located on the substrate 8, and the semiconductor material layer 110 may comprise a polysilicon layer which overlies the peripheral circuit.

A first-tier vertically alternating sequence of first insulating layers 132 and first sacrificial material layers 142 can be formed over the semiconductor material layer 110. Each of the first insulating layers 132 may be formed as a single continuous material layer, and thus, may be referred to as a first continuous insulating layer. Each of the first sacrificial material layers 142 may be formed as a single continuous material layer, and thus, may be formed as a first continuous sacrificial material layer. Each of the first insulating layers 132 and the first sacrificial material layers 142 may have a thickness in a range from 20 nm to 80 nm, although lesser and greater thicknesses may also be employed.

In one embodiment, the first-tier vertically alternating sequence of first insulating layers 132 and first sacrificial material layers 142 may include a periodic repetition of a unit layer stack including a first insulating layer 132 and a first sacrificial material layer 142. The total number of repetitions of the unit layer stack may be in a range from 4 to 1,024, such as from 16 to 256, although lesser and greater numbers of repetitions may also be employed.

The first insulating layers 132 may comprise, and/or may consist essentially of, an insulating material such as undoped silicate glass or a doped silicate glass. The first sacrificial material layers 142 may comprise, and/or may consist essentially of, a sacrificial material such as silicon nitride, a silicon-germanium alloy, organosilicate glass, or a polymer material. Generally, the first sacrificial material layers 142 comprise a material that may be removed selectively to the materials of the first insulating layers 132 and the semiconductor material layer 110. The topmost first insulating layer 132 is herein referred to as a first insulating cap layer 170. The first insulating layers 132 are a first subset of insulating layers 32 that are formed in this processing step and in subsequent processing steps. The first sacrificial material layers 142 are a first subset of sacrificial material layers 42 that are formed in this processing step and in subsequent processing steps.

The first exemplary structure may comprise a first memory array region 100A in which first memory arrays are to be subsequently formed, a second memory array region 100B in which second memory arrays are to be subsequently formed, and an inter-array region 200 in which stepped surfaces and layer contact via structures contacting a respective electrically conductive layer are to be subsequently formed. In one embodiment, the first memory array region 100A and the second memory array region 100B can be laterally spaced apart from each other along a first horizontal direction (e.g., word line direction) hd1 by the inter-array region 200.

First stepped surfaces can be formed by patterning the first-tier vertically alternating sequence (132, 142). Generally, the first stepped surfaces may be formed employing any method for forming stepped surfaces as known in the art. For example, a first patterned hard mask layer (not shown) may be formed over the first-tier vertically alternating sequence (132, 142) to define areas in which first stepped surfaces are to be subsequently formed. A first trimmable etch mask layer (not shown) can be formed over the first patterned hard mask layer, and can be lithographically patterned to form slit-shaped openings over peripheral regions of the openings in the first patterned hard mask layer. A unit processing sequence can be repeatedly performed to form first stepped surfaces in the first-tier vertically alternating sequence (132, 142) within the areas of openings in the first patterned hard mask layer. For example, the unit processing sequence may comprise an anisotropic etch process that etches a pair of a first insulating layer 132 and a first sacrificial material layer 142 and a trimming process that isotropically trims the first trimmable etch mask layer. The number of repetitions of the unit processing sequence may be the same as the total number of first sacrificial material layers 142 in the first-tier vertically alternating sequence (132, 142). A first-tier stepped cavity 169 overlying a respective set of first stepped surfaces of the first-tier vertically alternating sequence (132, 142) can be formed within each patterned area of the first-tier vertically alternating sequence (132, 142).

In one embodiment, the vertical steps within each first-tier stepped cavity may be laterally spaced from each other along the first horizontal direction hd1 (which may be a word line direction). In one embodiment, the first-tier stepped cavities may be arranged along a second horizontal direction hd2 (which may be a bit line direction). In one embodiment, the first exemplary structure may have a periodic pattern that repeats along the first horizontal direction hd1. Specifically, a repetition unit RU is repeated along the second horizontal direction hd2. In one embodiment, each repetition unit RU may comprise a first-tier stepped cavity. Physically exposed portions of the first continuous sacrificial material layers 142 can be locally thickened underneath the first-tier stepped cavities by depositing and patterning additional sacrificial material thereon.

In one embodiment, the lateral extent of the layers of the first alternating sequence (132, 142) along a first horizontal direction hd1 may vary (e.g., decrease) with a vertical distance from the substrate 8 within each region including a respective set of first stepped surfaces. In one embodiment, each opening in the topmost layer of the first-tier vertically alternating sequence (132, 142) may have a rectangular shape having a pair of lengthwise sides laterally extending along the first horizontal direction hd1 and a pair of widthwise sides laterally extending along a second horizontal direction hd2 that is perpendicular to the first horizontal direction hd1. Each set of first stepped surfaces may comprise vertical steps S shown in FIG. 1B. Tapered surfaces may be formed around each first-tier stepped cavity between the stepped surfaces and the topmost horizontal surface of the first-tier vertically alternating sequence (132, 142). Alternative schemes employing repetition of an etch step and a trimming step may be employed to pattern portions of the first-tier vertically alternating sequence (132, 142) that are not masked by the first patterned hard mask layer. The first trimmable etch mask layer and the first patterned hard mask layer can be subsequently removed.

According to an aspect of the present disclosure shown in FIG. 1B, each mask pattern in the various etch masks employed to form the first-tier stepped cavities 169 includes additional openings. In one embodiment the additional openings are arranged as a two-dimensional array of openings. The pattern of the additional openings in each etch mask pattern may be identical. Thus, the areas of the additional openings in the etch mask patterns are exposed to all anisotropic etch processes that are employed to form the first-tier stepped cavities 169. First-tier pillar cavities 125 are formed within the areas of the additional openings in the etch mask patterns. The first-tier pillar cavities 125 have the same depth as the deepest portion of the first-tier stepped cavities 169. Thus, the first-tier pillar cavities 125 may have a uniform depth that equals the thickness of the first-tier vertically alternating sequence (132, 142). In one embodiment, top surface segments of the semiconductor material layer 110 may be physically exposed underneath the first-tier pillar cavities 125. Optionally, a surface oxidation process may be performed to convert physically exposed surface portions of the semiconductor material layer 110 into semiconductor oxide liners (not illustrated), which may be silicon oxide liners.

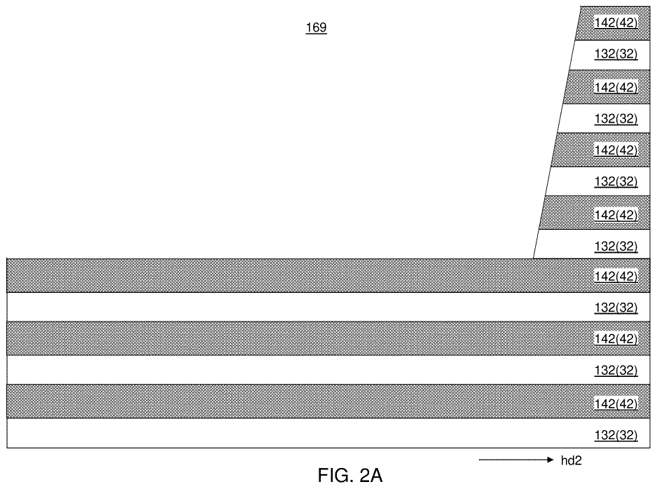

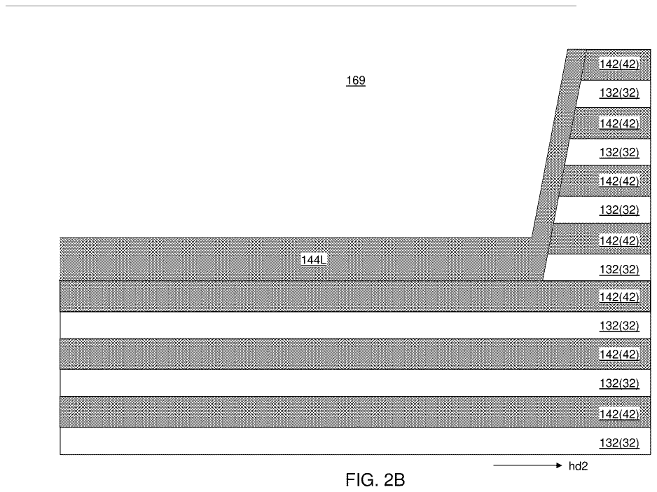

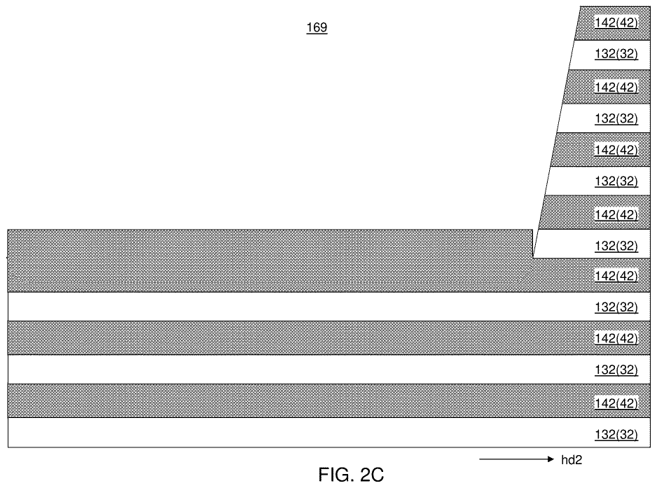

In one embodiment, the physically exposed portions of the first sacrificial material layers 142 can be locally thickened. FIG. 2A-2C are sequential vertical cross-sectional views of a region of the first exemplary structure during thickening of physically-exposed portions of the first sacrificial material layers according to an embodiment of the present disclosure.

Referring to FIG. 2A, an anisotropic material deposition process can be performed to anisotropically deposit a same material as the material of the first sacrificial material layers 142 to form a non-conformal sacrificial material layer 144L. In one embodiment, the first sacrificial material layers 142 comprise silicon nitride, and the anisotropic material deposition process may deposit a silicon nitride material anisotropically. The non-conformal sacrificial material layer 144L is deposited by a non-conformal deposition process such as a plasma-enhanced chemical vapor deposition (PECVD) process. Preferably, the deposition of the sacrificial material of the non-conformal sacrificial material layer 144L is highly anisotropic such that the thickness of each horizontally-extending portion of the non-conformal sacrificial material layer 144L is greater than (e.g., at least twice) the thickness of non-horizontally-extending portions of the non-conformal sacrificial material layer 144L. In one embodiment the thickness of the horizontally-extending portions of the non-conformal sacrificial material layer 144L may be in a range from 50% to 300% of the thickness of each first sacrificial material layer 142.

Referring to FIG. 2B, an isotropic etch process can be performed to isotropically recess the non-conformal sacrificial material layer 144L. The duration of the isotropic etch process can be selected such that the non-horizontally-extending portions of the non-conformal sacrificial material layer 144L are removed by the isotropic etch process. Remaining horizontally-extending portions of the non-conformal sacrificial material layer 144L overlying a top surface segment of a respective one of the first sacrificial material layers 142 can be incorporated into the respective one of the first sacrificial material layers 142.

Thus, physically-exposed portions of the sacrificial material layers 42 (such as the first sacrificial material layers 142) in the staircase region can be thickened such that the thickened portions of the sacrificial material layers 142 have a thickness in a range from 125% to 250%, such as from 150% to 200%, of the unthickened portion of the first sacrificial material layers 142 (which is the same as the original thickness of each first sacrificial material layers 142). While an embodiment is described in which physically exposed portions of the first sacrificial material layers 142 are locally thickened by anisotropic deposition and isotropic etchback of a sacrificial material, the physically exposed portions of the first sacrificial material layers 142 may be locally thickened by alternative methods that can selectively increase the thickness of physically exposed portions of the first sacrificial material layers 142.

Referring to FIG. 2C, portions of the non-conformal sacrificial material layer 144L that are deposited outside the areas of the first-tier stepped cavities 169 can be removed, for example, by covering the areas of the first-tier stepped cavities 169 with patterned photoresist materials without covering sidewalls of the first-tier stepped cavities 169, and by performing an etch process that etches unmasked portions of the material of the non-conformal sacrificial material layer 144L. Physically exposed portions of the first sacrificial material layers 142 may be locally thickened within the first-tier stepped cavities 169.

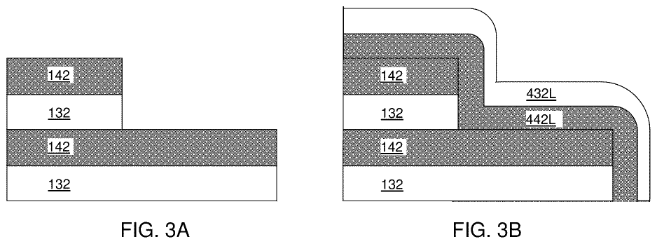

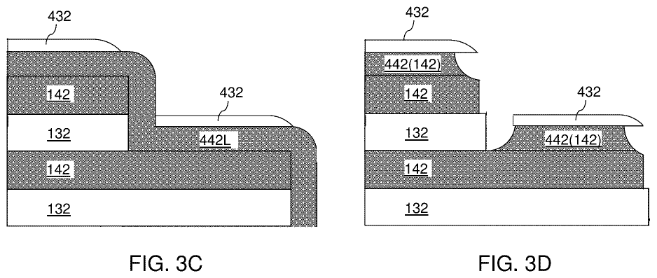

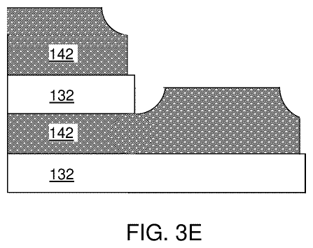

Local thickening of the physically exposed portions of the first sacrificial material layers 142 may also be performed employing alternative methods. FIG. 3A-3E are sequential vertical cross-sectional views of a region of the first exemplary structure during a sequence of processing steps that may be employed to locally thicken the physically-exposed portions of the first sacrificial material layers according to an embodiment of the present disclosure.

Referring to FIG. 3A, a region of the first-tier stepped surfaces in a first-tier stepped cavity 169 after the processing steps of FIGS. 1A and 1B is illustrated.

Referring to FIG. 3B, an additive sacrificial material layer 442L can be conformally deposited by a conformal deposition process such as a low pressure chemical vapor deposition process. The thickness of the additive sacrificial material layer 442L may be in a range from 40% to 300%, such as from 60% to 150%, of the thickness of each first sacrificial material layer 142. The additive sacrificial material layer 442L may comprise the same material as the first sacrificial material layers 142. For example, if the first sacrificial material layers 142 comprise silicon nitride, the additive sacrificial material layer 442L may comprise silicon nitride.

Subsequently, a non-conformal cover material layer 432L may be anisotropically deposited. The anisotropic deposition of the non-conformal cover material layer 432L may be effected, for example, by plasma enhanced chemical vapor deposition. The non-conformal cover material layer 432L comprises a material that can function as an etch mask material for subsequently etching unmasked portions of the additive sacrificial material layer 442L. For example, the non-conformal cover material layer 432L may comprise silicon oxide. The vertical thickness of the horizontally-extending portions of the non-conformal cover material layer 432L is greater than the lateral thickness of the vertically-extending portions of the non-conformal cover material layer 432L. The difference between the vertical thickness of the horizontally-extending portions of the non-conformal cover material layer 432L and the lateral thickness of the vertically-extending portions of the non-conformal cover material layer 432L may be in a range from 1.3 to 3.0, such as from 1.5 to 2.0.

Referring to FIG. 3C, an isotropic etch process can be performed to isotropically etch the material of the non-conformal cover material layer 432L. The duration of the isotropic etch process is selected such that the etch distance of the isotropic etch process for the material of the non-conformal cover material layer 432L is greater than the lateral thickness of vertically-extending portions of the non-conformal cover material layer 432L, and is less than the vertical thickness of the horizontally-extending portions of the non-conformal cover material layer 432L. Thus, remaining portions of the non-conformal cover material layer 432L after the isotropic etch process comprise cover material plates 432 that overlie horizontally-extending portions of the additive sacrificial material layer 442L. The cover material plates 432 have a vertical thickness that is not greater than the difference between the vertical thickness of the horizontally-extending portions of the non-conformal cover material layer 432L and the lateral thickness of vertically-extending portions of the non-conformal cover material layer 432L, and may be in a range from 10 nm to 50 nm, although lesser and greater thicknesses may also be employed.

Referring to FIG. 3D, a selective isotropic etch process can be performed to isotropically etch unmasked portions of the additive sacrificial material layer 442L without etching the materials of cover material plates 432 or the first-tier insulating layers 132. The duration of the selective isotropic etch process may be selected such that the etch distance of the selective isotropic etch process for the material of the additive sacrificial material layer 442L is not less than the uniform thickness of the additive sacrificial material layer 442L. Thus, vertically-extending portions of the additive sacrificial material layer 442L are removed by the selective isotropic etch process, while remaining horizontally-extending portions of the additive sacrificial material layer 442L underlie a respective one of the cover material plates 432. The remaining horizontally-extending portions of the additive sacrificial material layer 442L comprise sacrificial material plates 442, which are incorporated into a respective one of the first sacrificial material layers 142.

Referring to FIG. 3E, a selective etch process may be optionally performed to remove the cover material plates 432 without removing the materials of the sacrificial material plates 442 or the first sacrificial material layers 142. The material of sacrificial material plates 442 may be the same as the material of the first sacrificial material layers 142. Thus, the first sacrificial material layers 142 incorporate the sacrificial material plates 442, and are locally thickened in the regions of the first stepped surfaces.

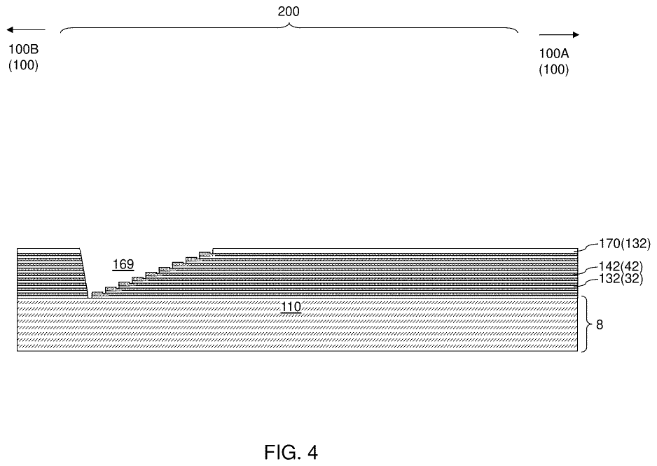

Referring to FIG. 4, the first exemplary structure is illustrated after local thickening of the first sacrificial material layers 142. Alternatively, the local thickening of the first sacrificial material layers 142 may be omitted if subsequently formed contact via structures do not extend through the respective word lines and select gate electrodes which will replace the sacrificial material layers.

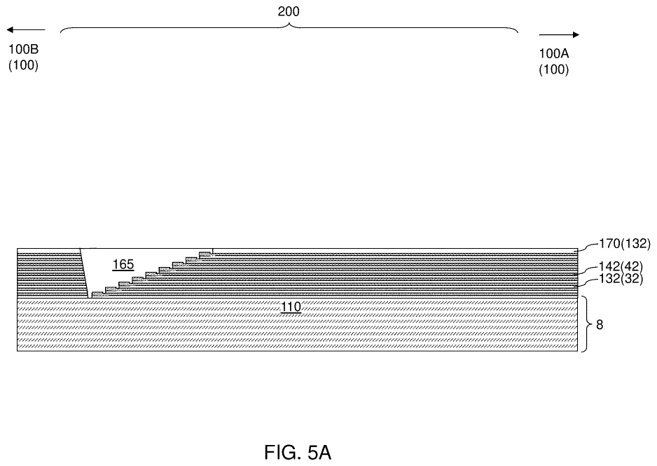

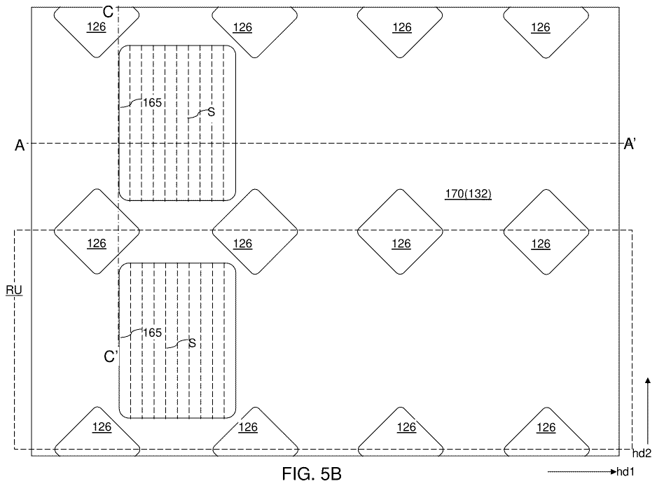

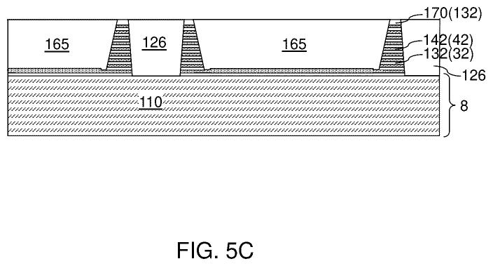

Referring to FIGS. 5A-5C, a dielectric fill material can be deposited within each of the first-tier stepped cavities 169 and each of the first-tier pillar cavities 125. Excess portions of the dielectric fill material can be removed from above the horizontal plane including the topmost surface of the first-tier vertically alternating sequence (132, 142) by performing a planarization process, which may comprise a chemical mechanical polishing process or a recess etch process. Each remaining portion of the dielectric fill material that fills a respective first-tier stepped cavity 169 constitutes a first-tier retro-stepped dielectric material portion 165. Each remaining portion of the dielectric fill material that fills a respective one of the first-tier pillar cavities 125 constitutes a first-tier dielectric pillar structure 126. A first-tier structure is formed, which comprises the first-tier vertically alternating sequence (132, 142), the first-tier retro-stepped dielectric material portions 165, and the first-tier dielectric pillar structures 126.

The horizontal cross-sectional shape of the first-tier dielectric pillar structures 126 may be any two-dimensional shape having a closed periphery. For example, the horizontal cross-sectional shapes of the first-tier dielectric pillar structures 126 may be a polygon (such as rectangle, a rhombus, a hexagon, etc.), a rounded polygon (i.e., a shape that is derived from a polygon by rounding at least one corner), a circle, an oval, or any other suitable two-dimensional shape. In the illustrated example, the shape of each first-tier dielectric pillar structure 126 is a rounded rhombus. Generally, the shapes of the first-tier retro-stepped dielectric material portions 165 and the first-tier dielectric pillar structures 126 are selected such that the first-tier vertically alternating stack (132, 142) is not completely cut along the first horizontal direction hd1. A first-tier structure is formed, which comprises the first-tier vertically alternating sequence (132, 142), the first-tier dielectric pillar structures 126 and the first-tier retro-stepped dielectric material portions 165.

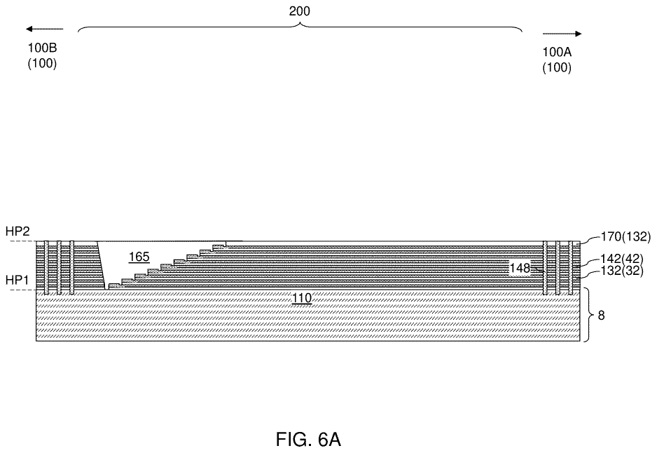

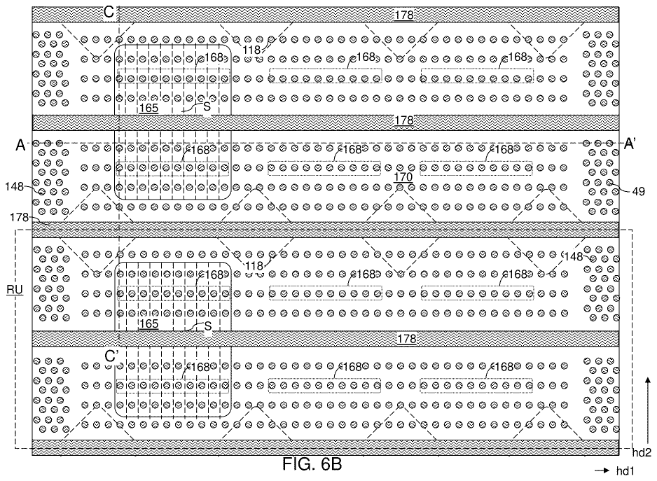

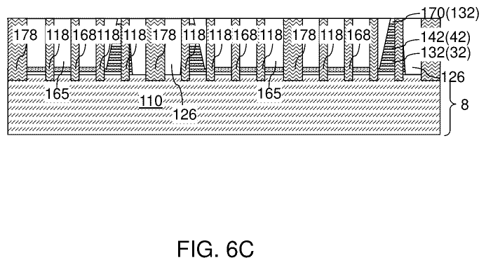

Referring to FIGS. 6A-6C, various first-tier openings can be formed through the first-tier structure (132, 142, 165) and into an upper portion of the semiconductor material layer 110. A photoresist layer (not shown) can be applied over the first insulating cap layer 170, and can be lithographically patterned to form various openings therethrough. The pattern of openings in the photoresist layer can be transferred through the first-tier structure (132, 142, 165) and into an upper portion of the semiconductor material layer 110 by a first anisotropic etch process to form the various first-tier openings concurrently. The various first-tier openings can include first-tier memory openings, first-tier support openings, sacrificial first-tier contact openings, and first-tier lateral isolation trenches.

The first-tier memory openings are formed in the memory array regions 100 through each layer within the first-tier vertically alternating sequence (132, 142). The first-tier memory openings are subsequently employed to form memory stack structures therein. The first-tier memory openings can be formed in clusters that are laterally spaced apart along the second horizontal direction hd2. Each cluster of first-tier memory openings can be formed as a two-dimensional array of first-tier memory openings.

The first-tier lateral isolation trenches may have a respective rectangular shape that is elongated along the first horizontal direction hd1. Each first-tier lateral isolation trench may laterally extend through the entirety of the first memory array region 100A, the inter-array region 200, and the second memory array region 100B. Thus, the first-tier vertically alternating sequence is divided into a plurality of first alternating stacks (132,142) of respective first insulating layers 132 and respective first sacrificial material layers 142.

In one embodiment, a first subset of the first-tier lateral isolation trenches may divide a respective first-tier retro-stepped dielectric material portion 165 into two discrete first-tier retro-stepped dielectric material portions 165. In one embodiment, the first exemplary structure may include a periodic repetition of a unit pattern that is repeated along the second horizontal direction hd2. The set of all structural elements within a unit pattern is herein referred to as a repetition unit RU. Each repetition unit RU may comprise a patterned portion of a first-tier retro-stepped dielectric material portion 165. Each repetition unit RU may comprise two first-tier alternating stacks of first insulating layers 132 and first sacrificial material layers 142.

In one embodiment, a second subset of the first-tier lateral isolation trenches may divide a respective row of first-tier dielectric pillar structures 126 into a respective pair of rows of first-tier dielectric pillar structures 126. Each of the first-tier dielectric pillar structures 126, after formation of the lateral isolation trenches, may comprise a respective sidewall that is exposed to a respective one of the lateral isolation trenches. Each repetition unit RU may comprise a pair of patterned portions of a first-tier retro-stepped dielectric material portion 165, and two rows of first-tier dielectric pillar structures 126 (as divided by the first-tier lateral isolation trenches). Each repetition unit RU may comprise two first-tier alternating stacks of first insulating layers 132 and first sacrificial material layers 142.

The sacrificial first-tier contact openings can be formed through the first-tier retro-stepped dielectric material portions 165 and through a respective horizontally-extending surface segment of the first stepped surfaces. The first-tier support openings can be formed in the inter-array region 200 in areas that are not filled with the sacrificial first-tier contact openings.

A sacrificial fill material can be deposited in the various first-tier openings to form various sacrificial first-tier opening fill structures. The various sacrificial first-tier opening fill structures comprise sacrificial first-tier memory opening fill structures 148 that are formed in the first-tier memory openings, sacrificial first-tier support opening fill structures 118 that are formed in the first-tier support openings, sacrificial first-tier contact opening fill structures 168 that are formed in the first-tier contact openings, and sacrificial first-tier wall structures 178 that are formed in the first-tier lateral isolation trenches. The sacrificial fill material in the various sacrificial first-tier opening fill structures comprises a material that is different from the materials of the first insulating layers 132 and the first sacrificial material layers 142. For example, the sacrificial fill material in the various sacrificial first-tier opening fill structures may comprise a semiconductor material (such as amorphous silicon or silicon-germanium).

The horizontal plane including the bottommost surfaces of the first-tier alternating stacks (132, 142) is herein referred to as a first horizontal plane HP1. The horizontal plane including the topmost surfaces of the first-tier alternating stacks (132, 142) is herein referred to as a second horizontal plane HP2.

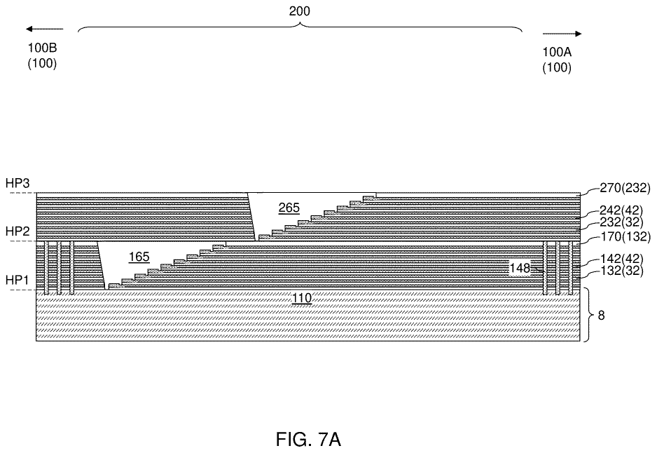

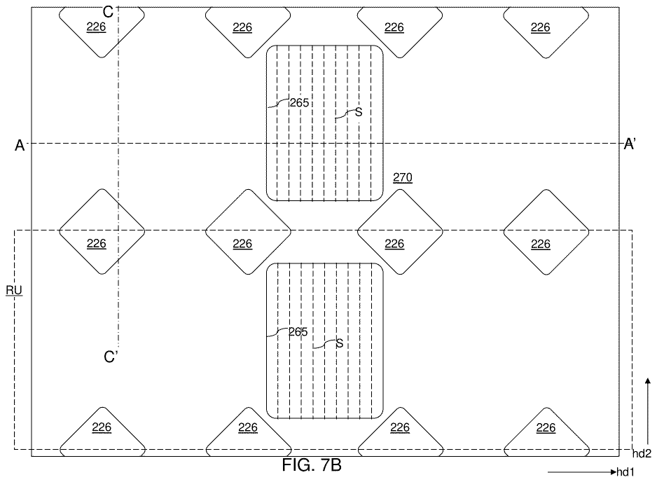

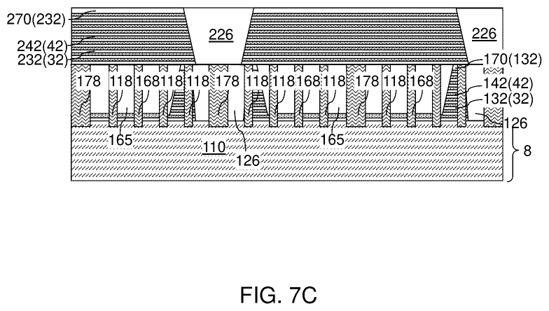

Referring to FIGS. 7A-7C, a second-tier vertically alternating sequence of second insulating layers 232 and second sacrificial material layers 242 can be formed over the first-tier structure. Each of the second insulating layers 232 may be formed as a single continuous material layer, and thus, may be referred to as a second continuous insulating layer. Each of the second sacrificial material layers 242 may be formed as a single continuous material layer, and thus, may be formed as a second continuous sacrificial material layer. Each of the second insulating layers 232 and the second sacrificial material layers 242 may have a thickness in a range from 20 nm to 80 nm, although lesser and greater thicknesses may also be employed.

In one embodiment, the second-tier vertically alternating sequence of second insulating layers 232 and second sacrificial material layers 242 may include a periodic repetition of a unit layer stack including a second insulating layer 232 and a second sacrificial material layer 242. The total number of repetitions of the unit layer stack may be in a range from 4 to 1,024, such as from 16 to 256, although lesser and greater numbers of repetitions may also be employed.

The second insulating layers 232 may comprise, and/or may consist essentially of, an insulating material such as undoped silicate glass or a doped silicate glass. The second sacrificial material layers 242 may comprise, and/or may consist essentially of, a sacrificial material such as silicon nitride, a silicon-germanium alloy, organosilicate glass, or a polymer material. Generally, the second sacrificial material layers 242 comprise a material that may be removed selectively to the materials of the second insulating layers 232 and the semiconductor material layer 110. The second insulating layers 232 may comprise the same material as the first insulating layers 132, and the second sacrificial material layers 242 may comprise the same material as the first sacrificial material layers 142. The topmost second insulating layer 232 is herein referred to as a second insulating cap layer 270. The second insulating layers 232 are a second subset of insulating layers 32 that are formed in the first exemplary structure. The second sacrificial material layers 242 are a second subset of sacrificial material layers 42 that are formed in the first exemplary structure. The topmost surface of the second-tier vertically alternating sequence (232, 242) may be formed in a third horizontal plane HP3.

Second-tier stepped surfaces can be formed by patterning the second-tier vertically alternating sequence (232, 242). Generally, the second-tier stepped surfaces may be formed employing any method for forming stepped surfaces as known in the art. For example, a second patterned hard mask layer (not shown) may be formed over the second-tier vertically alternating sequence (232, 242) to define areas in which second-tier stepped surfaces are to be subsequently formed. A second trimmable etch mask layer (not shown) can be formed over the second patterned hard mask layer, and can be lithographically patterned to form slit-shaped openings over peripheral regions of the openings in the second patterned hard mask layer. A unit processing sequence can be repeatedly performed to form second-tier stepped surfaces in the second-tier vertically alternating sequence (232, 242) within the areas of openings in the second patterned hard mask layer. For example, the unit processing sequence may comprise an anisotropic etch process that etches a pair of a second insulating layer 232 and a second sacrificial material layer 242 and a trimming process that isotropically trims the second trimmable etch mask layer. The number of repetitions of the unit processing sequence may be the same as the total number of second sacrificial material layers 242 in the second-tier vertically alternating sequence (232, 242). A second-tier stepped cavity overlying a respective set of second-tier stepped surfaces of the second-tier vertically alternating sequence (232, 242) can be formed within each patterned area of the second-tier vertically alternating sequence (232, 242).

In one embodiment, the vertical steps within each second-tier stepped cavity may be laterally spaced from each other along the first horizontal direction hd1 (which may be a word line direction). In one embodiment, the second-tier stepped cavities may be arranged along a second horizontal direction hd2 (which may be a bit line direction). In one embodiment, the first exemplary structure may have a periodic pattern that repeats along the first horizontal direction hd1. Specifically, a repetition unit RU is repeated along the second horizontal direction hd2. In one embodiment, each repetition unit RU may comprise a second-tier stepped cavity. Physically exposed portions of the second continuous sacrificial material layers 242 can be locally thickened underneath the second-tier stepped cavities.

According to an aspect of the present disclosure, each mask pattern in the various etch masks employed to form the second-tier stepped cavities includes additional openings. In one embodiment the additional openings are arranged as a two-dimensional array of openings located at the same locations as the first-tier dielectric pillar structures 126. The pattern of the additional openings in each etch mask pattern may be identical. Thus, the areas of the additional openings in the etch mask patterns are exposed to all anisotropic etch processes that are employed to form the second-tier stepped cavities. Second-tier pillar cavities are formed within the areas of the additional openings in the etch mask patterns. The second-tier pillar cavities have the same depth as the deepest portion of the second-tier stepped cavities. Thus, the second-tier pillar cavities may have a uniform depth that equals the vertical distance between the second horizontal plane HP2 and the third horizontal plane HP3. The maximum depth of each second-tier stepped cavity may be equal to the vertical distance between the second horizontal plane HP2 and the third horizontal plane HP3. In other words, the second-tier pillar cavities may extend through all layers of the second tier.

Each of the second-tier pillar cavities may be aligned to and may have an areal overlap with a respective pair of underlying sacrificial first-tier dielectric pillar structures 126 and a portion of a respective underlying sacrificial first-tier wall structure 178. In one embodiment, top surface segments of each of the sacrificial first-tier wall structures 178 may be physically exposed underneath a respective subset of the second-tier pillar cavities. Alternatively, a first subset of the sacrificial first-tier wall structures 178 may be physically exposed underneath the second-tier pillar cavities, while a second subset of the sacrificial first-tier wall structures 178 is not exposed to any second-tier pillar cavity. In the example illustrated in FIGS. 7A-7C, every other sacrificial first-tier wall structure 178 along the second horizontal direction (e.g., bit line direction) hd2 comprises top surface segments that are exposed to a respective row of second-tier pillar cavities.

The processing steps described with reference to FIGS. 2A-3E may be performed to locally thicken the physically exposed horizontally-extending portions of the second continuous sacrificial material layers 242. Physically exposed vertically extending surfaces of the second continuous sacrificial material layers 242 around the second-tier pillar cavities are not thickened during the local thickening of the physically exposed horizontally extending portions of the second continuous sacrificial material layers 242 due to the mechanisms described with reference to FIGS. 2A-3E.

A dielectric fill material can be deposited within each of the second-tier stepped cavities and in the second-tier pillar cavities. Excess portions of the dielectric fill material can be removed from above the third horizontal plane HP3 by performing a planarization process, which may comprise a chemical mechanical polishing process or a recess etch process. Each remaining portion of the dielectric fill material that fills a respective second-tier stepped cavity constitutes a second-tier retro-stepped dielectric material portion 265. Each remaining portion of the dielectric fill material that fills a respective one of the second-tier pillar cavities constitutes a second-tier dielectric pillar structure 226. A second-tier structure is formed, which comprises the second-tier vertically alternating sequence (232, 242), the second-tier retro-stepped dielectric material portions 265, and the second-tier dielectric pillar structures 226.

The horizontal cross-sectional shape of the second-tier dielectric pillar structures 226 may be any two-dimensional shape having a closed periphery. For example, the horizontal cross-sectional shapes of the second-tier dielectric pillar structures 226 may be a polygon (such as rectangle, a rhombus, a hexagon, etc.), a rounded polygon (i.e., a shape that is derived from a polygon by rounding at least one corner), a circle, an oval, or any other suitable two-dimensional shape. In the illustrated example, the shape of each second-tier dielectric pillar structure is a rounded rhombus. Generally, the shapes of the second-tier retro-stepped dielectric material portions 265 and the second-tier dielectric pillar structures 226 are selected such that the second-tier vertically alternating stack (232, 242) is not completely cut along the first horizontal direction hd1.

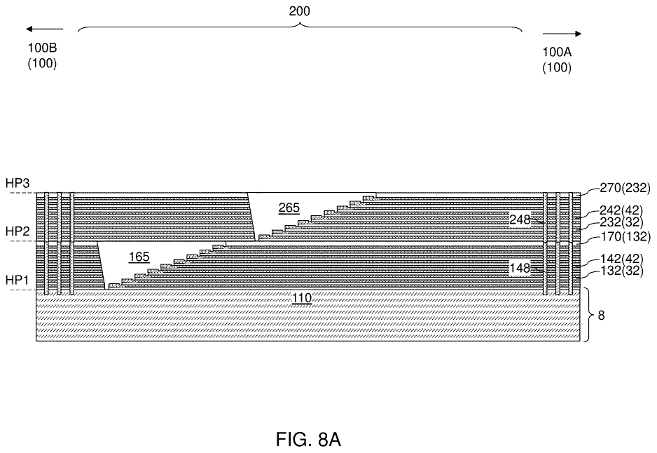

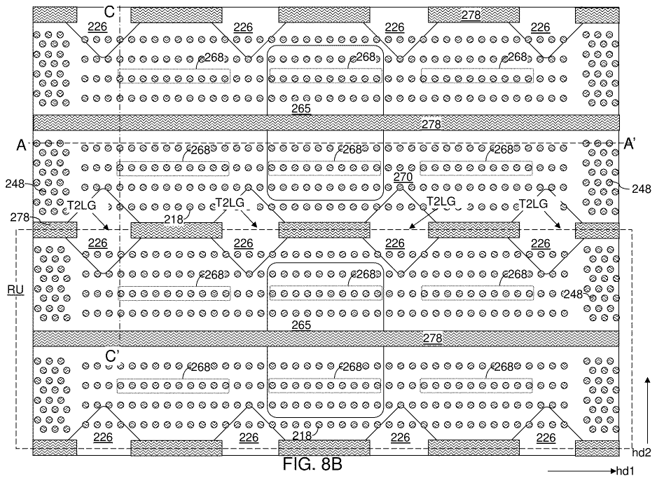

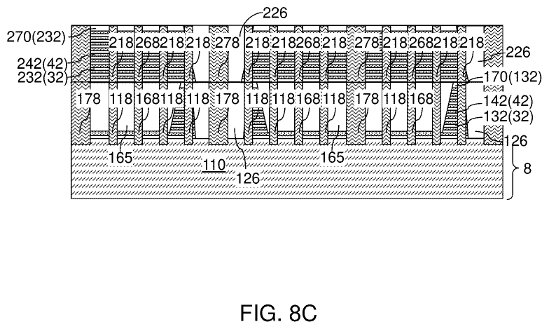

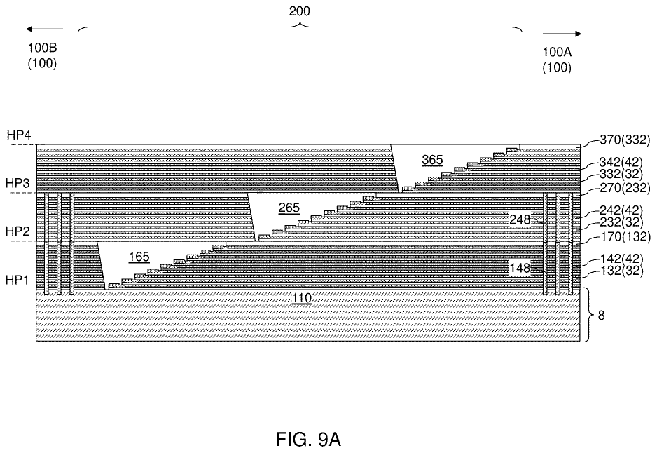

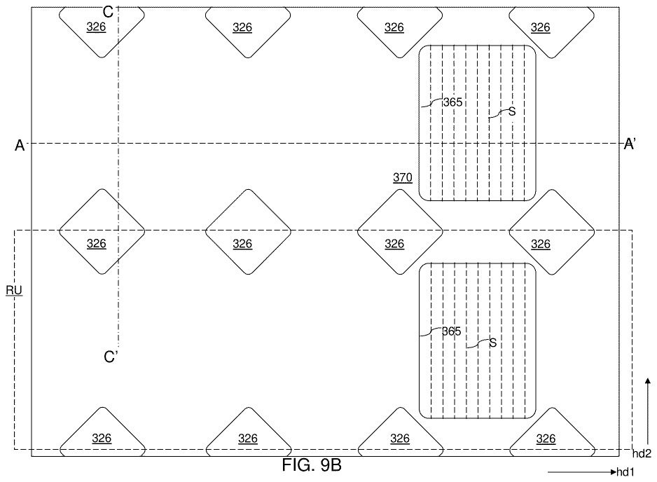

Referring to FIGS. 8A-8C, various second-tier openings can be formed through the second-tier structure (232, 242, 265). A photoresist layer (not shown) can be applied over the second insulating cap layer 270, and can be lithographically patterned to form various openings therethrough. The pattern of openings in the photoresist layer can be transferred through the second-tier structure (232, 242, 265) by a second anisotropic etch process to form the various second-tier openings concurrently. The various second-tier openings can include second-tier memory openings, second-tier support openings, sacrificial second-tier contact openings, and second-tier lateral isolation trenches.

The second-tier memory openings are formed in the memory array regions 100 through each layer within the second-tier vertically alternating sequence (232, 242). The second-tier memory openings are subsequently employed to form memory stack structures therein. The second-tier memory openings can be formed in clusters that are laterally spaced apart along the second horizontal direction hd2. Each cluster of second-tier memory openings can be formed as a two-dimensional array of second-tier memory openings. In one embodiment, each second-tier memory opening may be aligned to a respective sacrificial first-tier memory opening fill structure 148.

The second-tier lateral isolation trenches may have a respective rectangular shape that is elongated along the first horizontal direction hd1. According to an aspect of the present disclosure, each of the second-tier lateral isolation trenches may be aligned to, and may have an areal overlap with, a respective pair of underlying first-tier dielectric pillar structures 126 and a respective underlying sacrificial first-tier wall structure 178. According to an aspect of the present disclosure, each of the second-tier lateral isolation trenches may be formed entirely within the area of a respective underlying sacrificial first-tier wall structure 178. The areas of the second-tier lateral isolation trenches can be selected such that the combination of the second-tier lateral isolation trenches and the second-tier dielectric pillar structures 226 divide the second-tier vertically alternating sequence (232, 242) of second continuous insulating layers 232 and second continuous sacrificial material layers 242 into a plurality of second-tier alternating stacks (232, 242) of second insulating layers 232 and second sacrificial material layers 242.

In one embodiment shown in FIG. 8B, for each sacrificial first-tier wall structure 178 within a first subset of the sacrificial first-tier wall structures 178, a respective row of multiple second-tier lateral isolation trenches may be formed entirely within the area of the sacrificial first-tier wall structure 178 in a plan view (such as a top-down view). The multiple second-tier lateral isolation trenches are aligned along the second horizontal direction hd2, and are laterally spaced apart from each other by at least one lateral gap, which is herein referred to as at least one second-tier lateral gap T2LG. Each second-tier lateral gap T2LG may be located entirely within the area of a respective second-tier dielectric pillar structure 226. In other words, each laterally neighboring pair of second-tier lateral isolation trenches may cut into peripheral portions of an intervening second-tier dielectric pillar structure 226 such that the entire area of a second-tier lateral gap T2LG may be located entirely within the intervening second-tier dielectric pillar structure 226.

In one embodiment shown in FIG. 8B, each second-tier lateral isolation trench may comprise a pair of lengthwise sidewalls that are parallel to the first horizontal direction hd1, and a pair of end walls that are parallel to the second horizontal direction hd2. In one embodiment, for each laterally neighboring pair of second-tier lateral isolation trenches laterally separated along the first horizontal direction hd1 by an intervening second-tier dielectric pillar structure 226, end portions of each lengthwise sidewall of the laterally neighboring pair of second-tier lateral isolation trenches and two end walls of the laterally neighboring pair of second-tier lateral isolation trenches are defined by straight sidewalls of the intervening second-tier dielectric pillar structure 226. In other words, the ends of the second-tier lateral isolation trenches cut into a pair of dielectric pillar structures 226, such that the walls of the ends of the trenches comprise sidewalls of the dielectric pillar structure 226 exposed in the trenches.

In one embodiment, each second-tier alternating stack (232, 242) of second insulating layers 232 and second sacrificial material layers 242 may be laterally bounded by a second-tier lateral isolation trench that laterally extends through the first memory array region 100A, the inter-array region 200, and the second memory array region 100B on one side, and by a laterally alternating sequence of a plurality of second-tier lateral isolation trenches interlaced with at least one second-tier dielectric pillar structure 226 on the other side. In one embodiment, the laterally alternating sequence of the plurality of second-tier lateral isolation trenches interlaced with the at least one second-tier dielectric pillar structure 226 may comprise a laterally alternating sequence of the plurality of second-tier lateral isolation trenches interlaced with a plurality of second-tier dielectric pillar structure 226. Each second-tier alternating stack (232, 242) continuously extends from the first memory array region 100A through the inter-array region 200 to the second memory array region 100B as a single continuous structure.

The sacrificial second-tier contact openings can be formed through the second-tier retro-stepped dielectric material portions 265 and through a respective horizontally-extending surface segment of the second stepped surfaces. The second-tier support openings can be formed in the inter-array region 200 in areas that are not filled with the sacrificial second-tier contact openings.

A sacrificial fill material can be deposited in the various second-tier openings to form various sacrificial second-tier opening fill structures. The various sacrificial second-tier opening fill structures comprise sacrificial second-tier memory opening fill structures 248 that are formed in the second-tier memory openings, sacrificial second-tier support opening fill structures 218 that are formed in the second-tier support openings, sacrificial second-tier contact opening fill structures 268 that are formed in the second-tier contact openings, and sacrificial second-tier wall structures 278 that are formed in the second-tier lateral isolation trenches. The sacrificial fill material in the various sacrificial second-tier opening fill structures comprises a material that is different from the materials of the second insulating layers 232 and the second sacrificial material layers 242. For example, the sacrificial fill material in the various sacrificial second-tier opening fill structures may comprise a semiconductor material (such as amorphous silicon or silicon-germanium).

Each sacrificial second-tier memory opening fill structure 248 may be formed on a top surface of, may be aligned to, and may have an areal overlap in the plan view with a respective sacrificial first-tier memory opening fill structure 148. Each sacrificial second-tier support opening fill structure 218 may be formed on a top surface of, may be aligned to, and may have an areal overlap in the plan view with a respective sacrificial first-tier support opening fill structure 118. Each sacrificial second-tier contact opening fill structure 268 may be formed on a top surface of, may be aligned to, and may have an areal overlap in the plan view with a respective sacrificial first-tier contact opening fill structure 168. Each sacrificial second-tier wall structure 278 may be formed on a top surface of, may be aligned to, and may have an areal overlap in the plan view, with a respective sacrificial first-tier wall structure 178.

The first exemplary structure comprises multi-tier layer stacks {(132, 142), (232, 242)} laterally extending along a first horizontal direction hd1 and laterally spaced apart from each other along a second horizontal direction hd2 by lateral spacer structures (178, 278, 165, 265, 226). Each of the multi-tier layer stacks {(132, 142), (232, 242)} comprises a first-tier alternating stack (132, 142) of first insulating layers 132 and first sacrificial material layers 142, and further comprises a second-tier alternating stack (232, 242) of second insulating layers 232 and second sacrificial material layers 242 that overlies the first-tier alternating stack (132, 142). The first exemplary structure comprises a first memory array region 100A and a second memory array region 100B that are laterally spaced apart from each other along the first horizontal direction hd1 by an inter-array region 200. All layers within each multi-tier alternating stack among the multi-tier layer stacks {(132, 142), (232, 242)} are present in the first memory array region 100A and in the second memory array region 100B. Each multi-tier alternating stack of the multi-tier layer stacks {(132, 142), (232, 242)} comprises a respective set of stepped surfaces in the inter-array region 200.

In one embodiment, a first lateral spacer structure (178, 278, 165, 265, 226) of the lateral spacer structures (178, 278, 165, 265, 226) comprises a combination of a sacrificial first-tier wall structure 178, at least one sacrificial second-tier wall structure 278, and at least one second-tier dielectric material portion, which may comprise at least one second-tier retro-stepped dielectric material portion 265 (such as a pair of second-tier retro-stepped dielectric material portions 265) and/or at least one second-tier dielectric pillar structure 226.

Each sacrificial first-tier wall structure 178 continuously extends from the first memory array region 100A to the second memory array region 100B through the inter-array region 200 at a first-tier level of the first-tier alternating stacks (132, 142) within the multi-tier layer stacks {(132, 142), (232, 242)}. Each set of sacrificial second-tier wall structures 278 located on a same sacrificial first-tier wall structure 178 comprises at least one second-tier lateral gap T2LG at a second-tier level of the second-tier alternating stacks (232, 242). Each of the second-tier dielectric pillar structures 226 may be located in the respective second-tier lateral gap T2LG.

In one embodiment, each lateral spacer structure (178, 278, 165, 265, 226) provides a continuous dielectric barrier throughout the first memory array region 100A, the second memory array region 100B, and the inter-array region 200 between a neighboring pair of a first multi-tier layer stack {(132, 142), (232, 242)} and a second multi-tier layer stack {(132, 142), (232, 242)}. In one embodiment, each lateral spacer structure (178, 278, 165, 265, 226) may comprise at least one second-tier dielectric pillar structure 226. In one embodiment, each second-tier dielectric pillar structure 226 has a greater width along the second horizontal direction hd2 than the sacrificial first-tier wall structure 178 and the sacrificial second-tier wall structures 278 in the respective lateral spacer structure (178, 278, 165, 265, 226).

In one embodiment, each second-tier dielectric pillar structure 226 overlies a neighboring pair of first-tier alternating stacks (132, 142) within a neighboring pair of multi-tier layer stacks {(132, 142), (232, 242)}. In one embodiment, first-tier retro-stepped dielectric material portions 165 may be embedded within a respective one of the first-tier alternating stacks (132, 142). The first-tier retro-stepped dielectric material portions 165 may be components of the lateral spacer structures (178, 278, 165, 265, 226).

In one embodiment, bottommost surfaces of the first-tier alternating stacks (132, 142) are located in a first horizontal plane HP1, and bottommost surfaces of the second-tier alternating stacks (232, 242) are located in a second horizontal plane HP2. In one embodiment, each sacrificial first-tier wall structure 178 comprises at least one horizontal surface segment located in the second horizontal plane HP2 and contacting each of the at least one second-tier dielectric material portion (265, 226) in the same lateral spacer structure (178, 278, 165, 265, 226). The at least one second-tier dielectric material portion (265, 226) may comprise a second-tier retro-stepped dielectric material portion 265 or at least one second-tier dielectric pillar structure 226.

In one embodiment, top surfaces of the second-tier alternating stacks (232, 242) are located in a third horizontal plane HP3, and each of the at least one second-tier dielectric material portion (which comprise a second-tier retro-stepped dielectric material portion 265 or as a second-tier dielectric pillar structure 226) has a respective top surface located in the third horizontal plane HP3.

In one embodiment, each sacrificial first-tier wall structure 178 can be located between the first horizontal plane HP1 and the second horizontal plane HP2, and can continuously extend between the first memory array region 100A and the second memory array region 100B without any gap therein. In one embodiment, a set of sacrificial second-tier wall structures 278 can overlie a single sacrificial first-tier wall structure 178, can be located entirely between the second horizontal plane HP2 and a third horizontal plane HP3, and can be laterally spaced apart among one another by the at least one second-tier lateral gap T2LG. In one embodiment, each of the at least one second-tier lateral gap T2LG vertically extends from the second horizontal plane HP2 to the third horizontal plane HP3.

In one embodiment, each second-tier dielectric pillar structure 226 contacts end segments of lengthwise sidewalls and an end sidewall of each second-tier portion within a respective laterally neighboring pair of sacrificial second-tier wall structures 278. The lengthwise sidewalls of each of the sacrificial second-tier wall structures 278 are parallel to the first horizontal direction hd1, and the end sidewalls of each of the sacrificial second-tier wall structures 278 are parallel to the second horizontal direction hd2. All sidewalls of each second-tier dielectric pillar structure 226 vertically extend straight without any lateral step between a horizontal plane including bottommost surfaces of the second-tier alternating stacks (232, 242) and a horizontal plane including topmost surfaces of the second-tier alternating stacks (232, 242).

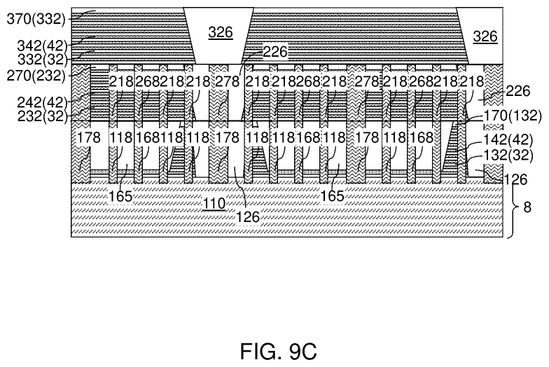

Referring to FIGS. 9A-9C, a third-tier vertically alternating sequence of third insulating layers 332 and third sacrificial material layers 342 can be formed over the second-tier structure. Each of the third insulating layers 332 may be formed as a single continuous material layer, and thus, may be referred to as a third continuous insulating layer. Each of the third sacrificial material layers 342 may be formed as a single continuous material layer, and thus, may be formed as a third continuous sacrificial material layer. Each of the third insulating layers 332 and the third sacrificial material layers 342 may have a thickness in a range from 20 nm to 80 nm, although lesser and greater thicknesses may also be employed.

In one embodiment, the third-tier vertically alternating sequence of third insulating layers 332 and third sacrificial material layers 342 may include a periodic repetition of a unit layer stack including a third insulating layer 332 and a third sacrificial material layer 342. The total number of repetitions of the unit layer stack may be in a range from 4 to 1,024, such as from 16 to 256, although lesser and greater numbers of repetitions may also be employed.

The third insulating layers 332 may comprise, and/or may consist essentially of, an insulating material such as undoped silicate glass or a doped silicate glass. The third sacrificial material layers 342 may comprise, and/or may consist essentially of, a sacrificial material such as silicon nitride, a silicon-germanium alloy, organosilicate glass, or a polymer material. Generally, the third sacrificial material layers 342 comprise a material that may be removed selectively to the materials of the third insulating layers 332 and the semiconductor material layer 110. The third insulating layers 332 may comprise the same material as the first insulating layers 132 and the second insulating layers 232, and the third sacrificial material layers 342 may comprise the same material as the first sacrificial material layers 142 and the second sacrificial material layers 242. The topmost third insulating layer 332 is herein referred to as a third insulating cap layer 370.

A third patterned hard mask layer (not shown) may be formed over the third-tier vertically alternating sequence (332, 342) to define areas in which third-tier stepped surfaces are to be subsequently formed. A third trimmable etch mask layer (not shown) can be formed over the third patterned hard mask layer, and can be lithographically patterned to form slit-shaped openings over peripheral regions of the openings in the third patterned hard mask layer. A unit processing sequence can be repeatedly performed to form third-tier stepped surfaces in the third-tier vertically alternating sequence (332, 342) within the areas of openings in the third patterned hard mask layer. For example, the unit processing sequence may comprise an anisotropic etch process that etches a pair of a third insulating layer 332 and a third sacrificial material layer 342 and a trimming process that isotropically trims the third trimmable etch mask layer. The number of repetitions of the unit processing sequence may be the same as the total number of third sacrificial material layers 342 in the third-tier vertically alternating sequence (332, 342). A third-tier stepped cavity overlying a respective set of third-tier stepped surfaces of the third-tier vertically alternating sequence (332, 342) can be formed within each patterned area of the third-tier vertically alternating sequence (332, 342).

In one embodiment, the vertical steps within each third-tier stepped cavity may be laterally spaced from each other along the first horizontal direction hd1 (which may be a word line direction). In one embodiment, the third-tier stepped cavities may be arranged along a second horizontal direction hd2 (which may be a bit line direction). In one embodiment, the first exemplary structure may have a periodic pattern that repeats along the first horizontal direction hd1. Specifically, a repetition unit RU is repeated along the second horizontal direction hd2. In one embodiment, each repetition unit RU may comprise a third-tier stepped cavity. Physically exposed portions of the third continuous sacrificial material layers 342 can be locally thickened underneath the third-tier stepped cavities.

According to an aspect of the present disclosure, each mask pattern in the various etch masks employed to form the third-tier stepped cavities includes additional openings. In one embodiment, the additional openings are arranged as a two-dimensional array of openings located at the same locations as the second-tier dielectric pillar structures 226. The pattern of the additional openings in each etch mask pattern may be identical. Thus, the areas of the additional openings in the etch mask patterns are exposed to all anisotropic etch processes that are employed to form the third-tier stepped cavities. Third-tier pillar cavities are formed within the areas of the additional openings in the etch mask patterns. The third-tier pillar cavities have the same depth as the deepest portion of the third-tier stepped cavities. Thus, the third-tier pillar cavities may have a uniform depth that equals the vertical distance between the third horizontal plane HP3 and the fourth horizontal plane HP4. The maximum depth of each third-tier stepped cavity may be equal to the vertical distance between the third horizontal plane HP3 and the fourth horizontal plane HP4. In other words, the third-tier pillar cavities may extend through all layers of the third tier.

Each of the third-tier pillar cavities may be aligned to, and may have an areal overlap with, a respective underlying sacrificial second-tier wall structure 278. In one embodiment, top surface segments of each of the sacrificial second-tier wall structures 278 may be physically exposed underneath a respective subset of the third-tier pillar cavities. Alternatively, a first subset of the sacrificial second-tier wall structures 278 may be physically exposed underneath the third-tier pillar cavities, while a second subset of the sacrificial second-tier wall structures 278 is not exposed to any third-tier pillar cavity. In the example illustrated in FIGS. 9A-9C, every other sacrificial second-tier wall structure 278 along the second horizontal direction hd2 comprises top surface segments that are exposed to a respective row of third-tier pillar cavities.

The processing steps described with reference to FIGS. 2A-3E may be performed to locally thicken the physically exposed horizontally-extending portions of the third continuous sacrificial material layers 342. Physically exposed vertically extending surfaces of the third continuous sacrificial material layers 342 around the second-tier pillar cavities are not thickened during the local thickening of the physically exposed horizontally extending portions of the third continuous sacrificial material layers 342 due to the mechanisms described with reference to FIGS. 2A-3E.

A dielectric fill material can be deposited within each of the third-tier stepped cavities and in the third-tier pillar cavities. Excess portions of the dielectric fill material can be removed from above the fourth horizontal plane HP4 by performing a planarization process, which may comprise a chemical mechanical polishing process or a recess etch process. Each remaining portion of the dielectric fill material that fills a respective third-tier stepped cavity constitutes a third-tier retro-stepped dielectric material portion 365. Each remaining portion of the dielectric fill material that fills a respective one of the third-tier pillar cavities constitutes a third-tier dielectric pillar structure 326. A third-tier structure is formed, which comprises the third-tier vertically alternating sequence (332, 342), the third-tier retro-stepped dielectric material portions 365, and the third-tier dielectric pillar structures 326.

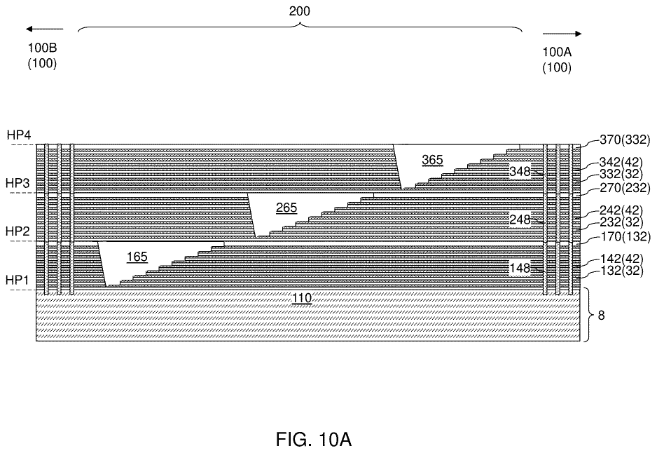

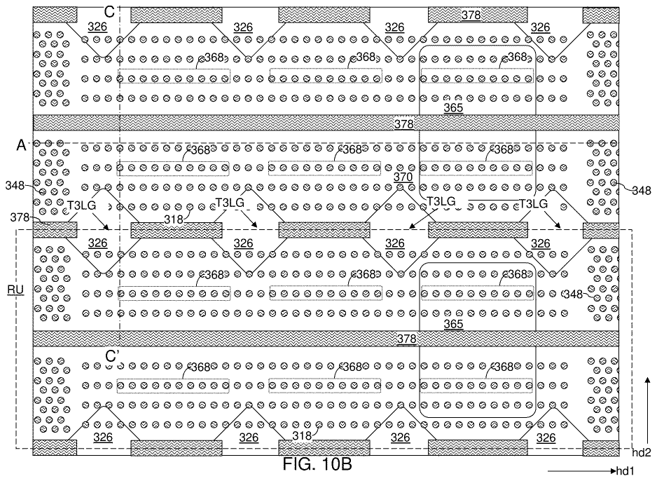

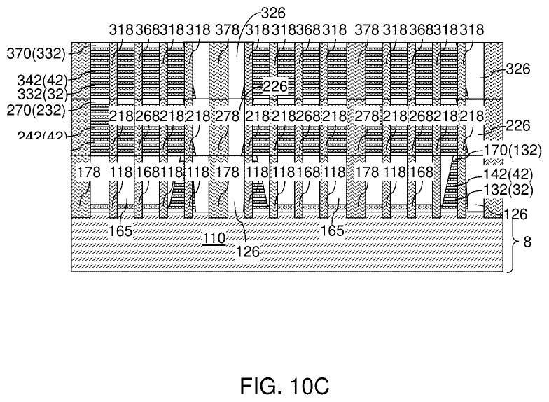

Referring to FIGS. 10A-10C, various third-tier openings can be formed through the third-tier structure (332, 342, 365). A photoresist layer (not shown) can be applied over the third insulating cap layer 370, and can be lithographically patterned to form various openings therethrough. The pattern of openings in the photoresist layer can be transferred through the third-tier structure (332, 342, 365) by a third anisotropic etch process to form the various third-tier openings concurrently. The various third-tier openings can include third-tier memory openings, third-tier support openings, sacrificial third-tier contact openings, and third-tier lateral isolation trenches.

The third-tier memory openings are formed in the memory array regions 100 through each layer within the third-tier vertically alternating sequence (332, 342). The third-tier memory openings are subsequently employed to form memory stack structures therein. The third-tier memory openings can be formed in clusters that are laterally spaced apart along the second horizontal direction hd2. Each cluster of third-tier memory openings can be formed as a two-dimensional array of third-tier memory openings.

The third-tier lateral isolation trenches may have a respective rectangular shape that is elongated along the first horizontal direction hd1. Each third-tier lateral isolation trench may laterally extend through the entirety of the first memory array region 100A, the inter-array region 200, and the second memory array region 100B. Thus, the third-tier vertically alternating sequence is divided into a plurality of third alternating stacks (332, 342) of respective third insulating layers 332 and respective third sacrificial material layers 342.

In one embodiment, a subset of the third-tier lateral isolation trenches may divide a respective third-tier retro-stepped dielectric material portion 365 into two discrete third-tier retro-stepped dielectric material portions 365. In one embodiment, the first exemplary structure may include a periodic repetition of a unit pattern that is repeated along the second horizontal direction hd2. The set of all structural elements within a unit pattern is herein referred to as a repetition unit RU. Each repetition unit RU may comprise a patterned portion of a third-tier retro-stepped dielectric material portion 365. Each repetition unit RU may comprise two third-tier alternating stacks of third insulating layers 332 and third sacrificial material layers 342.

The sacrificial third-tier contact openings can be formed through the third-tier retro-stepped dielectric material portions 365 and through a respective horizontally-extending surface segment of the third stepped surfaces. The third-tier support openings can be formed in the inter-array region 200 in areas that are not filled with the sacrificial third-tier contact openings.

A sacrificial fill material can be deposited in the various third-tier openings to form various sacrificial third-tier opening fill structures. The various sacrificial third-tier opening fill structures comprise sacrificial third-tier memory opening fill structures 348 that are formed in the third-tier memory openings, sacrificial third-tier support opening fill structures 318 that are formed in the third-tier support openings, sacrificial third-tier contact opening fill structures 368 that are formed in the third-tier contact openings, and sacrificial third-tier wall structures 378 that are formed in the third-tier lateral isolation trenches. The sacrificial fill material in the various sacrificial third-tier opening fill structures comprises a material that is different from the materials of the third insulating layers 332 and the third sacrificial material layers 342. For example, the sacrificial fill material in the various sacrificial third-tier opening fill structures may comprise a semiconductor material (such as amorphous silicon or silicon-germanium).

Each sacrificial third-tier memory opening fill structure 348 may be formed on a top surface of, may be aligned to, and may have an areal overlap in the plan view with, a respective sacrificial second-tier memory opening fill structure 248. Each sacrificial third-tier support opening fill structure 318 may be formed on a top surface of, may be aligned to, and may have an areal overlap in the plan view with, a respective sacrificial second-tier support opening fill structure 218. Each sacrificial third-tier contact opening fill structure 368 may be formed on a top surface of, may be aligned to, and may have an areal overlap in the plan view with, a respective sacrificial second-tier contact opening fill structure 268. Each sacrificial third-tier wall structure 378 may be formed on a top surface of, may be aligned to, and may have an areal overlap in the plan view, with a respective sacrificial second-tier wall structure 278.

The horizontal plane including the bottommost surfaces of the third-tier alternating stacks (332, 342) is herein referred to as a third horizontal plane HP3. The horizontal plane including the topmost surfaces of the third-tier alternating stacks (332, 342) is herein referred to as a fourth horizontal plane HP4.

The first exemplary structure comprises multi-tier layer stacks {(132, 142), (232, 242), (332, 342)} laterally extending along a first horizontal direction hd1 and laterally spaced apart among one another along a second horizontal direction hd2 by lateral spacer structures (178, 278, 378, 165, 265, 365, 126, 226, 326). Each of the multi-tier layer stacks {(132, 142), (232, 242), (332, 342)} comprises a first-tier alternating stack (132, 142) of first insulating layers 132 and first sacrificial material layers 142, a second-tier alternating stack (232, 242) of second insulating layers 232 and second sacrificial material layers 242 that overlies the first-tier alternating stack (132, 142), and a third-tier alternating stack (332, 342) of third insulating layers 332 and third sacrificial material layers 342 that overlies the second-tier alternating stack (232, 242). The first exemplary structure comprises a first memory array region 100A and a second memory array region 100B that are laterally spaced apart from each other along the first horizontal direction hd1 by an inter-array region 200. All layers within each multi-tier alternating stack among the multi-tier layer stacks {(132, 142), (232, 242), (332, 342)} are present in the first memory array region 100A and in the second memory array region 100B. Each multi-tier alternating stack among the multi-tier layer stacks {(132, 142), (232, 242), (332, 342)} comprises a respective set of stepped surfaces in the inter-array region 200.

In one embodiment, a first lateral spacer structure (178, 278, 378, 165, 265, 365, 126, 226, 326) among the lateral spacer structures (178, 278, 378, 165, 265, 365, 126, 226, 326) comprises a combination of a sacrificial first-tier wall structure 178, at least one sacrificial second-tier wall structure 278, at least one sacrificial third-tier wall structure 378, and at least one second-tier dielectric material portion, which may be embodied as at least one second-tier retro-stepped dielectric material portion 265 (such as a pair of second-tier retro-stepped dielectric material portions 265) and/or at least one second-tier dielectric pillar structure 226, and at least one third-tier dielectric material portion, which may be embodied as at least one third-tier retro-stepped dielectric material portion 365 (such as a pair of third-tier retro-stepped dielectric material portions 365) and/or at least one third-tier dielectric pillar structure 326.

Each sacrificial first-tier wall structure 178 continuously extends from the first memory array region 100A to the second memory array region 100B through the inter-array region 200 at a first-tier level of the first-tier alternating stacks (132, 142) within the multi-tier layer stacks {(132, 142), (232, 242), (332, 342)}. Each set of sacrificial second-tier wall structures 278 located on a same sacrificial first-tier wall structure 178 comprises at least one second-tier lateral gap T2LG at a second-tier level of the second-tier alternating stacks (232, 242). Each of the second-tier dielectric pillar structures 226 may be located at a respective second-tier lateral gap T2LG among the at least one second-tier lateral gap T2LG. Each set of sacrificial third-tier wall structures 378 located on a same sacrificial second-tier wall structure 278 comprises at least one third-tier lateral gap T3LG at a third-tier level of the third-tier alternating stacks (332, 342). Each of the third-tier dielectric pillar structures 326 may be located at a respective third-tier lateral gap T3LG among the at least one third-tier lateral gap T3LG.

In one embodiment, each lateral spacer structure (178, 278, 378, 165, 265, 365, 126, 226, 326) provides a continuous dielectric barrier throughout the first memory array region 100A, the second memory array region 100B, and the inter-array region 200 between a neighboring pair of a first multi-tier layer stack {(132, 142), (232, 242), (332, 342)} and a second multi-tier layer stack {(132, 142), (232, 242), (332, 342)} among the multi-tier layer stacks {(132, 142), (232, 242), (332, 342)}. In one embodiment, each lateral spacer structure (178, 278, 378, 165, 265, 365, 126, 226, 326) may comprise at least one second-tier dielectric pillar structure 226 and at least one third-tier dielectric pillar structure 326. In one embodiment, each second-tier dielectric pillar structure 226 has a greater width along the second horizontal direction hd2 than the sacrificial first-tier wall structure 178 and the sacrificial second-tier wall structures 278 in a respective lateral spacer structure (178, 278, 378, 165, 265, 365, 126, 226, 326). In one embodiment, each third-tier dielectric pillar structure 326 has a greater width along the second horizontal direction hd2 than the sacrificial first-tier wall structure 178, the sacrificial second-tier wall structures 278, and the sacrificial third-tier wall structures 378 in a respective lateral spacer structure (178, 278, 378, 165, 265, 365, 126, 226, 326).

In one embodiment, each second-tier dielectric pillar structure 226 overlies a neighboring pair of first-tier alternating stacks (132, 142) within a neighboring pair of multi-tier layer stacks {(132, 142), (232, 242), (332, 342)}. In one embodiment, each third-tier dielectric pillar structure 326 overlies a neighboring pair of second-tier alternating stacks (232, 242) within a neighboring pair of multi-tier layer stacks {(132, 142), (232, 242), (332, 342)}. In one embodiment, first-tier retro-stepped dielectric material portions 165 may be embedded within a respective one of the first-tier alternating stacks (132, 142). The first-tier retro-stepped dielectric material portions 165 may be components of the lateral spacer structures (178, 278, 378, 165, 265, 365, 126, 226, 326).

In one embodiment, bottommost surfaces of the first-tier alternating stacks (132, 142) are located in a first horizontal plane HP1, bottommost surfaces of the second-tier alternating stacks (232, 242) are located in a second horizontal plane HP2, and bottommost surfaces of the third-tier alternating stacks (332, 342) are located in a third horizontal plane HP3. In one embodiment, each sacrificial first-tier wall structure 178 comprises at least one horizontal surface segment located in the second horizontal plane HP2 and contacting each of the at least one second-tier dielectric material portion (265, 226) in the same lateral spacer structure (178, 278, 378, 165, 265, 365, 126, 226, 326). The at least one second-tier dielectric material portion (265, 226) may comprise a second-tier retro-stepped dielectric material portion 265 or at least one second-tier dielectric pillar structure 226. In one embodiment, each sacrificial second-tier wall structure 278 comprises at least one horizontal surface segment located in the third horizontal plane HP3 and contacting each of the at least one third-tier dielectric material portion (365, 326) in the same lateral spacer structure (178, 278, 378, 165, 265, 365, 126, 226, 326). The at least one third-tier dielectric material portion (365, 326) may comprise a third-tier retro-stepped dielectric material portion 365 or at least one third-tier dielectric pillar structure 326.

In one embodiment, top surfaces of the third-tier alternating stacks (332, 342) are located in a fourth horizontal plane HP4, and each of the at least one third-tier dielectric material portion (which may be embodied as a third-tier retro-stepped dielectric material portion 365 or as a third-tier dielectric pillar structure 326) has a respective top surface located in the fourth horizontal plane HP4.

In one embodiment, each sacrificial first-tier wall structure 178 can be located between the first horizontal plane HP1 and the second horizontal plane HP2, and can continuously extend between the first memory array region 100A and the second memory array region 100B without any gap therein. In one embodiment, a set of sacrificial second-tier wall structures 278 overlying a respective sacrificial first-tier wall structure 178 can be located between the second horizontal plane HP2 and the third horizontal plane HP3, and can be laterally spaced apart among one another by the at least one second-tier lateral gap T2LG. In one embodiment, each of the at least one second-tier lateral gap T2LG vertically extends from the second horizontal plane HP2 to the third horizontal plane HP3. In one embodiment, a set of sacrificial third-tier wall structures 378 overlying a respective sacrificial second-tier wall structure 278 can be located between the third horizontal plane HP3 and the fourth horizontal plane HP4, and can be laterally spaced apart among one another by the at least one third-tier lateral gap T3LG. In one embodiment, each of the at least one third-tier lateral gap T3LG vertically extends from the third horizontal plane HP3 to the fourth horizontal plane HP4.

In one embodiment, each second-tier dielectric pillar structure 226 contacts end segments of lengthwise sidewalls and an end sidewall of each second-tier portion within a respective laterally neighboring pair of sacrificial second-tier wall structures 278. The lengthwise sidewalls of each of the sacrificial second-tier wall structures 278 are parallel to the first horizontal direction hd1, and the end sidewalls of each of the sacrificial second-tier wall structures 278 are parallel to the second horizontal direction hd2. All sidewalls of each second-tier dielectric pillar structure 226 vertically extend straight without any lateral step between a horizontal plane including bottommost surfaces of the second-tier alternating stacks (232, 242) and a horizontal plane including topmost surfaces of the second-tier alternating stacks (232, 242).

In one embodiment, each third-tier dielectric pillar structure 326 contacts end segments of lengthwise sidewalls and an end sidewall of each third-tier portion within a respective laterally neighboring pair of sacrificial third-tier wall structures 378. The lengthwise sidewalls of each of the sacrificial third-tier wall structures 378 are parallel to the first horizontal direction hd1, and the end sidewalls of each of the sacrificial third-tier wall structures 378 are parallel to the second horizontal direction hd2. All sidewalls of each third-tier dielectric pillar structure 326 vertically extend straight without any lateral step between a horizontal plane including bottommost surfaces of the third-tier alternating stacks (332, 342) and a horizontal plane including topmost surfaces of the third-tier alternating stacks (332, 342).

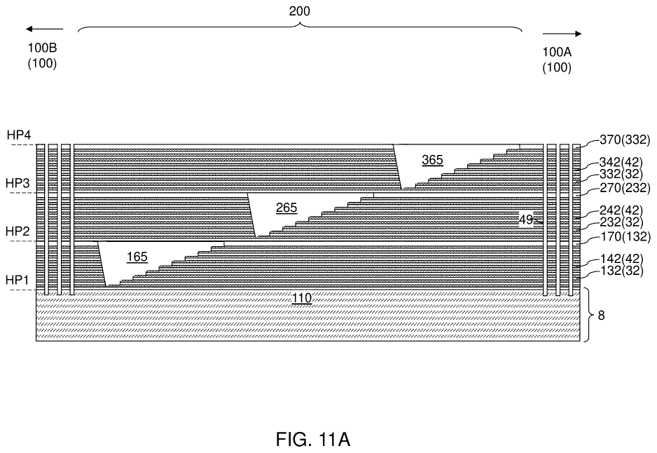

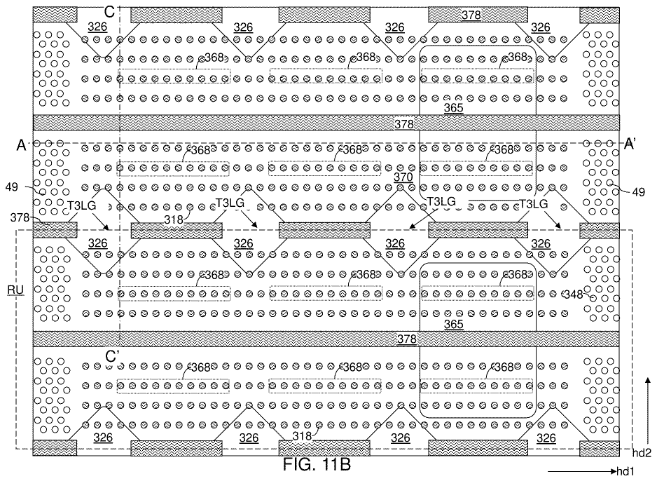

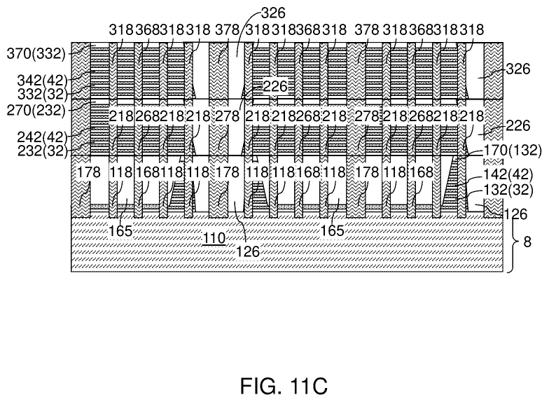

Referring to FIG. 11A-11C, a masking layer, such as a photoresist layer (not shown), can be deposited over the structure of FIG. 10A-10C, and patterned to form openings in the areas of the sacrificial third-tier memory opening fill structures 348, the sacrificial second-tier memory opening fill structures 248, and the sacrificial first-tier memory opening fill structures 148 while covering all other sacrificial fill material portions. The sacrificial third-tier memory opening fill structures 348, the sacrificial second-tier memory opening fill structures 248, and the sacrificial first-tier memory opening fill structures 148 are removed selectively to the alternating stacks of insulating layers (132, 232, 332) and sacrificial material layers (142, 242, 342) and selectively to the semiconductor material layer 110. An isotropic etch process or an anisotropic etch process may be performed. Inter-tier memory openings 49 are formed in volumes from which the sacrificial memory opening fill structures (348, 248, 148) are removed. Each of the inter-tier memory openings 49 vertically extends through a respective first alternating stack (132, 142), a respective second alternating stack (232, 242), and a respective third alternating stack (332, 342). The inter-tier memory openings 49 are formed in the memory array regions 100. The inter-tier memory openings 49 may also be referred to as memory openings 49. The photoresist layer may then be removed by ashing or another suitable method.

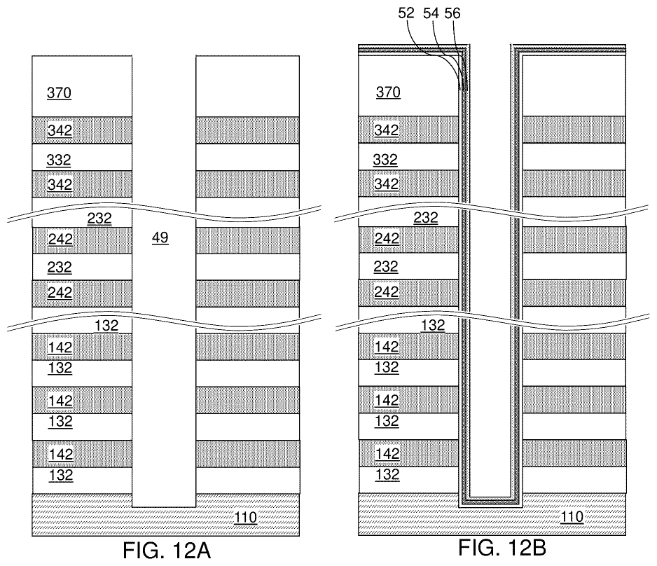

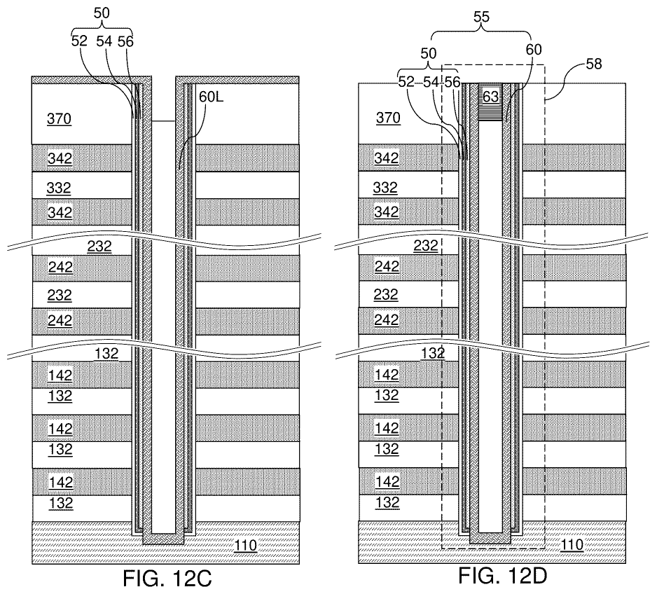

FIG. 12A-12D illustrate sequential vertical cross-sectional views of a memory opening 49 during formation of a memory opening fill structure according to an embodiment of the present disclosure.

Referring to FIG. 12A, a memory opening 49 in the first exemplary structure of FIG. 11A-11C is illustrated. The memory opening 49 extends through a first-tier structure, a second-tier structure, and a third-tier structure.

Referring to FIG. 12B, a stack of layers including an optional blocking dielectric layer 52, a memory material layer 54, an optional dielectric liner 56, and a semiconductor channel material layer 60L can be sequentially deposited in the memory openings 49. The blocking dielectric layer 52 can include a single dielectric material layer or a stack of a plurality of dielectric material layers. In one embodiment, the blocking dielectric layer can include a dielectric metal oxide layer consisting essentially of a dielectric metal oxide. As used herein, a dielectric metal oxide refers to a dielectric material that includes at least one metallic element and at least oxygen. The dielectric metal oxide may consist essentially of the at least one metallic element and oxygen, or may consist essentially of the at least one metallic element, oxygen, and at least one non-metallic element such as nitrogen. In one embodiment, the blocking dielectric layer 52 can include a dielectric metal oxide having a dielectric constant greater than 7.9, i.e., having a dielectric constant greater than the dielectric constant of silicon nitride. The thickness of the dielectric metal oxide layer can be in a range from 1 nm to 20 nm, although lesser and greater thicknesses can also be employed. The dielectric metal oxide layer can subsequently function as a dielectric material portion that blocks leakage of stored electrical charges to control gate electrodes. In one embodiment, the blocking dielectric layer 52 includes aluminum oxide. Alternatively or additionally, the blocking dielectric layer 52 can include a dielectric semiconductor compound such as silicon oxide, silicon oxynitride, silicon nitride, or a combination thereof.

Subsequently, the memory material layer 54 can be formed. Generally, the memory material layer may comprise any memory material such as a charge storage material, a ferroelectric material, a phase change material, or any material that can store data bits in the form of presence or absence of electrical charges, a direction of ferroelectric polarization, electrical resistivity, or another measurable physical parameter. In one embodiment, the memory material layer 54 can be a continuous layer or patterned discrete portions of a charge trapping material including a dielectric charge trapping material, which can be, for example, silicon nitride. Alternatively, the memory material layer 54 can include a continuous layer or patterned discrete portions of a conductive material such as doped polysilicon or a metallic material that is patterned into multiple electrically isolated portions (e.g., floating gates), for example, by being formed within lateral recesses into sacrificial material layers 42. In one embodiment, the memory material layer 54 includes a silicon nitride layer. In one embodiment, the sacrificial material layers 42 and the insulating layers 32 can have vertically coincident sidewalls, and the memory material layer 54 can be formed as a single continuous layer.

The optional dielectric liner 56, if present, includes a dielectric material. In case the memory material layer 54 comprises a charge storage material, the dielectric liner 56 comprises a tunneling dielectric layer through which charge tunneling can be performed under suitable electrical bias conditions. The charge tunneling may be performed through hot-carrier injection or by Fowler-Nordheim tunneling induced charge transfer depending on the mode of operation of the monolithic three-dimensional NAND string memory device to be formed. The dielectric liner 56 can include silicon oxide, silicon nitride, silicon oxynitride, dielectric metal oxides (such as aluminum oxide and hafnium oxide), dielectric metal oxynitride, dielectric metal silicates, alloys thereof, and/or combinations thereof. In one embodiment, the dielectric liner 56 can include a stack of a first silicon oxide layer, a silicon oxynitride layer, and a second silicon oxide layer, which is commonly known as an ONO stack. In one embodiment, the dielectric liner 56 can include a silicon oxide layer that is substantially free of carbon or a silicon oxynitride layer that is substantially free of carbon. The thickness of the dielectric liner 56 can be in a range from 2 nm to 20 nm, although lesser and greater thicknesses can also be employed. The stack of the blocking dielectric layer 52, the memory material layer 54, and the dielectric liner 56 constitutes a memory film 50 that stores memory bits.

Referring to FIG. 12C, an anisotropic etch process can be performed to remove horizontally-extending portions of the dielectric liner 56, the memory material layer 54, and the blocking dielectric layer 52. Each remaining contiguous combination of an optional blocking dielectric layer 52, a memory material layer 54, and an optional dielectric liner 56 constitutes a memory film 50. A top surface of the semiconductor material layer 110 can be physically exposed at the bottom of each memory opening 49.

A semiconductor channel material layer 60L can be conformally deposited over the memory film 50 within each memory opening 49. The semiconductor channel material layer 60L includes a semiconductor material such as at least one elemental semiconductor material, at least one III-V compound semiconductor material, at least one II-VI compound semiconductor material, at least one organic semiconductor material, or other semiconductor materials known in the art. In one embodiment, the semiconductor channel material layer 60L includes amorphous silicon or polysilicon. The semiconductor channel material layer 60L can be formed by a conformal deposition method such as low pressure chemical vapor deposition (LPCVD). The thickness of the semiconductor channel material layer 60L can be in a range from 2 nm to 10 nm, although lesser and greater thicknesses can also be employed. A cavity may be present in the volume of each memory opening 49 that is not filled with the deposited material layers (52, 54, 56, 60L).

In case the cavity in each memory opening is not completely filled by the semiconductor channel material layer 60L, a dielectric core layer can be deposited in the cavity to fill any remaining portion of the cavity within each memory opening. The dielectric core layer includes a dielectric material such as silicon oxide or organosilicate glass. The dielectric core layer can be deposited by a conformal deposition method such as low pressure chemical vapor deposition (LPCVD), or by a self-planarizing deposition process such as spin coating. The horizontal portion of the dielectric core layer overlying the second insulating cap layer 270 can be removed, for example, by a recess etch. The recess etch continues until top surfaces of the remaining portions of the dielectric core layer are recessed to a height between the top surface of the third insulating cap layer 370 and the bottom surface of the third insulating cap layer 370. Each remaining portion of the dielectric core layer constitutes a dielectric core 62.

Referring to FIG. 12D, a doped semiconductor material can be deposited in cavities overlying the dielectric cores 62. The doped semiconductor material has a doping of the opposite conductivity type of the doping of the semiconductor channel material layer 60L. Thus, the doped semiconductor material has a doping of the second conductivity type. Portions of the deposited doped semiconductor material, the semiconductor channel material layer 60L, the dielectric liner 56, the memory material layer 54, and the blocking dielectric layer 52 that overlie the horizontal plane including the top surface of the second insulating cap layer 270 can be removed by a planarization process such as a chemical mechanical planarization (CMP) process.

Each remaining portion of the doped semiconductor material having a doping of the second conductivity type constitutes a drain region 63. The drain regions 63 can have a doping of a second conductivity type that is the opposite of the first conductivity type. For example, if the first conductivity type is p-type, the second conductivity type is n-type, and vice versa. The dopant concentration in the drain regions 63 can be in a range from 5.0×10¹⁸/cm³ to 2.0×10²¹/cm³, although lesser and greater dopant concentrations can also be employed. The doped semiconductor material can be, for example, doped polysilicon.

Each remaining portion of the semiconductor channel material layer 60L constitutes a vertical semiconductor channel 60 through which electrical current can flow when a vertical NAND device including the vertical semiconductor channel 60 is turned on. A dielectric liner 56 is surrounded by a memory material layer 54, and laterally surrounds a vertical semiconductor channel 60. Each adjoining set of a blocking dielectric layer 52, a memory material layer 54, and a dielectric liner 56 collectively constitute a memory film 50, which can store electrical charges with a macroscopic retention time. In some embodiments, a blocking dielectric layer 52 may not be present in the memory film 50 at this step, and a blocking dielectric layer may be subsequently formed after formation of laterally-extending cavities. As used herein, a macroscopic retention time refers to a retention time suitable for operation of a memory device as a permanent memory device such as a retention time in excess of 24 hours.

Each combination of a memory film 50 and a vertical semiconductor channel 60 within a memory opening 49 constitutes a memory stack structure 55. The memory stack structure 55 is a combination of a vertical semiconductor channel 60, a dielectric liner 56, a plurality of memory elements embodied as portions of the memory material layer 54, and an optional blocking dielectric layer 52. Each combination of a memory stack structure 55, a dielectric core 62, and a drain region 63 within a memory opening 49 constitutes a memory opening fill structure 58. In one embodiment, top surfaces of the memory opening fill structures 58 may be formed within a horizontal plane including the top surfaces of the multi-tier layer stacks {(132, 142), (232, 242), (332, 342)}.

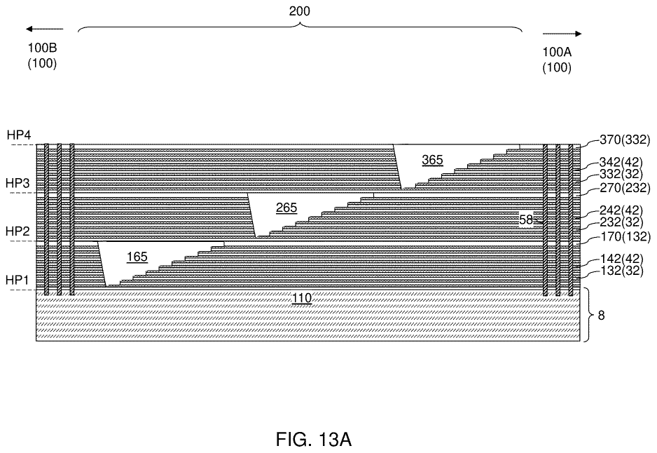

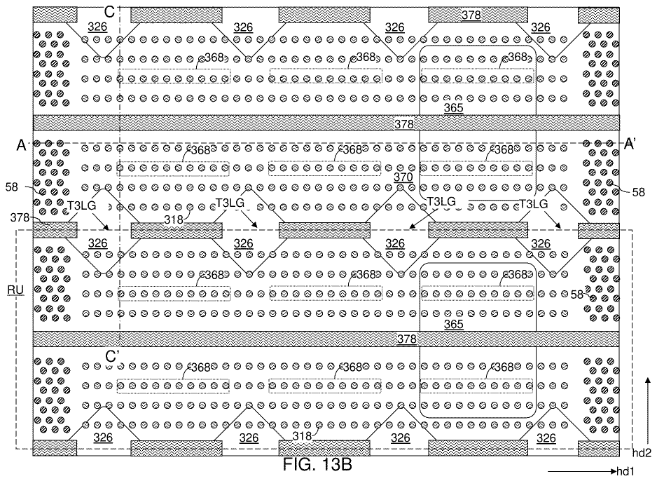

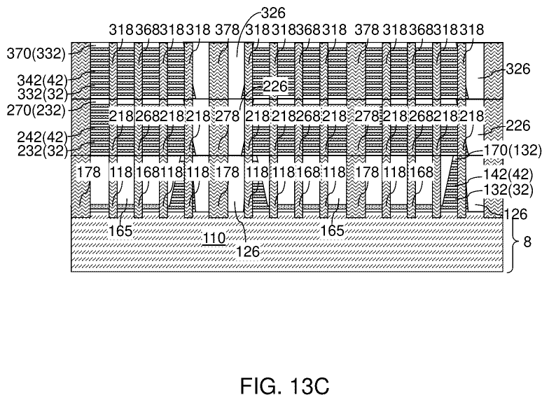

Referring to FIG. 13A-13C, the first exemplary structure is illustrated after formation of the memory opening fill structures 58. Each of the memory opening fill structures 58 comprises a respective vertical semiconductor channel 60 and respective vertical stack of memory elements, which may comprise portions of the memory material layers 54 located at the levels of the sacrificial material layers (142, 242, 342).

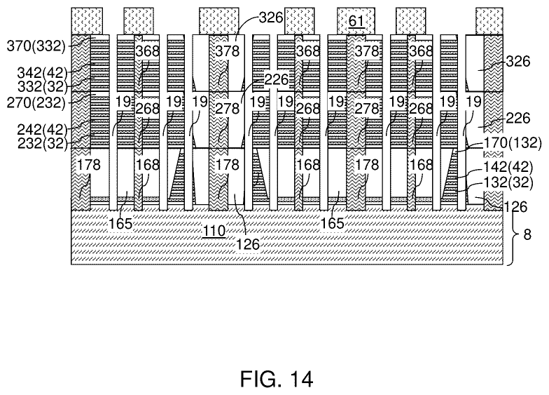

Referring to FIG. 14, a photoresist layer 61 can be applied over the multi-tier layer stacks {(132, 142), (232, 242), (332, 342)} and the lateral spacer structures (178, 278, 378, 165, 265, 365, 126, 226, 326), and can be lithographically patterned to form openings over the areas of the sacrificial third-tier support opening fill structures 318, the sacrificial second-tier support opening fill structures 218, and the sacrificial first-tier support opening fill structures 118 while covering all other sacrificial fill material portions. The sacrificial third-tier support opening fill structures 318, the sacrificial second-tier support opening fill structures 218, and the sacrificial first-tier support opening fill structures 118 are removed selectively to the alternating stacks of insulating layers (132, 232, 332) and sacrificial material layers (142, 242, 342) and selectively to the semiconductor material layer 110. An isotropic etch process or an anisotropic etch process may be performed. Inter-tier support openings 19 are formed in volumes from which the sacrificial support opening fill structures (318, 218, 118) are removed. Each of the inter-tier support openings 19 vertically extends through a respective first alternating stack (132, 142), a respective second alternating stack (232, 242), and a respective third alternating stack (332, 342). The inter-tier support openings 19 are formed in the inter-array region 200. The inter-tier support openings 19 may also be referred to as support openings 19. The photoresist layer 61 may then be removed by ashing or another suitable method.

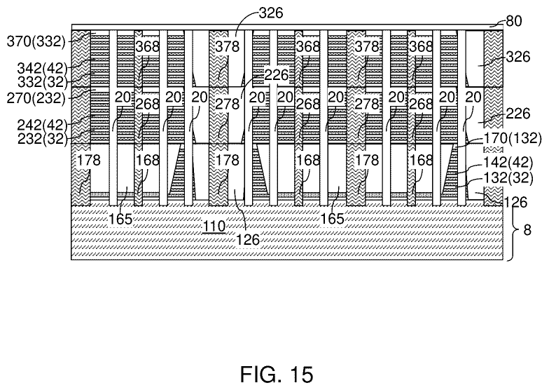

Referring to FIG. 15, a dielectric fill material can be conformally deposited in the support openings 19 and over the multi-tier layer stacks {(132, 142), (232, 242), (332, 342)} and the lateral spacer structures (178, 278, 378, 165, 265, 365, 126, 226, 326). The dielectric fill material may comprise undoped silicate glass (i.e., silicon oxide) or a doped silicate glass (such as borosilicate glass, borophosphosilicate glass, a carbon-doped silicate glass, etc.). Optionally, a dielectric metal oxide liner (such as an aluminum oxide liner or a dielectric transition metal oxide liner) may be conformally deposited before deposition of the dielectric fill material.

Optionally, horizontally-extending portions of the dielectric fill material overlying top surfaces of the multi-tier layer stacks {(132, 142), (232, 242), (332, 342)} may be thinned by performing a planarization process. The planarization process may comprise a recess etch process and/or a chemical mechanical polishing process. Each remaining portion of the dielectric fill material that fills a respective support opening 19 constitutes a support pillar structure 20. A remaining horizontally-extending portion of the dielectric fill material overlying the top surfaces of the multi-tier layer stacks {(132, 142), (232, 242), (332, 342)} constitutes a contact-level dielectric layer 80. The thickness of the contact-level dielectric layer 80 may be in a range from 100 nm to 600 nm, although lesser or greater thicknesses may also be employed. In one embodiment, top surfaces of the support pillar structures 20 may be formed within a horizontal plane including the top surfaces of the multi-tier layer stacks {(132, 142), (232, 242), (332, 342)}.

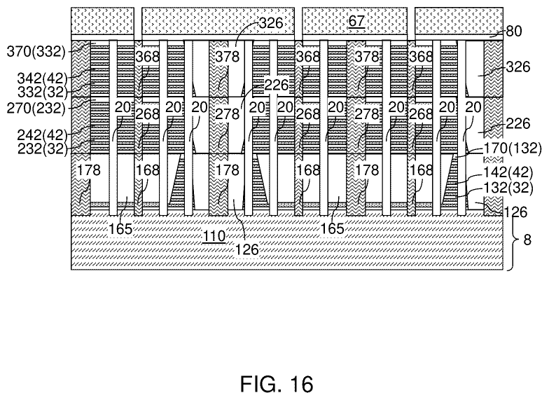

Referring to FIG. 16, a photoresist layer 67 can be applied over the contact-level dielectric layer 80, and can be lithographically patterned to form openings over the sacrificial contact openings fill structures (168, 268, 368). An etch process, such as an anisotropic etch process, can be performed to form openings over the sacrificial contact openings fill structures (168, 268, 368).

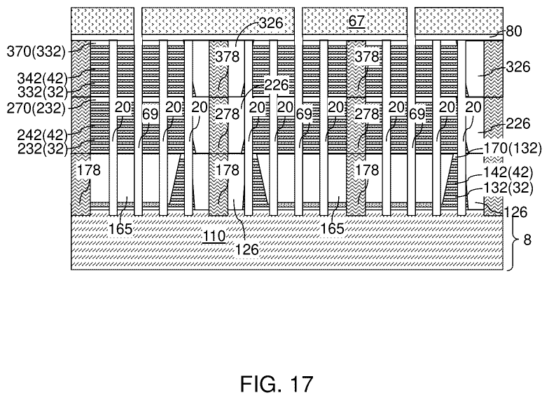

Referring to FIG. 17, the sacrificial contact opening fill structures (168, 268, 368) are removed selectively to the alternating stacks of insulating layers (132, 232, 332) and sacrificial material layers (142, 242, 342), and selectively to the semiconductor material layer 110. Inter-tier contact openings 69, which are also referred to as contact openings 69, are formed in volumes from which the sacrificial contact opening fill structures (168, 268, 368) are removed. The photoresist layer 67 can be subsequently removed, for example, by ashing.

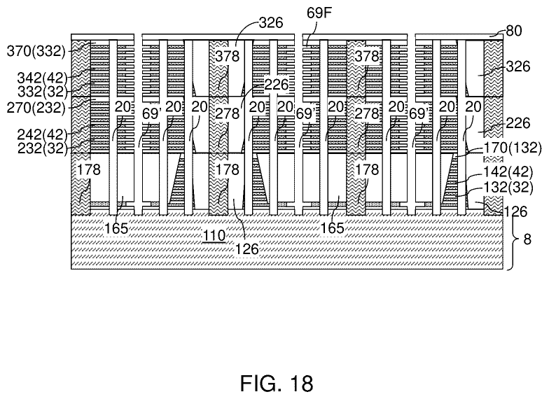

Referring to FIG. 18, a selective isotropic etch process can be performed to isotropically etch portions of the sacrificial material layers (142, 242, 342) that are proximal to the contact openings 69. Fin-shaped voids 69F are formed around each contact opening 69 at each level of the sacrificial material layers (142, 242, 342). Each contiguous combination of a contact opening 69 and adjoined fin-shaped voids 69F constitutes a finned contact opening 69′.

As discussed above, portions of the continuous sacrificial material layers (142, 242, 342) that are exposed to the first stepped cavities, the second stepped cavities, or the third stepped cavities are locally thickened. Thus, for each set of at least one fin-shaped void 69F within a finned contact opening 69′, a fin-shaped void 69F that immediately underlies a respective retro-stepped dielectric material portion (165, 265, 365) is thicker than any other fin-shaped void 69F.

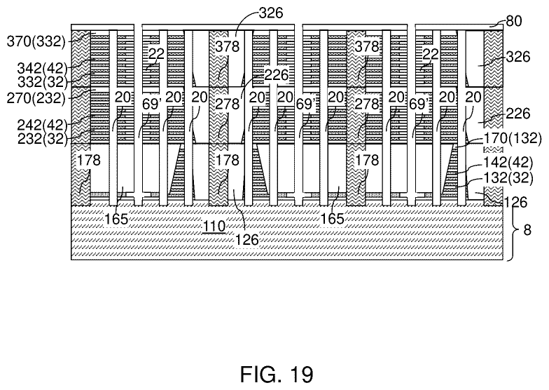

Referring to FIG. 19, a dielectric liner layer can be conformally deposited in peripheral regions of the finned contact openings 69′. The dielectric liner layer comprises a dielectric material having a different material composition than the sacrificial material layers (142, 242, 342). For example, the dielectric liner layer may comprise silicon oxide. The thickness of the dielectric liner layer is greater than one half of the thickness of unthickened portions of the sacrificial material layers (142, 242, 342), and is less than one half of the thickness of locally thickened portions of the continuous sacrificial material layers (142, 242, 342). Thus, for each set of at least one fin-shaped void 69F within a finned contact opening 69′, one fin-shaped void 69F that is laterally surrounded by a respective locally thickened portion of the sacrificial material layers (142, 242, 342) is not completely filled within the dielectric liner layer, while any other fin-shaped void 69F (if present) is completely filled with the dielectric liner layer.

An isotropic recess etch process can be performed to isotropically recess portions of the dielectric liner layer that are deposited outside completely filled fin-shaped voids 69F. Each remaining portion of the dielectric liner layer located in a subset of the fin-shaped voids 69F constitutes an annular insulating spacer 22, while the tallest fin-shaped void 69F remains unfilled. For each finned contact opening 69′ comprising two or more fin-shaped voids 69F, one or more annular insulating spacers 22 are formed in the fin-shaped voids 69F except within the tallest fin-shaped void 69F. The tallest fin-shaped void 69F within each finned contact opening 69′ has a greater height than the fin-shaped voids 69F that are filled with the annular insulating spacers 22 due to the local thickening of the physically exposed portions of the sacrificial material layers (142, 242, 342) discussed above. The annular insulating spacers 22 provide lateral electrical isolation between layer contact via structures to be subsequently formed and electrically conductive layers to be subsequently formed.

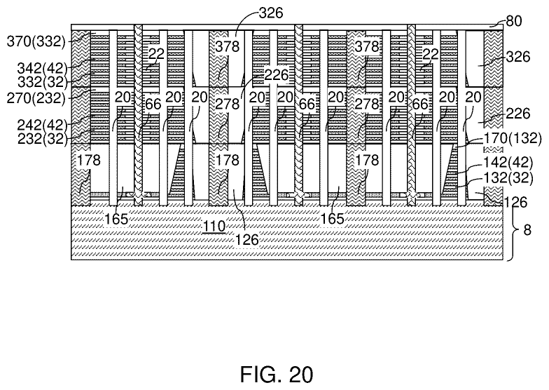

Referring to FIG. 20, a sacrificial via fill material can be deposited in the finned contact openings 69′, each including a respective unfilled fin-shaped void 69F, to form sacrificial contact via structures 66. The sacrificial contact via structures 66 may comprise a semiconductor material, such as amorphous silicon.

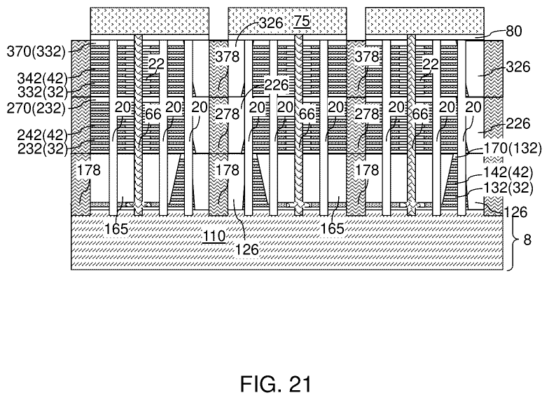

Referring to FIG. 21, a photoresist layer 75 can be applied over the contact-level dielectric layer 80, and can be lithographically patterned to form openings over the sacrificial wall structures (178, 278, 378). In one embodiment, each opening in the photoresist layer 67 may extend over a respective sacrificial wall structure (178, 278, 378). In one embodiment, a two-dimensional rectangular array of openings may be formed in the photoresist layer 75.

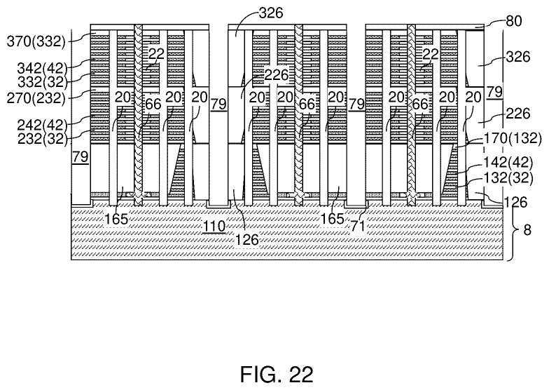

Referring to FIG. 22, the sacrificial wall structures (178, 278, 378) can be removed selectively to the alternating stacks of insulating layers (132, 232, 332) and sacrificial material layers (142, 242, 342). An isotropic etch process or an anisotropic etch process may be performed. Inter-tier lateral isolation trenches 79, which are also referred to as lateral isolation trenches 79, are formed in volumes from which the sacrificial wall structures (178, 278, 378) are removed.

Optionally, an oxidation process may be performed to convert physically exposed surface portions of the semiconductor material layer 110 into silicon oxide portions 71, which can be subsequently employed to protect the semiconductor material layer 110 during subsequent etch processes.

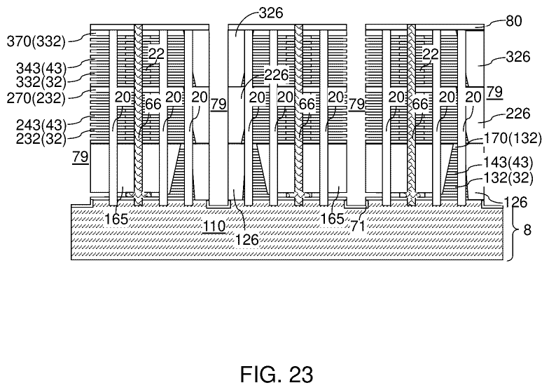

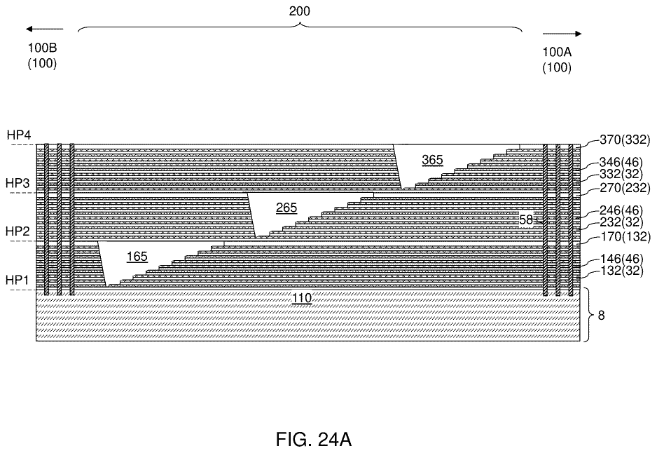

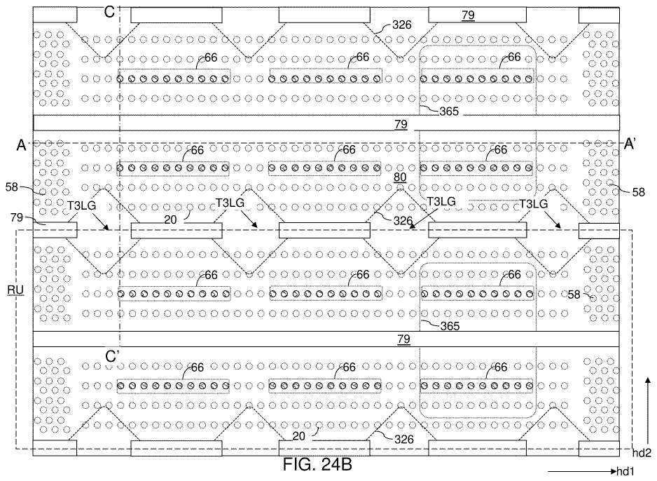

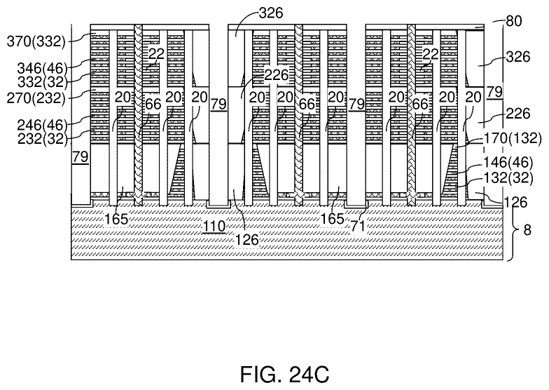

Referring to FIG. 23, an etchant that selectively etches the materials of the sacrificial material layers (142, 242, 342) with respect to the materials of the insulating layers (132, 232, 332), the contact-level dielectric layer 80, the retro-stepped dielectric material portions (165, 265, 365), and the material of the outermost layer of the memory films 50 can be introduced into the lateral isolation trenches 79, for example, employing an isotropic etch process. For example, the sacrificial material layers (142, 242, 342) can include silicon nitride, the materials of the insulating layers (132, 232, 332), the material of the retro-stepped dielectric material portions (165, 265, 365), and the material of the outermost layer of the memory films 50 can include silicon oxide materials.

The isotropic etch process can be a wet etch process employing a wet etch solution, or can be a gas phase (dry) etch process in which the etchant is introduced in a vapor phase into the lateral isolation trenches 79. For example, if the sacrificial material layers (142, 242, 342) include silicon nitride, the etch process can be a wet etch process in which the first exemplary structure is immersed within a wet etch tank including phosphoric acid, which etches silicon nitride selectively to silicon oxide, silicon, and various other materials employed in the art. Laterally-extending cavities (143, 243, 343) are formed in the volumes from which the sacrificial material layers (142, 242, 342) are removed.

Each of the laterally-extending cavities (143, 243, 343) can be a laterally extending cavity having a lateral dimension that is greater than the vertical extent of the cavity. In other words, the lateral dimension of each of the laterally-extending cavities (143, 243, 343) can be greater than the height of the respective laterally-extending cavity (143, 243, 343). A plurality of first laterally-extending cavities 143 can be formed in the volumes from which the material of the first sacrificial material layers 142 is removed. A plurality of second laterally-extending cavities 243 can be formed in the volumes from which the material of the second sacrificial material layers 242 is removed. A plurality of third laterally-extending cavities 343 can be formed in the volumes from which the material of the third sacrificial material layers 342 is removed. Each of the laterally-extending cavities (143, 243, 343) can extend substantially parallel to the top surface of the substrate 8. A laterally-extending cavity (143, 243, 343) can be vertically bounded by a top surface of an underlying insulating layer (132, 232, 332) and a bottom surface of an overlying insulating layer (132, 232, or 332). In one embodiment, each of the laterally-extending cavities (143, 243, 343) can have a uniform height throughout.

Referring to FIG. 24A-24C, an outer blocking dielectric layer (not shown) can be optionally deposited in the laterally-extending cavities (143, 243, 343) and the lateral isolation trenches 79 and over the contact-level dielectric layer. At least one conductive material can be deposited in the plurality of laterally-extending cavities (143, 243, 343), on the sidewalls of the lateral isolation trenches 79, and over the contact-level dielectric layer 80. The at least one conductive material can be deposited by a conformal deposition method, which can be, for example, chemical vapor deposition (CVD), atomic layer deposition (ALD), electroless plating, electroplating, or a combination thereof. The at least one conductive material can include an elemental metal, an intermetallic alloy of at least two elemental metals, a conductive nitride of at least one elemental metal, a conductive metal oxide, a conductive doped semiconductor material, a conductive metal-semiconductor alloy such as a metal silicide, alloys thereof, and combinations or stacks thereof.

In one embodiment, the at least one conductive material can include at least one metallic material, i.e., an electrically conductive material that includes at least one metallic element. Non-limiting exemplary metallic materials that can be deposited in the laterally-extending cavities (143, 243, 343) include tungsten, tungsten nitride, titanium, titanium nitride, tantalum, tantalum nitride, cobalt, and ruthenium. For example, the at least one conductive material can include a conductive metallic nitride liner that includes a conductive metallic nitride material such as TiN, TaN, WN, or a combination thereof, and a conductive fill material such as W, Co, Ru, Mo, Cu, or combinations thereof. In one embodiment, the at least one conductive material for filling the laterally-extending cavities (143, 243, 343) can be a combination of titanium nitride layer and a tungsten fill material.

Electrically conductive layers (146, 246, 346) can be formed in the laterally-extending cavities (143, 243, 343) by deposition of the at least one conductive material. A plurality of first electrically conductive layers 146 can be formed in the plurality of first laterally-extending cavities 243, a plurality of second electrically conductive layers 246 can be formed in the plurality of second laterally-extending cavities 243, a plurality of third electrically conductive layers 346 can be formed in the plurality of third laterally-extending cavities 343, and a continuous metallic material layer (not shown) can be formed on the sidewalls of each lateral isolation trench 79 and over the contact-level dielectric layer 80. Each of the electrically conductive layers (146, 246, 346) may include a respective conductive metallic nitride liner and a respective conductive fill material. Thus, the sacrificial material layers (142, 242, 342) can be replaced with the electrically conductive layers (146, 246, 346), respectively. Specifically, each first sacrificial material layer 142 can be replaced with an optional portion of the outer blocking dielectric layer and a first electrically conductive layer 146, each second sacrificial material layer 242 can be replaced with an optional portion of the outer blocking dielectric layer and a second electrically conductive layer 246, and each third sacrificial material layer 342 can be replaced with an optional portion of the outer blocking dielectric layer and a third electrically conductive layer 346. A backside cavity is present in the portion of each lateral isolation trench 79 that is not filled with the continuous metallic material layer.

Residual conductive material can be removed from inside the lateral isolation trenches 79. Specifically, the deposited metallic material of the continuous metallic material layer can be etched back from the sidewalls of each lateral isolation trench 79 and from above the contact-level dielectric layer 80, for example, by an isotropic etchback process. Each remaining portion of the deposited metallic material in the first laterally-extending cavities 143 constitutes a first electrically conductive layer 146. Each remaining portion of the deposited metallic material in the second laterally-extending cavities 243 constitutes a second electrically conductive layer 246. Each remaining portion of the deposited metallic material in the third laterally-extending cavities 343 constitutes a third electrically conductive layer 346. The first electrically conducive layers 146, the second electrically conductive layers 246, and the third electrically conductive layers 346 are collectively referred to as electrically conductive layers 46. Thus, the sacrificial material layers 42 are replaced with the electrically conductive layers 46.

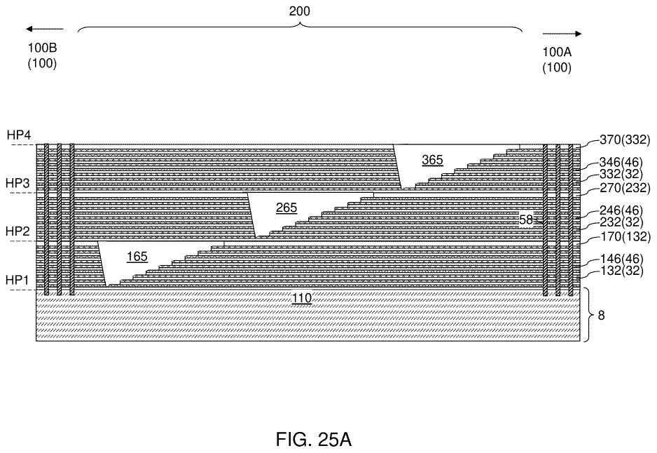

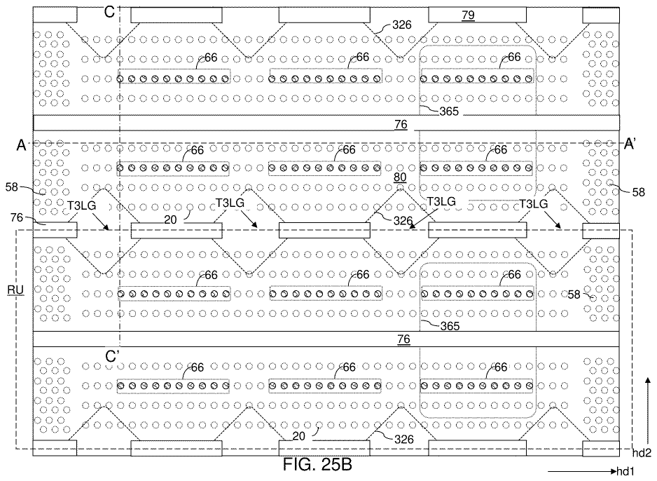

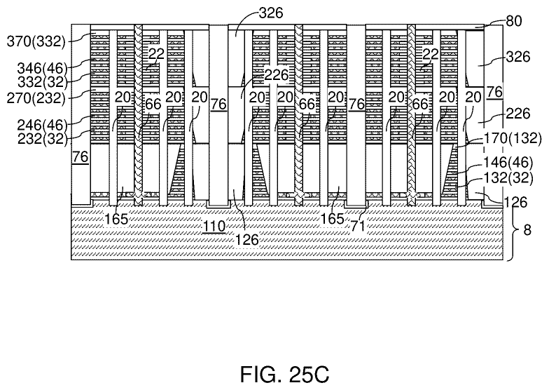

Referring to FIG. 25A-25C, a dielectric fill material, such as undoped silicate glass (i.e., silicon oxide) or a doped silicate glass may be deposited in the lateral isolation trenches 79. The dielectric fill material may be deposited by a conformal deposition process (such as a chemical vapor deposition process) or a self-planarizing deposition process (such as spin-coating). Any excess portion of the dielectric fill material overlying the contact-level dielectric layer 80 may be removed from above the horizontal plane including the top surface of the contact-level dielectric layer 80 by a planarization process (which may comprise a recess etch process or a chemical mechanical polishing process). Remaining portions of the dielectric fill material filling the lateral isolation trenches 79 constitute dielectric wall structures 76. Alternatively, the excess portion of the dielectric fill material overlying the contact-level dielectric layer 80 may be incorporated into the contact-level dielectric layer 80. Generally, top surfaces of the dielectric wall structures 76 may be formed within the horizontal plane including the top surface of the contact-level dielectric layer 80.

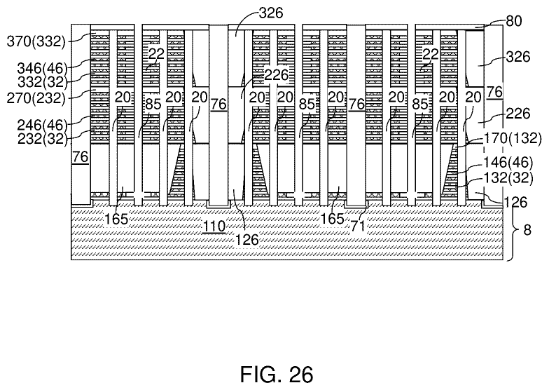

Referring to FIG. 26, a selective etch process may be performed to remove sacrificial contact via structures 66 selective to the materials of the contact-level dielectric layer 80, the retro-stepped dielectric material portions (165, 265, 365), the insulating layers 32, and the electrically conductive layers 46. Through-via cavities 85 can be formed in the volumes from which the sacrificial contact via structures 66 are removed. An isotropic etch process may be performed to remove any physically exposed portion of the outer blocking dielectric layers (not shown) from around the through-via cavities 85. Each through-via cavity 85 is a contact via cavity to which a surface of a respective electrically conductive layer 46 is physically exposed. In one embodiment, each through-via cavity 85 comprises a respective annular recess region to which a cylindrical sidewall of a respective electrically conductive layer 46 is physically exposed.

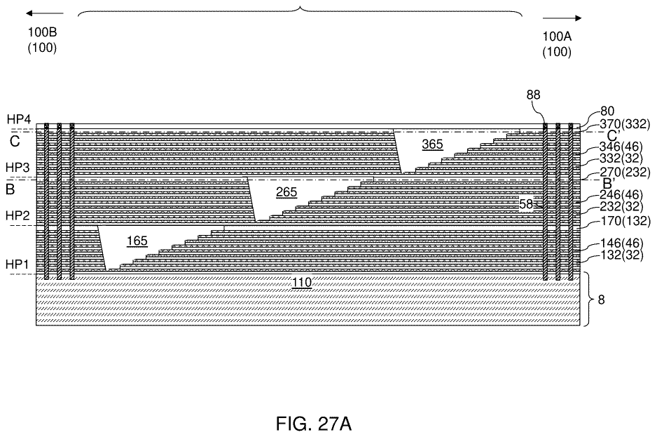

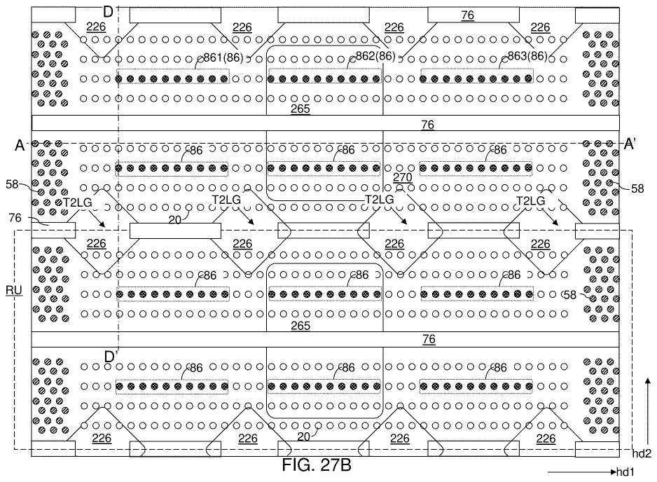

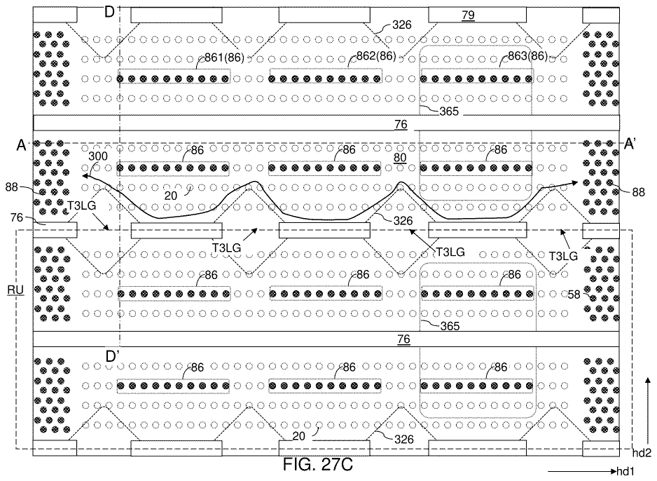

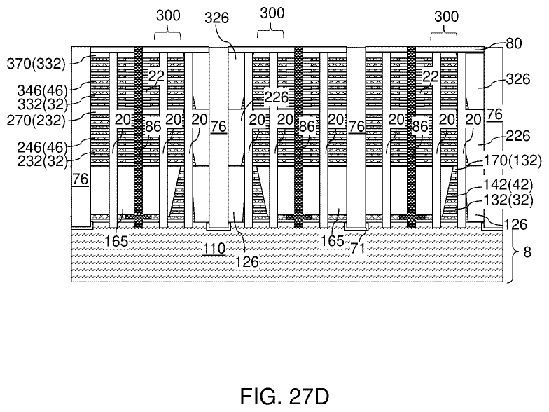

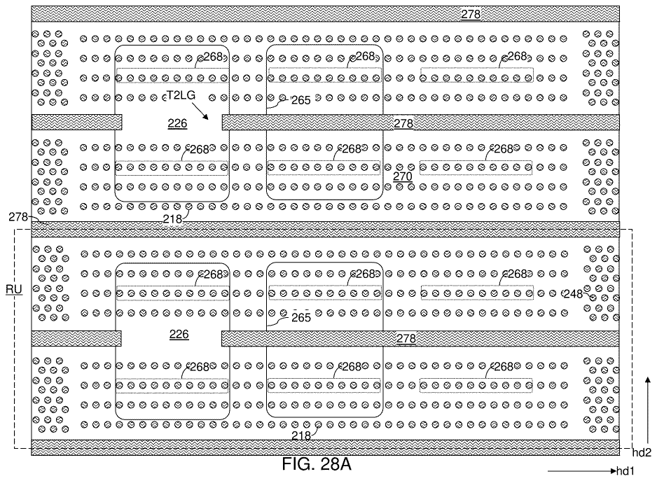

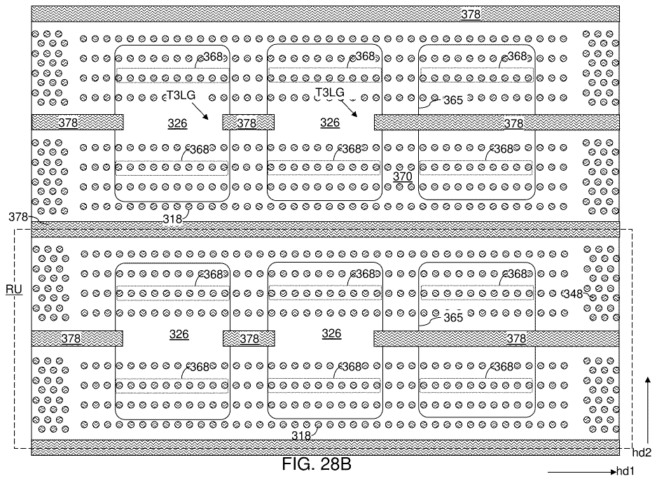

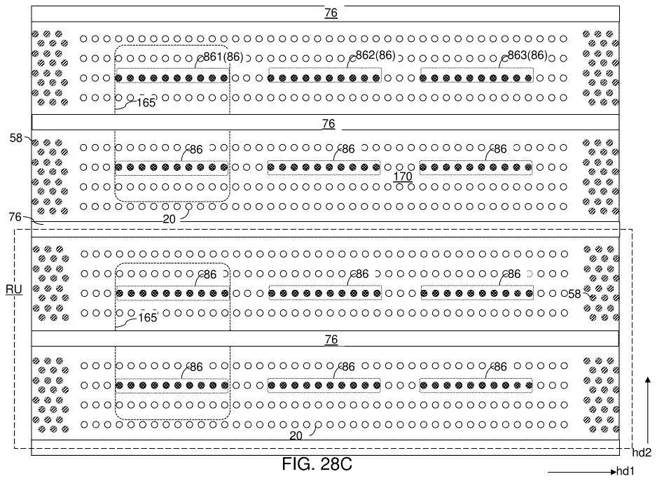

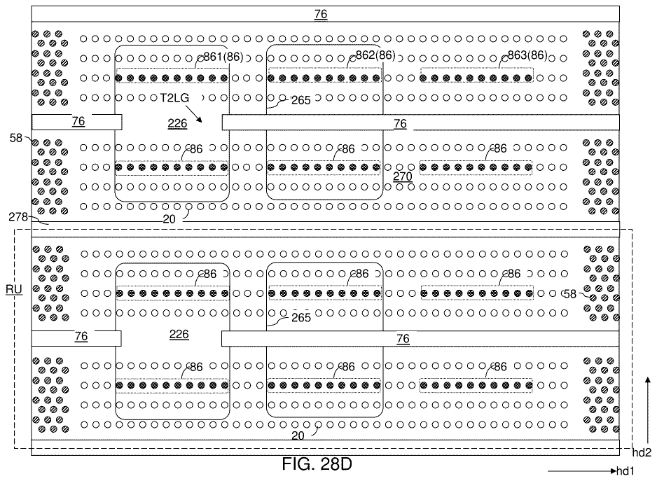

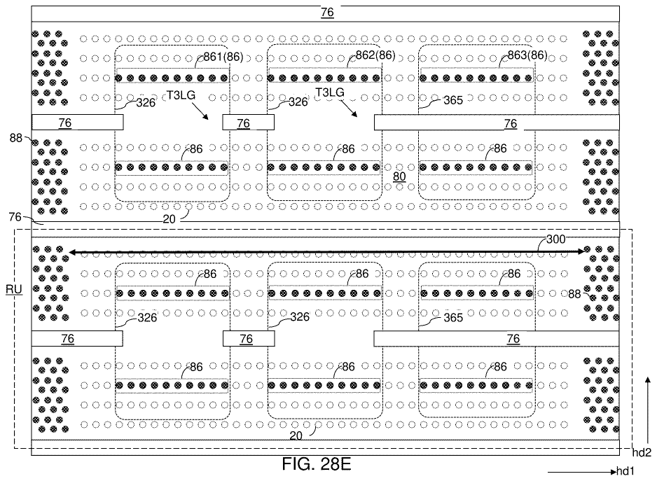

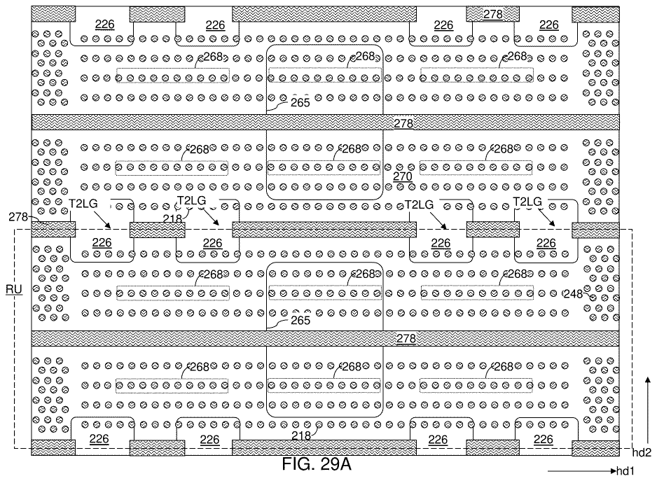

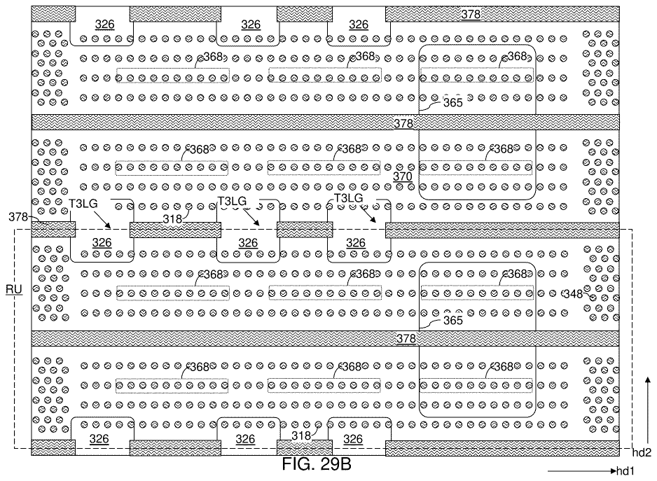

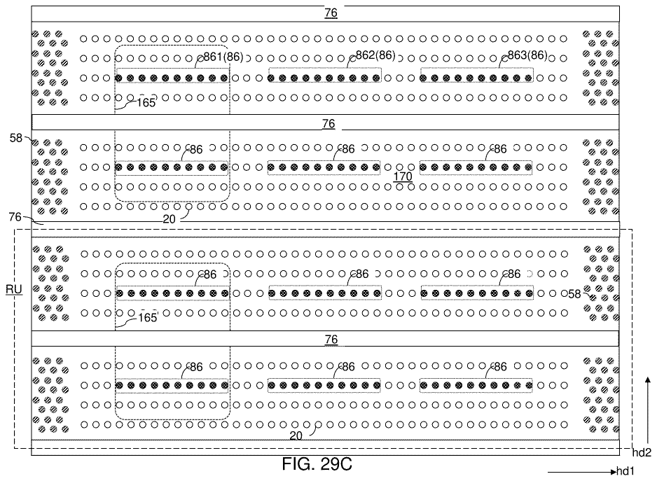

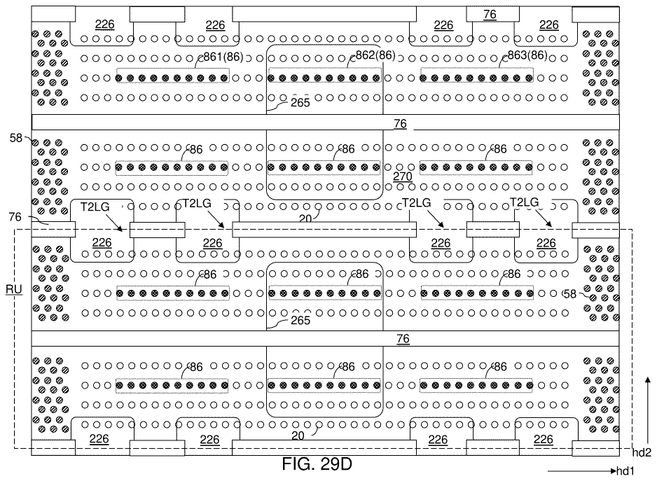

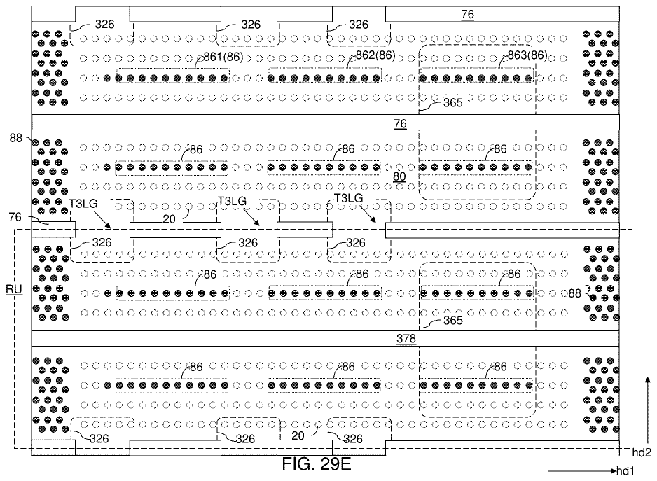

Referring to FIG. 27A-27D, at least one electrically conductive material, such as a combination of a metallic barrier liner material and a metal fill material, can be conformally deposited in the through-via cavities 85 directly on physically exposed surface segments of the electrically conductive layers 46. Excess portions of the at least one electrically conductive material may be removed from above the horizontal plane including the top surface of the contact-level dielectric layer 80 by a planarization process, which may comprise a recess etch process and/or a chemical mechanical polishing process. Each remaining portion of the at least one electrically conductive material filling a respective one of the through-via cavities 85 constitute a layer contact via structure 86. The layer contact via structures 86 comprise first-tier-contact layer contact via structures 861 that contact a respective one of the first-tier electrically conductive layers 146, second-tier-contact layer contact via structures 862 that contact a respective one of the second-tier electrically conductive layers 246, and third-tier-contact layer contact via structures 863 that contact a respective one of the third-tier electrically conductive layers 346.

Each layer contact via structure 86 vertically extends through a respective retro-stepped dielectric material portion (165, 265, or 365) and a set of at least one electrically conductive layer 46 located within a same tier structure as the respective retro-stepped dielectric material portion (165, 265, or 365) and underlies the respective retro-stepped dielectric material portion (165, 265, or 365). Each layer contact via structure 86 is electrically connected to and is in direct contact with a topmost electrically conductive layer 46 within the set of at least one electrically conductive layer 46. If the set of at least one electrically conductive layer 46 comprises a plurality of electrically conductive layers 46, the layer contact via structure 86 is laterally spaced from, and is electrically isolated from, each electrically conductive layer 46 within the set except the topmost electrically conductive layer 46 within the set by at least one annular insulating spacer 22. In case the layer contact via structure 86 vertically extends through any opening in any other electrically conductive layer 46 that overlies the tier structure or underlies the tier structure, the layer contact via structure 86 is laterally spaced from, and is electrically isolated from, any such electrically conductive layer 46 by a respective annular insulating spacer 22.

Drain contact via structures 88 can be formed through the contact-level dielectric layer 80 on the drain regions 63 within the memory opening fill structures 58. Each drain region 634 may be contacted by a respective one of the drain contact via structures 88.

In this embodiment, even numbered dielectric wall structures 76 may contact only the retro-stepped dielectric material portions (165, 265, 365) but not the dielectric pillar structures (226, 326), while odd numbered dielectric wall structures 76 may contact only the dielectric pillar structures (226, 326) but not the retro-stepped dielectric material portions (165, 265, 365), or vice-versa.

Each alternating stack (32, 46) located between adjacent dielectric wall structures 76 comprises a memory block. As shown in FIGS. 27C and 27D, a continuous electrically conductive path (e.g., a bridge region) 300 extends through each inter-array region 200 between the first memory array region 100A and the second memory array region 100B. Thus, each electrically conductive layer 46 continuously extends through each inter-array region 200 between the first memory array region 100A and the second memory array region 100B in the bridge region 300. As shown in FIG. 27C, the bridge region 300 may be curved around retro-stepped dielectric material portions (165, 265, 365) and the dielectric pillar structures (226, 326).

As shown in FIG. 27D, the width of the bottom of the second-tier dielectric pillar structure 226 along the second horizontal direction hd2 is wider than the width along the second horizontal direction hd2 of the bottom of the lateral isolation trench 79 and the dielectric wall structure 76 that fills the trench 79.

Suitable additional processing steps may be performed as needed. For example, bit lines and metal interconnect structures embedded within dielectric material layers can be formed over the contact-level dielectric layer. Bonding pads may be formed at the uppermost level of the dielectric material layers to provide at least one memory die. Each memory die may be bonded to a respective logic die including a controller circuit for operation of a three-dimensional array in a memory die. A wafer-to-wafer bonding, a wafer-to-die bonding, or a die-to-die bonding may be employed. The semiconductor material layer 110 may be thinned and/or removed as needed. In this case, source layers (not shown) may be formed on the bottom surfaces of the vertical semiconductor channels 60.

The first exemplary structure may be implemented in various alternative configurations. FIGS. 28A-35 illustrate such alternative configurations for the first exemplary structure.

FIG. 28A is a top-down view of a first alternative configuration of the first exemplary structure after formation of a second-tier structure (232, 242) according to an embodiment of the present disclosure. FIG. 28B is a top-down view of the first alternative configuration of the first exemplary structure after formation of a third-tier structure (332, 342) according to an embodiment of the present disclosure. FIG. 28C is a first horizontal cross-sectional view of the first alternative configuration of the first exemplary structure along a horizontal plane including first insulating cap layers 170 after formation of various contact via structures (86, 88) according to an embodiment of the present disclosure. FIG. 28D is a second horizontal cross-sectional view of the first alternative configuration of the first exemplary structure along a horizontal plane including second insulating cap layers 270 after formation of various contact via structures (86, 88) according to an embodiment of the present disclosure. FIG. 28E is a top-down view of the first alternative configuration of the first exemplary structure after formation of various contact via structures (86, 88) according to an embodiment of the present disclosure.

In the first alternative configuration of the first exemplary structure, the second-tier dielectric material portions (265, 226) within a lateral isolation structure (76, 165, 265, 365, 126, 226, 326) may comprise second-tier retro-stepped dielectric material portions 265 and second-tier dielectric pillar structures 226 having a horizontal cross-sectional shape of notched rounded rectangles; and the third-tier dielectric material portions (365, 326) within the lateral isolation structure (76, 165, 265, 365, 126, 226, 326) may comprise third-tier retro-stepped dielectric material portions 365 and third-tier dielectric pillar structures 326 having a horizontal cross-sectional shape of notched rounded rectangles. Each horizontal cross-sectional shape of a notched rounded rectangle may be derived from a rounded rectangle by forming two notches on two sides of a rounded rectangle.

In this embodiment, even numbered dielectric wall structures 76 may contact both the retro-stepped dielectric material portions (165, 265, 365) and the dielectric pillar structures (226, 326), while odd numbered dielectric wall structures 76 may contact neither the dielectric pillar structures (226, 326) nor the retro-stepped dielectric material portions (165, 265, 365), or vice-versa. In this embodiment, the bridge region 300 may extend along a straight line along the first horizontal direction hd1, as shown in FIG. 28E.

FIG. 29A is a top-down view of a second alternative configuration of the first exemplary structure after formation of a second-tier structure (232, 242) according to an embodiment of the present disclosure. FIG. 29B is a top-down view of the second alternative configuration of the first exemplary structure after formation of a third-tier structure (332, 342) according to an embodiment of the present disclosure. FIG. 29C is a first horizontal cross-sectional view of the second alternative configuration of the first exemplary structure along a horizontal plane including first insulating cap layers 170 after formation of various contact via structures (86, 88) according to an embodiment of the present disclosure. FIG. 29D is a second horizontal cross-sectional view of the second alternative configuration of the first exemplary structure along a horizontal plane including second insulating cap layers 270 after formation of various contact via structures (86, 88) according to an embodiment of the present disclosure. FIG. 29E is a top-down view of the second alternative configuration of the first exemplary structure after formation of various contact via structures (86, 88) according to an embodiment of the present disclosure.

In the second alternative configuration of the first exemplary structure, the second-tier dielectric material portions (265, 226) within a lateral isolation structure (76, 165, 265, 365, 126, 226, 326) may comprise a pair of second-tier retro-stepped dielectric material portions 265, or second-tier dielectric pillar structures 226 having a horizontal cross-sectional shape of notched rounded rectangles; and the third-tier dielectric material portions (365, 326) within the lateral isolation structure (76, 165, 265, 365, 126, 226, 326) may comprise third-tier retro-stepped dielectric material portions 365, or third-tier dielectric pillar structures 326 having a horizontal cross-sectional shape of notched rounded rectangles. Each horizontal cross-sectional shape of a notched rounded rectangle may be derived from a rounded rectangle by forming two notches on two sides of a rounded rectangle. Thus, in the second alternative configuration a pair of second-tier dielectric pillar structures 226 is provided instead of a single second-tier dielectric pillar structure 226 of the first alternative configuration.

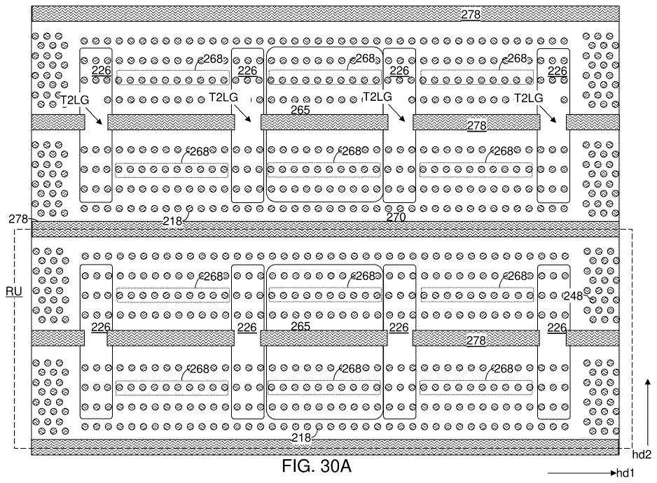

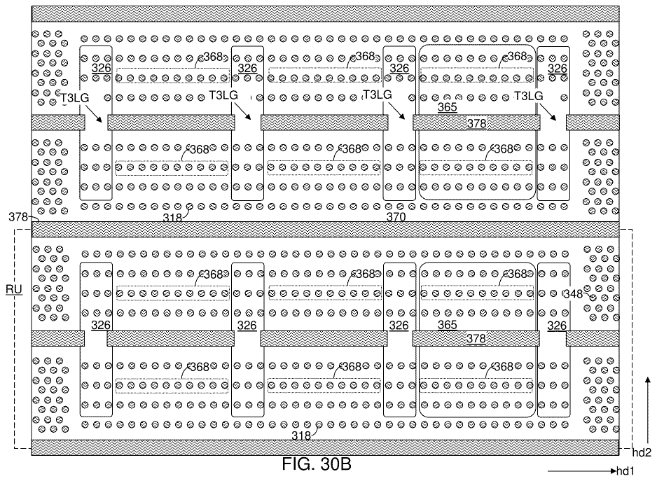

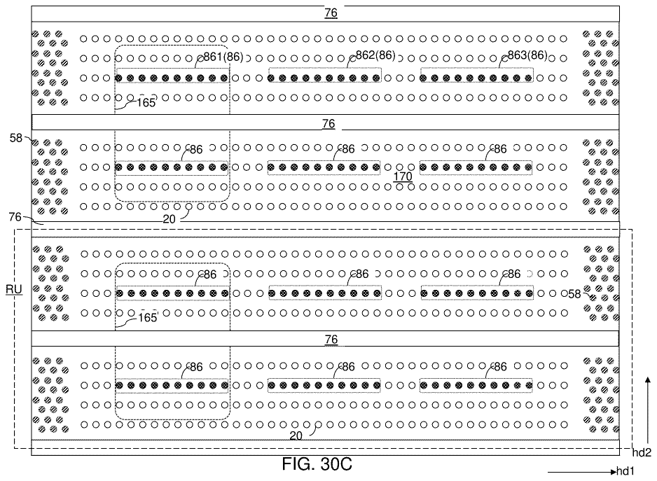

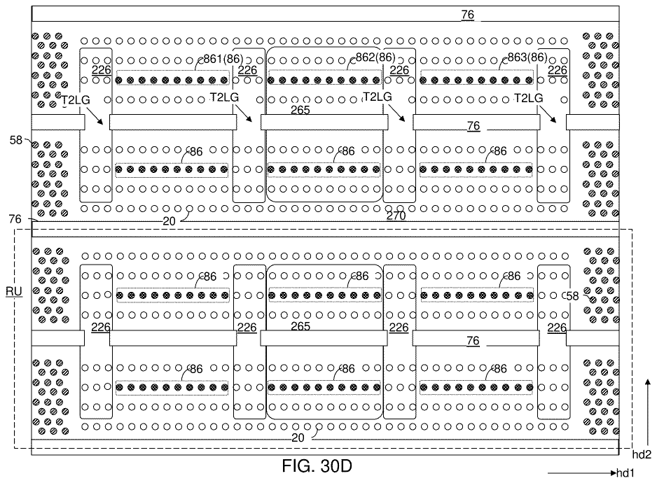

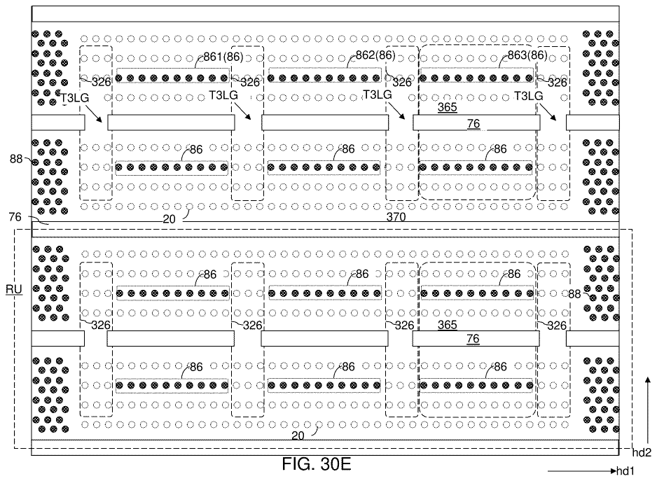

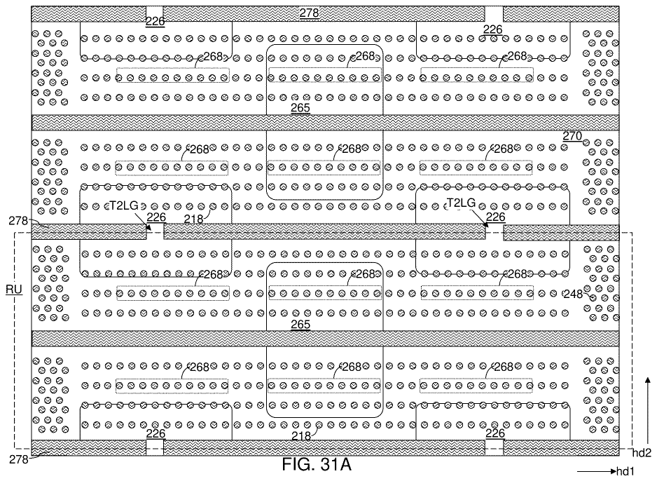

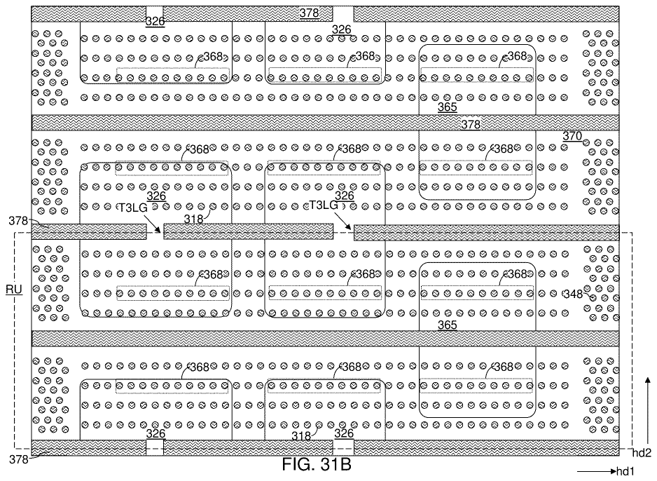

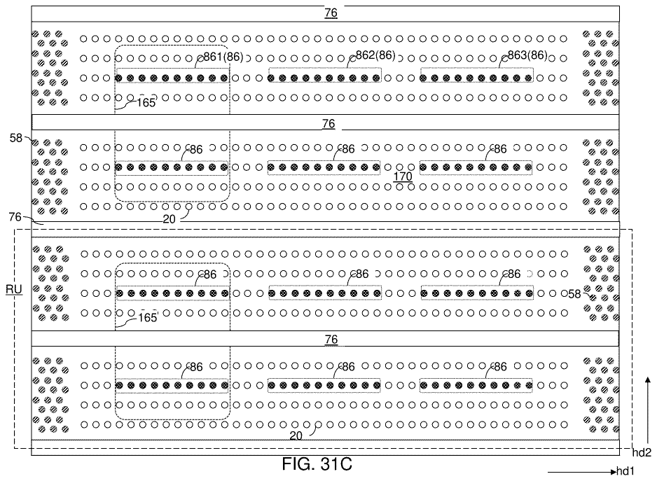

FIG. 30A is a top-down view of a third alternative configuration of the first exemplary structure after formation of a second-tier structure (232, 242) according to an embodiment of the present disclosure. FIG. 30B is a top-down view of the third alternative configuration of the first exemplary structure after formation of a third-tier structure (332, 342) according to an embodiment of the present disclosure. FIG. 30C is a first horizontal cross-sectional view of the third alternative configuration of the first exemplary structure along a horizontal plane including first insulating cap layers 170 after formation of various contact via structures (86, 88) according to an embodiment of the present disclosure. FIG. 30D is a second horizontal cross-sectional view of the third alternative configuration of the first exemplary structure along a horizontal plane including second insulating cap layers 270 after formation of various contact via structures (86, 88) according to an embodiment of the present disclosure. FIG. 30E is a top-down view of the third alternative configuration of the first exemplary structure after formation of various contact via structures (86, 88) according to an embodiment of the present disclosure.

In the third alternative configuration of the first exemplary structure, the second-tier dielectric material portions (265, 226) within a lateral isolation structure (76, 165, 265, 365, 126, 226, 326) may comprise second-tier retro-stepped dielectric material portions 265 and second-tier dielectric pillar structures 226 having a horizontal cross-sectional shape of notched rounded rectangles; and the third-tier dielectric material portions (365, 326) within the lateral isolation structure (76, 165, 265, 365, 126, 226, 326) may comprise third-tier retro-stepped dielectric material portions 365 and third-tier dielectric pillar structures 326 having a horizontal cross-sectional shape of notched rounded rectangles. The second-tier retro-stepped dielectric material portion 265 may be in contact with second-tier dielectric pillar structures 226. The third-tier retro-stepped dielectric material portions 365 may be in contact with the third-tier dielectric pillar structures 326. Thus, the retro-stepped dielectric material portions may be continuous with the respective dielectric pillar structures in the same tier in this configuration.

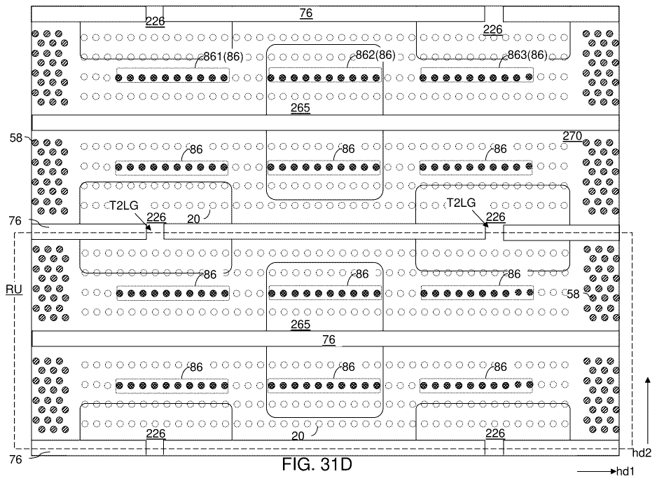

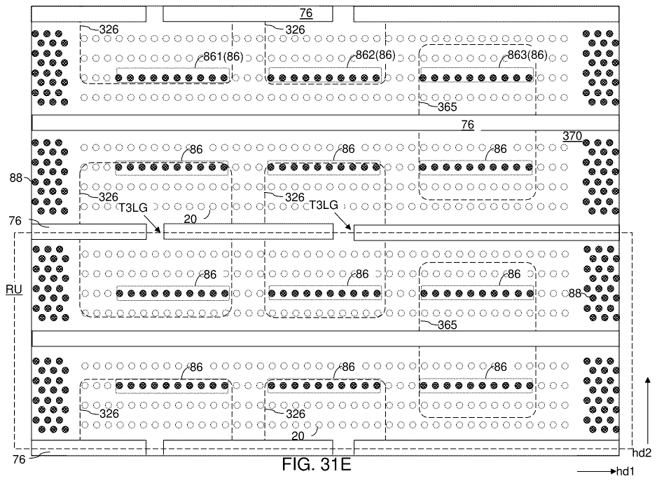

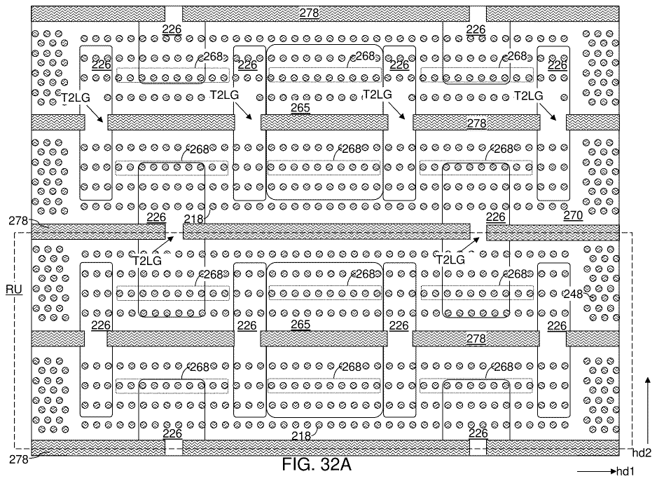

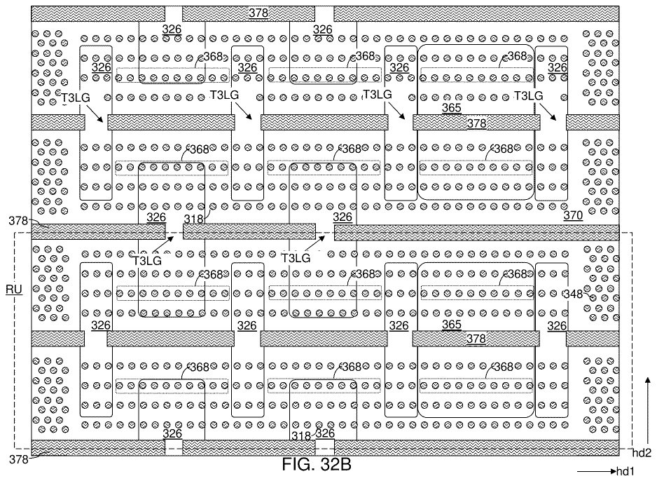

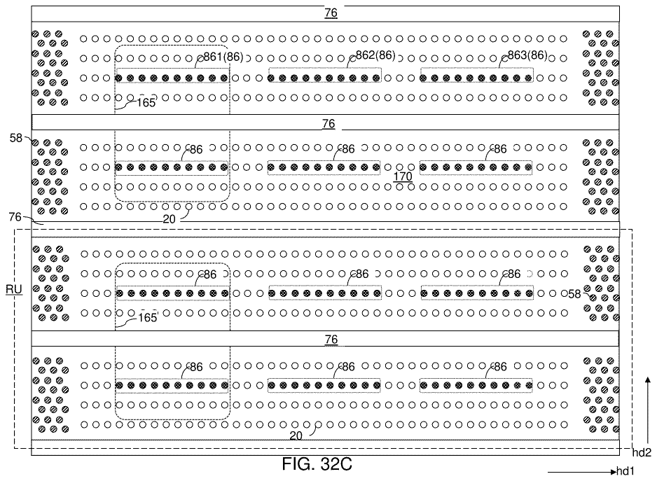

FIG. 31A is a top-down view of a fourth alternative configuration of the first exemplary structure after formation of a second-tier structure (232, 242) according to an embodiment of the present disclosure. FIG. 31B is a top-down view of the fourth alternative configuration of the first exemplary structure after formation of a third-tier structure (332, 342) according to an embodiment of the present disclosure. FIG. 31C is a first horizontal cross-sectional view of the fourth alternative configuration of the first exemplary structure along a horizontal plane including first insulating cap layers 170 after formation of various contact via structures (86, 88) according to an embodiment of the present disclosure. FIG. 31D is a second horizontal cross-sectional view of the fourth alternative configuration of the first exemplary structure along a horizontal plane including second insulating cap layers 270 after formation of various contact via structures (86, 88) according to an embodiment of the present disclosure. FIG. 31E is a top-down view of the fourth alternative configuration of the first exemplary structure after formation of various contact via structures (86, 88) according to an embodiment of the present disclosure.

In the fourth alternative configuration of the first exemplary structure, the second-tier dielectric material portions (265, 226) within a lateral isolation structure (76, 165, 265, 365, 126, 226, 326) may comprise a pair of second-tier retro-stepped dielectric material portions 265, or a pair second-tier dielectric pillar structures 226 having a horizontal cross-sectional shape of notched rounded rectangles; and the third-tier dielectric material portions (365, 326) within the lateral isolation structure (76, 165, 265, 365, 126, 226, 326) may comprise a pair of third-tier retro-stepped dielectric material portions 365, or a pair of third-tier dielectric pillar structures 326 having a horizontal cross-sectional shape of notched rounded rectangles.

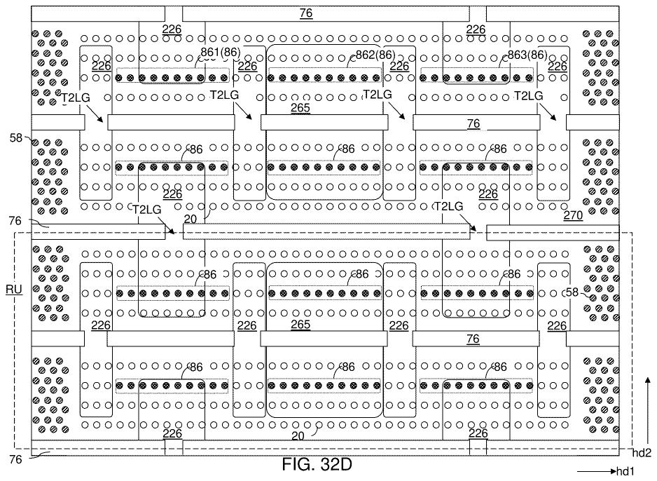

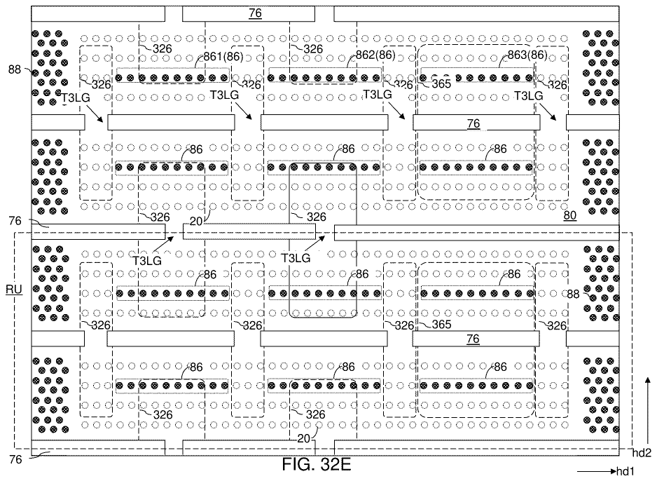

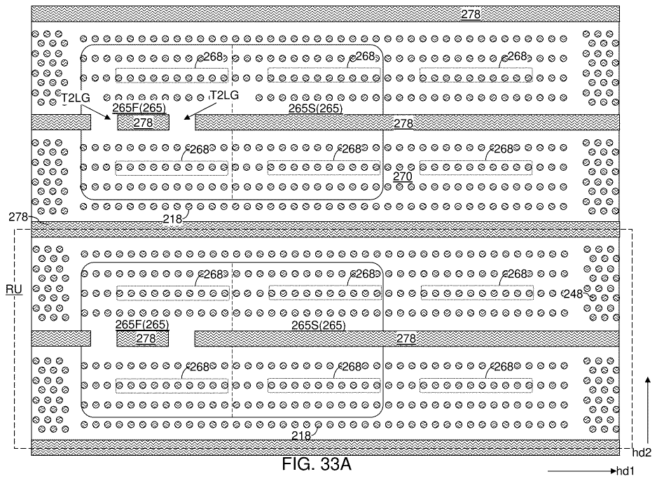

FIG. 32A is a top-down view of a fifth alternative configuration of the first exemplary structure after formation of a second-tier structure (232, 242) according to an embodiment of the present disclosure. FIG. 32B is a top-down view of the fifth alternative configuration of the first exemplary structure after formation of a third-tier structure (332, 342) according to an embodiment of the present disclosure. FIG. 32C is a first horizontal cross-sectional view of the fifth alternative configuration of the first exemplary structure along a horizontal plane including first insulating cap layers 170 after formation of various contact via structures (86, 88) according to an embodiment of the present disclosure. FIG. 32D is a second horizontal cross-sectional view of the fifth alternative configuration of the first exemplary structure along a horizontal plane including second insulating cap layers 270 after formation of various contact via structures (86, 88) according to an embodiment of the present disclosure. FIG. 32E is a top-down view of the fifth alternative configuration of the first exemplary structure after formation of various contact via structures (86, 88) according to an embodiment of the present disclosure.

In the fifth alternative configuration of the first exemplary structure, the second-tier dielectric material portions (265, 226) within a first-type lateral isolation structure (76, 165, 265, 365, 126, 226, 326) may comprise two second-tier retro-stepped dielectric material portions 265 and second-tier dielectric pillar structures 226 having a horizontal cross-sectional shape of notched rounded rectangles. The second-tier dielectric material portions (265, 226) within a second-type lateral isolation structure (76, 165, 265, 365, 126, 226, 326) may comprise only second-tier dielectric pillar structures 226 having a horizontal cross-sectional shape of notched rounded rectangles. Likewise, the third-tier dielectric material portions (365, 326) within a first-type lateral isolation structure (76, 165, 265, 365, 126, 226, 326) may comprise two third-tier retro-stepped dielectric material portions 365 and third-tier dielectric pillar structures 326 having a horizontal cross-sectional shape of notched rounded rectangles. The third-tier dielectric material portions (365, 326) within a second-type lateral isolation structure (76, 165, 265, 365, 126, 226, 326) may comprise only third-tier dielectric pillar structures 326 having a horizontal cross-sectional shape of notched rounded rectangles. Thus, even numbered dielectric wall structures 76 may contact both the retro-stepped dielectric material portions (165, 265, 365) and the “first type” dielectric pillar structures (226, 326), while odd numbered dielectric wall structures 76 may contact only the “second type” dielectric pillar structures (226, 326), or vice-versa.

In embodiments in which the retro-stepped dielectric material portions may be continuous with the respective dielectric pillar structures in the same tier, and the dielectric pillar structures have the same lateral extent along the second horizontal direction hd2 as the retro-stepped dielectric material portions in the same tier, the dielectric pillar structures (226, 326) may be referred to as full-height dielectric material sub-portions of the respective retro-stepped dielectric material portion (265, 365). Thus, in these embodiments, each second-tier retro-stepped dielectric material portion 265 may include a second-tier staircase dielectric material sub-portion 265S and a second-tier full-height dielectric material sub-portion 265F. Likewise, each third-tier retro-stepped dielectric material portion 365 may include a third-tier staircase dielectric material sub-portion 365S and a third-tier full-height dielectric material sub-portion 365F. The full-height dielectric material sub-portions vertically extend along the entire height of their respective tier, while the staircase dielectric material sub-portions may include a stepped bottom surface and vertically extend less than the entire height of their respective tier.

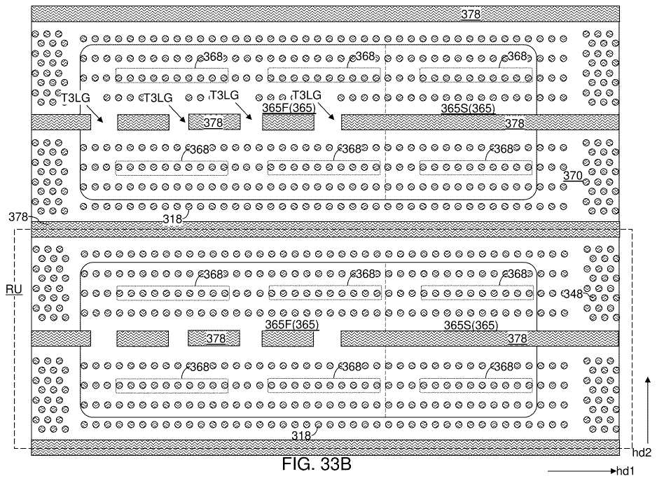

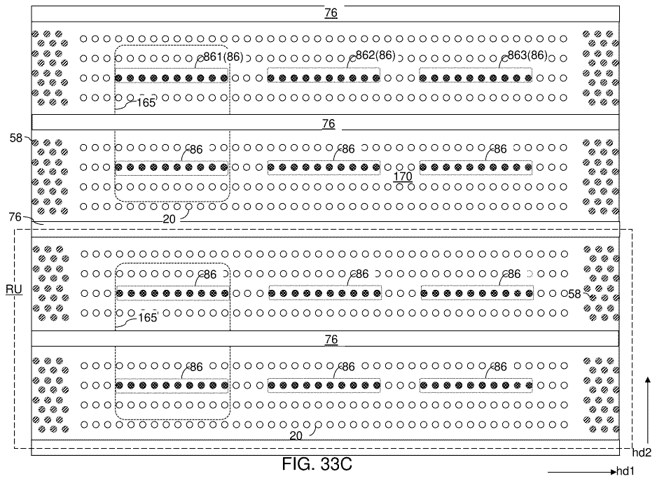

FIG. 33A is a top-down view of a sixth alternative configuration of the first exemplary structure after formation of a second-tier structure (232, 242) according to an embodiment of the present disclosure. FIG. 33B is a top-down view of the sixth alternative configuration of the first exemplary structure after formation of a third-tier structure (332, 342) according to an embodiment of the present disclosure. FIG. 33C is a first horizontal cross-sectional view of the sixth alternative configuration of the first exemplary structure along a horizontal plane including first insulating cap layers 170 after formation of various contact via structures (86, 88) according to an embodiment of the present disclosure. FIG. 33D is a second horizontal cross-sectional view of the sixth alternative configuration of the first exemplary structure along a horizontal plane including second insulating cap layers 270 after formation of various contact via structures (86, 88) according to an embodiment of the present disclosure. FIG. 33E is a top-down view of the sixth alternative configuration of the first exemplary structure after formation of various contact via structures (86, 88) according to an embodiment of the present disclosure.

In the sixth alternative configuration of the first exemplary structure, the lateral gaps LG in the dielectric wall structure 76 are located only over the retro-stepped dielectric material portion over the underlying tier. Thus, the lower portion of the dielectric wall structure 76 may extend continuously through the first tier in the inter-array region 200 from the first memory array region 100A to the second memory array region 100B without any lateral gaps therein. In a two tier structure, the upper portion of the dielectric wall structure 76 may include the lateral gaps (e.g. the second-tier lateral gaps T2LG) in the second tier in the inter-array region 200. The second-tier lateral gaps T2LG are located only over the first-tier retro-stepped dielectric material portion 165. Thus, in this embodiment, the second-tier staircase dielectric material sub-portion 265S is laterally offset from the first-tier retro-stepped dielectric material portion 165 along the first horizontal direction hd1, while the second-tier full-height dielectric material sub-portion 265F (e.g., the second-tier dielectric pillar structure 226) fills the second-tier lateral gaps T2LG and is located over the first-tier retro-stepped dielectric material portion 165.

In a three tier structure, the upper portion of the dielectric wall structure 76 may include the lateral gaps (e.g. the third-tier lateral gaps T3LG) in the third tier in the inter-array region 200. The third-tier lateral gaps T3LG are located only over the first and second-tier retro-stepped dielectric material portions (165, 265). Thus, in this embodiment, the third-tier staircase dielectric material sub-portion 365S is laterally offset from the first and second-tier retro-stepped dielectric material portions (165, 265) along the first horizontal direction hd1, while the third-tier full-height dielectric material sub-portion 365F (e.g., the third-tier dielectric pillar structure 326) fills the third-tier lateral gaps T3LG and is located over the first and second-tier retro-stepped dielectric material portions (165, 265).

The same configuration may be extended to a four or more tier structure. In general, the overlying tier lateral gaps LG are located only over the underlying tier retro-stepped dielectric material portions. Thus, the overlying tier staircase dielectric material sub-portion is laterally offset from the underlying tier retro-stepped dielectric material portions along the first horizontal direction hd1, while the overlying tier full-height dielectric material sub-portion fills the overlying tier lateral gaps and is located over the underlying tier retro-stepped dielectric material portions.

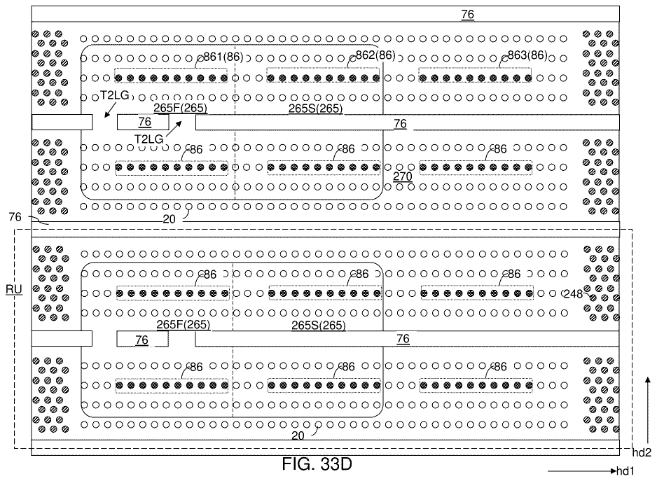

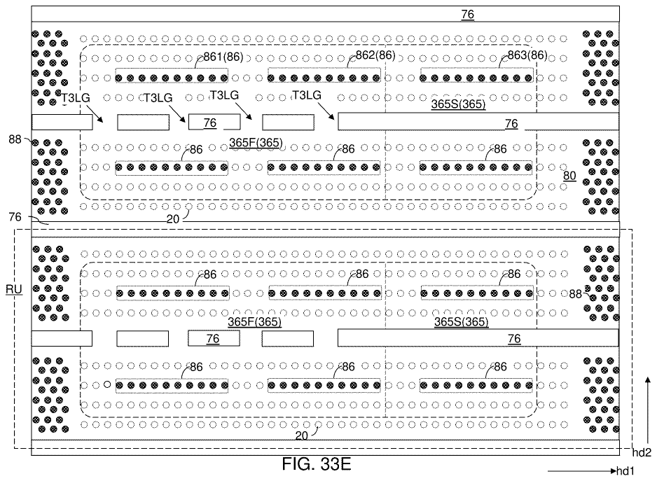

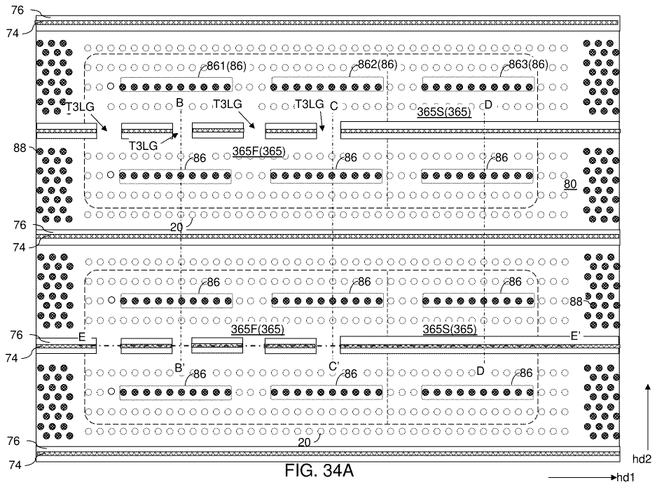

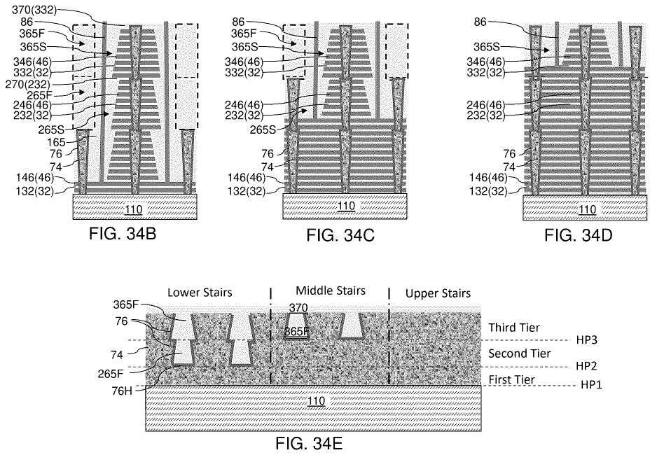

Referring to FIG. 34A-34E, the seventh alternative configuration of the first exemplary structure may be derived from the sixth alternative configuration by embedding an electrically conductive local interconnect 74 in the dielectric wall structure 76. The local interconnect 74 may contact the source region of the memory device which underlies the alternating stack (32, 46). The source region may comprise the semiconductor material layer 110 or another heavily doped semiconductor layer which is deposited on the bottom of the alternating stack (32, 46) and exposed bottom ends of the vertical semiconductor channels 60 after removing the substrate 8. In this embodiment, the dielectric wall structure 76 comprises a dielectric liner which surrounds the local interconnect 74 and which isolates the local interconnect 74 from the electrically conductive layers 46. The local interconnect 74 may comprise any suitable electrically conductive material, such as TiN barrier layer and tungsten fill layer embedded in the barrier layer.

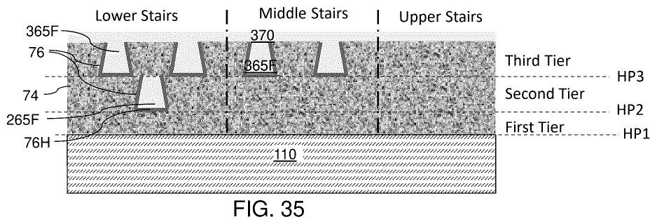

Referring to FIG. 35, in an alternative configuration, the second-tier full-height dielectric material sub-portion 265F may be laterally offset from the third-tier full-height dielectric material sub-portions 365F along the first horizontal direction hd1. Furthermore, there may be a different number of second-tier full-height dielectric material sub-portion 265F than the third-tier full-height dielectric material sub-portions 365F overlying the first retro-stepped dielectric material portion 165. For example, more third-tier full-height dielectric material sub-portions 365F (e.g., two portions 365F) than the second-tier full-height dielectric material sub-portions 265F (e.g., one portion 265F) overlie the first retro-stepped dielectric material portion 165. Thus, the number of third-tier lateral gaps (T3LG) may be different than the number of second-tier lateral gaps (T2LG) overlying the first retro-stepped dielectric material portion 165/

Referring collectively to FIGS. 1A-35, the first exemplary structure comprises a semiconductor structure which includes: multi-tier layer stacks {(132, 146), (232, 246), (323, 346)} laterally extending along a first horizontal direction hd1 and laterally spaced apart from each other along a second horizontal direction hd2 by lateral isolation structures (76, 165, 265, 365, 126, 226, 326), wherein each of the multi-tier layer stacks {(132, 146), (232, 246), (323, 346)} comprises a first-tier alternating stack (132, 146) of first insulating layers 132 and first electrically conductive layers 146, and further comprises a second-tier alternating stack (232, 246) of second insulating layers 232 and second electrically conductive layers 246 that overlies the first-tier alternating stack (132, 146), wherein the semiconductor structure comprises a first memory array region 100A and a second memory array region 100B that are laterally spaced apart from each other along the first horizontal direction hd1 by an inter-array region 200, wherein all layers within each of the multi-tier layer stacks {(132, 146), (232, 246), (323, 346)} are present in the first memory array region 100A and in the second memory array region 100B, and wherein each of the multi-tier layer stacks {(132, 146), (232, 246), (323, 346)} comprises a respective set of stepped surfaces in the inter-array region 200. The semiconductor structure further includes: memory openings 49 vertically extending through a respective one of the multi-tier layer stacks {(132, 146), (232, 246), (323, 346)} and located in a respective one of the first memory array region 100A and the second memory array region 100B; and memory opening fill structures 58 located in a respective one of the memory openings 49 and comprising a vertical semiconductor channel 60 and respective vertical stack of memory elements (e.g., portions of the memory film 50). A first lateral isolation structure (76, 165, 265, 365, 126, 226, 326) of the lateral isolation structures (76, 165, 265, 365, 126, 226, 326) comprises a combination of a dielectric wall structure 76 and at least one second-tier dielectric material portion (265F or 226); the dielectric wall structure 76 comprises at least one second-tier lateral gap T2LG at a second-tier level of the second-tier alternating stacks (232, 246); each of the at least one second-tier dielectric material portions (265F and/or 226) is located in a respective second-tier lateral gap T2LG of the at least one second-tier lateral gap T2LG; and the first lateral isolation structure (76, 165, 265, 365, 126, 226, 326) comprises a continuous dielectric barrier that extends continuously from the first memory array region 100A to the second memory array region 100B through the inter-array region 200.

In one embodiment, the at least one second-tier dielectric material portion (265F and/or 226) may have a greater width along the second horizontal direction hd2 than the dielectric wall structure 76. In one embodiment, the at least one second-tier dielectric material portion (265F and/or 226) may overlie a neighboring pair of first-tier alternating stacks (132, 146) within a neighboring pair of multi-tier layer stacks {(132, 146), (232, 246), (323, 346)}.

In one embodiment, the semiconductor structure may further comprise support pillar structures 20 vertically extending through a respective portion of the multi-tier layer stacks {(132, 146), (232, 246), (323, 346)}. In one embodiment, a first subset of the support pillar structures 20 may vertically extend through the at least one second-tier dielectric material portion (265F and/or 226) and a respective first-tier alternating stack (132, 146) within the neighboring pair of first-tier alternating stacks (132, 146).

In one embodiment, the semiconductor structure may further comprise: first-tier retro-stepped dielectric material portions 165 embedded within a respective one of the first-tier alternating stacks (132, 146); and first layer contact via structures 86 vertically extending through a respective one of the first-tier retro-stepped dielectric material portions 165 and contacting a respective one of the first electrically conductive layers 146 in the first-tier alternating stacks (132, 146).

In one embodiment, a first subset of the first layer contact via structures 86 may vertically extend through a respective second-tier dielectric material portion (265F and/or 226) of the at least one second-tier dielectric material portion (265F or 226). In one embodiment, a second subset of the first layer contact via structures 86 may vertically extend through a respective one of the second-tier alternating stacks (232, 246), and may be laterally spaced from each of the at least one second-tier dielectric material portions (265F or 226).

In the embodiments illustrated in FIG. 34A-35, the dielectric wall structure 76 comprises a dielectric liner embedding an electrically conductive source local interconnect 74.

In one embodiment shown in FIGS. 34E and 35, bottommost surfaces of the first-tier alternating stacks (132, 146) may be located in a first horizontal plane HP1; bottommost surfaces of the second-tier alternating stacks (232, 246) may be located in a second horizontal plane HP2; and the dielectric wall structure 76 may comprise at least one horizontal surface segment 76H located in the second horizontal plane HP2 and contacting each of the at least one second-tier dielectric material portion (265F or 226).

In one embodiment, top surfaces of the second-tier alternating stacks (232, 246) may be located in a third horizontal plane HP3; each of the at least one second-tier dielectric material portion (265F or 226) may have a respective top surface located in the third horizontal plane HP3. In one embodiment, second-tier portions of the dielectric wall structure 76 located between the second horizontal plane HP2 and a third horizontal plane HP3 including top surfaces of the second-tier alternating stacks (232, 246) may be laterally spaced apart from each other by the at least one second-tier lateral gap T2LG. In one embodiment, each of the at least one second-tier lateral gap T2LG may vertically extend from the second horizontal plane HP2 to the third horizontal plane HP3.

In one embodiment, each of the at least one second-tier dielectric material portion (265F or 226) may contact end segments of lengthwise sidewalls and an end sidewall of each second-tier portion within a respective laterally neighboring pair of the second-tier portions of the dielectric wall structure 76, the lengthwise sidewalls of each of the second-tier portions being parallel to the first horizontal direction hd1, and the end sidewalls of each of the second-tier portions being parallel to the second horizontal direction hd2. In some embodiments, the at least one second-tier dielectric material portion (265F or 226) may comprise a second-tier dielectric pillar structure 226. All sidewalls of the dielectric pillar structure 226 may vertically extend straight without any lateral step between a horizontal plane including bottommost surfaces of the second-tier alternating stacks (232, 246) and a horizontal plane including topmost surfaces of the second-tier alternating stacks (232, 246). In one embodiment, a width of a bottom of the second-tier dielectric pillar structure 226 along the second horizontal direction hd2 is wider than a width along the second horizontal direction hd2 of a bottom of the dielectric wall structure 76 in the second horizontal plane HP2 including bottommost surfaces of the second-tier alternating stacks (232, 246).

In one embodiment, each of the multi-tier layer stacks {(132, 146), (232, 246), (323, 346)} may also comprise a third-tier alternating stack (332, 346) of third insulating layers 332 and third electrically conductive layers 346 that overlies the second-tier alternating stack (232, 246); the dielectric wall structure 76 may comprise at least one third-tier lateral gap T3LG at a third-tier level of the third-tier alternating stacks (332, 346); the first lateral isolation structure (76, 165, 265, 365, 126, 226, 326) may further comprise at least one third-tier dielectric pillar structure 326 located in a respective third-tier lateral gap T3LG of the at least one third-tier lateral gap T3LG. In one embodiment, the at least one third-tier lateral gap T3LG may comprise a plurality of third-tier lateral gaps T3LG; and a total number of the plurality of third-tier lateral gaps T3LG may be greater than a total number of the at least one second-tier lateral gap T2LG.

In one embodiment, bottommost surfaces of the third-tier alternating stacks (332, 346) may be located in a third horizontal plane HP3; and the dielectric wall structure 76 may contact the at least one third-tier dielectric pillar structure 326 within the third horizontal plane HP3. In one embodiment, at least one third-tier dielectric pillar structure 326 may comprise a plurality of third-tier dielectric pillar structures 326; a first subset of the plurality of third-tier dielectric pillar structures 326 may contact a respective one of the at least one second-tier dielectric pillar structure 226; and a second subset of the plurality of third-tier dielectric pillar structures 326 may comprise a respective bottom surface that does not contact any of the at least one second-tier dielectric pillar structure 226.

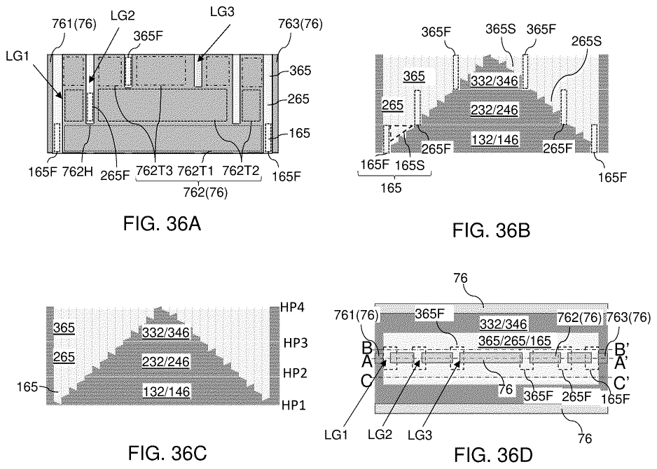

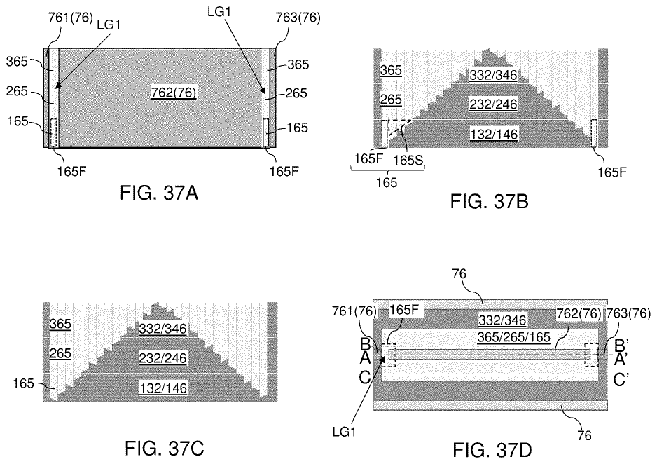

According to a second embodiment of the present disclosure, a second exemplary structure is provided. Various configurations of the second exemplary structure are illustrated in FIGS. 36A-37D.

The second embodiment differs from the first embodiment in that the dielectric wall structure 76 in the first tier also includes the first lateral gaps (LG1). The lateral gaps in the first tier may be filled with the dielectric pillar structures or first-tier full-height dielectric material sub-portions. For example, FIG. 36A-36B illustrate that the first lateral gaps are filled with first-tier full-height dielectric material sub-portion 165F of the first-tier retro-stepped dielectric material portion 165. Thus, in the second exemplary structure, each first-tier retro-stepped dielectric material portion 165 may include a first-tier staircase dielectric material sub-portion 165S and a first-tier full-height dielectric material sub-portion 165F. The first-tier staircase dielectric material sub-portions 165S may have a first stepped bottom surface and first variable verticals extent that are less than a first height of the first-tier alternating stacks. The first-tier full-height dielectric material sub-portion 165F may have a same height as the first height of the first-tier alternating stacks (132, 146). The first lateral gap LG1 may vertically extend through overlying tier structures, such as the second-tier structure and the third-tier structure. The first lateral gap LG1 may be filled with respective combination of first, second and third-tier full-height dielectric material sub-portions (165F, 265F, 365F).

The dielectric material of the first-tier full-height dielectric material sub-portion 165F within the first lateral gap LG1 may be used to increase structural support during replacement of the sacrificial material layers 42 with the electrically conductive layers 46. In this case, combinations of a respective set of two first-tier lateral isolation trenches 79 and a respective first-tier retro-stepped dielectric material portion 165 may be used to divide a first-tier vertically alternating sequence into multiple first-tier alternating stacks (132, 242) during the manufacture process. The entire bottom surface of each first-tier full-height dielectric material sub-portion 165F may be located in the first horizontal plane HP1, and the entire top surface of each first-tier retro-stepped dielectric material portion 165 may be located in the second horizontal plane HP2.

In the second exemplary structure, each second-tier retro-stepped dielectric material portion 265 may include a second-tier staircase dielectric material sub-portion 265S and a second-tier full-height dielectric material sub-portion 265F, as described above. In the second exemplary structure, each third-tier retro-stepped dielectric material portion 365 may include a third-tier staircase dielectric material sub-portion 365S and a third-tier full-height dielectric material sub-portion 365F, as described above. The second lateral gap LG2 may vertically extend through the second and third tiers and be filled with a respective pair of second and third-tier full-height dielectric material sub-portions (265F, 365F).

Upon formation of dielectric wall structures 76, each laterally neighboring pair of multi-tier layer stacks {(132, 146), (232, 2346), (332, 346)} is laterally spaced from each other by a respective lateral isolation structure (761, 762, 165, 265, 365) that includes a first dielectric wall structure 761, a second dielectric wall structure 762, a first-tier retro-stepped dielectric material portion 165, a second-tier retro-stepped dielectric material portion 265, and a third-tier retro-stepped dielectric material portion 365. The second dielectric wall structure 762 may be laterally spaced from the first dielectric wall structure 761 by a set of dielectric material portions that continuously extends from the first horizontal plane HP1 containing the bottom surfaces of the first-tier alternating stacks (132, 146) to the fourth horizontal plane HP4 containing the top surfaces of the third-tier alternating stacks (332, 346). The set of dielectric material portions that continuously extends from the first horizontal plane HP1 to the fourth horizontal plane HP4 through the first lateral gap LG1 include the first-tier full-height dielectric material sub-portion 165F, the second-tier full-height dielectric material sub-portion 265F, and the third-tier full-height dielectric material sub-portion 365F.

For each pair of dielectric wall structures 76 contacting a vertical stack of a first-tier retro-stepped dielectric material portion 165, a second-tier retro-stepped dielectric material portion 265, and a third-tier retro-stepped dielectric material portion 365, one of the dielectric wall structures 76 is referred to as a first dielectric wall structure 761 and another of the dielectric wall structures 76 is referred to as a second dielectric wall structure 762. The second exemplary structure comprises lateral isolation structures (761, 762, 165, 265, 365), each including a first dielectric wall structure 761, a second dielectric wall structure 762, a first-tier retro-stepped dielectric material portion 165, a second-tier retro-stepped dielectric material portion 265, and a third-tier retro-stepped dielectric material portion 365. The second dielectric wall structure 762 is laterally spaced from the first dielectric wall structure 761 by a first lateral gap LG1. The first-tier full-height dielectric material sub-portion 165F fills an entire volume of the first lateral gap LG1 in the first tier. The first lateral gap LG1 vertically extends at least from the first horizontal plane HP1 and at least to the second horizontal plane HP2, and may vertically extend to the third horizontal plane HP3 including topmost surfaces of the second-tier alternating stacks (232, 246), and may further extend to the fourth horizontal plane HP4 including the topmost surfaces of the third-tier alternating stacks (332, 346).

In one embodiment, a second lateral gap LG2 may be provided within the second-tier structure. The second lateral gap LG2 may be laterally offset from the first lateral gap LG1 along the first horizontal direction hd1, and may overlie a first-tier portion 762T1 of the second dielectric wall structure 762 located within the first-tier structure, as shown in FIG. 36A. In this case, the second dielectric wall structure 762 may comprise plural (e.g., three) second-tier dielectric wall portions 762T2 located above the second horizontal plane HP2 and laterally spaced apart from each other by the respective second lateral gap LG2. In one embodiment, the second-tier full-height dielectric material sub-portion 265F may fill an entire volume of the second lateral gap LG2 in the second tier.

In one embodiment, the second dielectric wall structure 762 may comprise plural third-tier dielectric wall portions 762T3 and at least one additional lateral gap (such as the third lateral gap LG3) that vertically extends from the third horizontal plane HP3 to a fourth horizontal plane including topmost surfaces of the third-tier alternating stacks (332, 346). In this case, the third-tier full-height dielectric material sub-portion 365F may fill an entire volume of the additional lateral gap (such as the third lateral gap LG3) in the third tier.

The first exemplary structure staircases in the inter-tier region 200 were illustrated as generally ascending in which the majority of the heights of the horizontal step surface increase stepwise along the first horizontal direction hd1. However, alternative embodiments are expressly contemplated in which the stepped surface of an alternating stack of insulating layers 32 and electrically conductive layers 46 within any tier structure is generally stepwise decreasing along the first horizontal direction hd1, or includes any mixture of generally stepwise-increasing portions and stepwise-decreasing portions. FIG. 36B-36C illustrate a configuration in which stepped surfaces of each stepped surface of alternating stacks (32, 46) include combinations of generally stepwise-increasing segments and generally stepwise decreasing segments.

Further, each lateral isolation structure (761, 762, 763, 165, 265, 365) may include three or more dielectric wall structures (761, 762, 763), two or more first-tier retro-stepped dielectric material portions 165, two or more second-tier dielectric material portions 265, and/or two or more third-tier retro-stepped dielectric material portions 365. FIGS. 36A-36D illustrate a configuration in which a lateral isolation structure (761, 762, 763, 165, 265, 365) may comprise a third dielectric wall structure 763 that is laterally spaced from the second dielectric wall structure 762 by an additional lateral gap (such as the first lateral gap LG1).

While an embodiment is illustrated in which three tier structures are employed, embodiments of the present disclosure may be practiced with two tier structures, or four or more tier structures. Such variations are expressly contemplated herein.

FIG. 37A is a first vertical cross-sectional view of the alternative configuration of the second exemplary structure according to an embodiment of the present disclosure. FIG. 37B is a second vertical cross-sectional view of the alternative configuration of the second exemplary structure according to an embodiment of the present disclosure. FIG. 37C is a third vertical cross-sectional view of the alternative configuration of the second exemplary structure according to an embodiment of the present disclosure. FIG. 37D is a top-down view of the second configuration of the second exemplary structure. The vertical plane A-A′ is the cut plane of the first vertical cross-sectional view of FIG. 37A. The vertical plane B-B′ is the cut plane of the second vertical cross-sectional view of FIG. 37B. The vertical plane C-C′ is the cut plane of the third vertical cross-sectional view of FIG. 37C.

Generally, the second and/or third lateral gaps at the second-tier level and/or at the third-tier level that do not overlap with lateral gaps at the first-tier level are optional, and thus, may be omitted. FIGS. 37A-37D illustrate a configuration in which two first lateral gaps LG1 vertically extend through the entire height of a multi-tier layer stack {(132, 146), (232, 246), (323, 346)}.

Referring collectively to FIGS. 36A-37D and related drawings within FIG. 1A-34E and according to second embodiment of the present disclosure, a semiconductor structure comprises: multi-tier layer stacks {(132, 146), (232, 246), (323, 346)} laterally extending along a first horizontal direction hd1 and laterally spaced apart from each other along a second horizontal direction hd2 by lateral isolation structures (76, 165, 265, 365), wherein each of the multi-tier layer stacks {(132, 146), (232, 246), (323, 346)} comprises a first-tier alternating stack (132, 146) of first insulating layers 132 and first electrically conductive layers 146, and further comprises a second-tier alternating stack (232, 246) of second insulating layers 232 and second electrically conductive layers 246 that overlies the first-tier alternating stack (132, 146). The semiconductor structure comprises a first memory array region 100A and a second memory array region 100B that are laterally spaced apart from each other along the first horizontal direction hd1 by an inter-array region 200, wherein all layers within each of the multi-tier layer stacks {(132, 146), (232, 246), (323, 346)} are present in the first memory array region 100A and in the second memory array region 100B, and wherein each of the multi-tier layer stacks {(132, 146), (232, 246), (323, 346)} comprises a respective set of stepped surfaces in the inter-array region 200. The semiconductor structure further comprises: memory openings 49 vertically extending through a respective one of the multi-tier layer stacks {(132, 146), (232, 246), (323, 346)} and located in a respective one of the first memory array region 100A and the second memory array region 100B; and memory opening fill structures 58 located in a respective one of the memory openings 49 and comprising a vertical semiconductor channel 60 and respective vertical stack of memory elements (e.g., portions of the memory film 50). A first lateral isolation structure of the lateral isolation structures (76 (e.g., 761, 762), 165, 265, 365) comprises a combination of a first dielectric wall structure 761, a second dielectric wall structure 762 that is laterally spaced from the first dielectric wall structure 761 by a first lateral gap LG1, a first-tier retro-stepped dielectric material portion 165 located at a first-tier level of the first-tier alternating stacks (132, 146) within the multi-tier layer stacks {(132, 146), (232, 246), (323, 346)}, and a second-tier retro-stepped dielectric material portion 265 located at a second-tier level of the second-tier alternating stacks (232, 246) within the multi-tier layer stacks {(132, 146), (232, 246), (323, 346)}; the first-tier retro-stepped dielectric material portion 165 comprises a first-tier staircase dielectric material sub-portion 165S having a first stepped bottom surface and having first variable vertical extents that are less than a first height of the first-tier alternating stacks (132, 146) and further comprises a first-tier full-height dielectric material sub-portion 165F having a same height as the first height of the first-tier alternating stacks (132, 146) and filling an entire volume of the first lateral gap LG1; and the first lateral isolation structure (76, 165, 265, 365) comprises continuous dielectric barrier that extends continuously from the first memory array region 100A to the second memory array region 100B through the inter-array region 200.

In one embodiment, the semiconductor structure further comprises a first-tier full-height dielectric material sub-portion 165F that has a greater width along the second horizontal direction hd2 than the first dielectric wall structure 761 and the second dielectric wall structure 762. In one embodiment, the semiconductor structure further comprises bottommost surfaces of the first-tier alternating stacks (132, 146) located in a first horizontal plane HP1, and bottommost surfaces of the second-tier alternating stacks (232, 246) located in a second horizontal plane HP2. As shown in FIG. 36A, the second dielectric wall structure 762 may comprise a horizontal surface segment 762H located in the second horizontal plane HP2 and contacting a bottom surface segment of the second-tier retro-stepped dielectric material portion 265.

In one embodiment, the first lateral gap LG1 vertically extends at least from the first horizontal plane HP1 to at least a third horizontal plane HP3 including topmost surfaces of the second-tier alternating stacks (232, 246). In one embodiment, the second-tier retro-stepped dielectric material portion 265 includes a second-tier staircase dielectric material sub-portion 265S having a second stepped bottom surface and second variable vertical extents that are less than a second height of the second-tier alternating stacks (232, 246). The second-tier retro-stepped dielectric material portion 265 may further comprise a second-tier full-height dielectric material sub-portion 265F having a same height as the second height of the second-tier alternating stacks (232, 246). The bottom surface segment of the second-tier retro-stepped dielectric material portion 265 may comprise a bottom surface segment of the second-tier full-height dielectric material sub-portion 265F.

In one embodiment shown in FIG. 36A, the second dielectric wall structure 762 comprises a first-tier dielectric wall portion 762T1 located below the second horizontal plane HP2 and two second-tier dielectric wall portions 762T2 located above the second horizontal plane HP2 and laterally spaced apart from each other by a second lateral gap LG2. The second-tier full-height dielectric material sub-portion 265F may fill an entire volume of the second lateral gap LG2. In one embodiment, a first one of the two second-tier dielectric wall portions 762T2 is laterally surrounded by the second-tier full-height dielectric material sub-portion 265F.

In one embodiment, the semiconductor structure further comprises a third-tier alternating stack (332, 346) of third insulating layers 332 and third electrically conductive layers 346 that overlies the second-tier alternating stack (232, 246) in each of the multi-tier layer stacks {(132, 146), (232, 246), (323, 346)}. The first lateral isolation structure (76, 165, 265, 365, 126, 226, 326) (76, 165, 265, 365) may comprise a third-tier retro-stepped dielectric material portion 365 located at a third-tier level of the third-tier alternating stacks (332, 346) within the multi-tier layer stacks {(132, 146), (232, 246), (323, 346)}. The third-tier retro-stepped dielectric material portion 365 may comprise a third-tier staircase dielectric material sub-portion 365S having a third stepped bottom surface and third variable vertical extents that are less than a third height of the third-tier alternating stacks (332, 346), and may further comprise a third-tier full-height dielectric material sub-portion 365F having a same height as the third height of the third-tier alternating stacks (332, 346).

In one embodiment, bottommost surfaces of the third-tier alternating stacks (332, 346) are located in a third horizontal plane HP3, and the second dielectric wall structure 762 comprises a horizontal surface segment located in the third horizontal plane HP3 and contacting a bottom surface segment of the third-tier retro-stepped dielectric material portion 365. In one embodiment, the second dielectric wall structure 762 comprises an additional lateral gap (such as the third lateral gap LG3) that vertically extends from the third horizontal plane HP3 to a fourth horizontal plane including topmost surfaces of the third-tier alternating stacks (332, 346). The third-tier full-height dielectric material sub-portion 365F may fill an entire volume of the additional lateral gap (such as the third lateral gap LG3).

In one embodiment, the second-tier retro-stepped dielectric material portion 265 comprises a second-tier staircase dielectric material sub-portion 265S having a second stepped bottom surface and second variable vertical extents that are less than a second height of the second-tier alternating stacks (232, 246), and further comprises a second-tier full-height dielectric material sub-portion 265F having a same height as the second height of the second-tier alternating stacks (232, 246). The bottom surface segment of the second-tier retro-stepped dielectric material portion 265 may comprise a bottom surface segment of the second-tier full-height dielectric material sub-portion 265F.

In one embodiment, the second dielectric wall structure 762 comprises a first-tier dielectric wall portion 762T1 located below the second horizontal plane HP2 and two second-tier dielectric wall portions 762T2 located above the second horizontal plane HP2 and laterally spaced apart from each other by a second lateral gap LG2.

In one embodiment illustrated in FIG. 34A-35, the dielectric wall structure 76 comprises a dielectric liner embedding an electrically conductive source local interconnect 74. In other embodiments, the dielectric wall structure 76 consists essentially of a dielectric material, such as silicon oxide.

In one embodiment, the second dielectric wall structure 762 is located entirely within the inter-array region 200, and the first lateral isolation structure (76, 165, 265, 365) comprises a third dielectric wall structure 763 that is laterally spaced from the second dielectric wall structure 762 by an additional lateral gap (another first lateral gap LG1) and laterally extends through an entire extent of one of the second memory array region 100B along the first horizontal direction hd1. The first dielectric wall structure 761 laterally extends through the first memory region 100A along the first horizontal direction hd1, and is located entirely outside of the second memory array region 100B.

In one embodiment shown in FIG. 36D, a width of the first-tier full-height dielectric material sub-portion 165F along the second horizontal direction hd2 is less than a width of the first-tier staircase dielectric material sub-portion 165S along the second horizontal direction hd2. In one embodiment, the semiconductor structure further comprises layer contact via structures 86 vertically extending through the first-tier retro-stepped dielectric material portion 165 and contacting a respective first electrically conductive layer 146 within the first-tier alternating stacks (132, 146).

In one embodiment, the first-tier full-height dielectric material sub-portion 165F contacts end segments of lengthwise sidewalls of the first dielectric wall structure 761, end segments of lengthwise sidewalls of the second dielectric wall structure 762, an end wall of the first dielectric wall structure 761, and an end wall of the second dielectric wall structure 762. The lengthwise sidewalls of the first dielectric wall structure 761 and the lengthwise sidewalls of the second dielectric wall structure 762 may be parallel to the first horizontal direction hd1, and the end wall of the first dielectric wall structure 761 and the end wall of the second dielectric wall structure 762 may be parallel to the second horizontal direction hd2.

Embodiments of the present disclosure may provide improved structural integrity in multi-tier memory devices. The lateral isolation structures (e.g., the dielectric pillar structures (226, 326) or full-height dielectric material sub-portions (165F, 265F, 365F) may enhance mechanical stability during replacement of the sacrificial material layers 42 with electrically conductive layers 46 by reducing or eliminating tilting of the alternating stacks (32, 46) into the lateral isolation trenches 79. The method of forming sacrificial wall structures (178, 278) and subsequently replacing them with dielectric wall structures (76, 761, 762) may allow for easier integration of the lateral isolation structures (76, 165, 265, 365, 126, 226, 326) without significantly altering the overall fabrication process flow or adding a large number of process steps.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph or in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A semiconductor structure, comprising:
multi-tier layer stacks laterally extending along a first horizontal direction and laterally spaced apart from each other along a second horizontal direction by lateral isolation structures, wherein each of the multi-tier layer stacks comprises a first-tier alternating stack of first insulating layers and first electrically conductive layers, and further comprises a second-tier alternating stack of second insulating layers and second electrically conductive layers that overlies the first-tier alternating stack, wherein the semiconductor structure comprises a first memory array region and a second memory array region that are laterally spaced apart from each other along the first horizontal direction by an inter-array region, wherein all layers within each of the multi-tier alternating stacks are present in the first memory array region and in the second memory array region, and wherein each of the multi-tier alternating stacks comprises a respective set of stepped surfaces in the inter-array region;
memory openings vertically extending through a respective one of the multi-tier layer stacks and located in a respective one of the first memory array region and the second memory array region; and
memory opening fill structures located in a respective one of the memory openings and comprising a vertical semiconductor channel and respective vertical stack of memory elements,
wherein:
a first lateral isolation structure of the lateral isolation structures comprises a combination of a dielectric wall structure and at least one second-tier dielectric material portion;
the dielectric wall structure comprises at least one second-tier lateral gap at a second-tier level of the second-tier alternating stacks;
each of the at least one second-tier dielectric material portions is located in a respective second-tier lateral gap of the at least one second-tier lateral gaps; and
the first lateral isolation structure comprises a continuous dielectric barrier that extends continuously from the first memory array region to the second memory array region through the inter-array region.

2. The semiconductor structure of claim 1, wherein the at least one second-tier dielectric material portion has a greater width along the second horizontal direction than the dielectric wall structure.

3. The semiconductor structure of claim 1, wherein the at least one second-tier dielectric material portion overlies a neighboring pair of first-tier alternating stacks within a neighboring pair of multi-tier layer stacks.

4. The semiconductor structure of claim 3, further comprising support pillar structures vertically extending through a respective portion of the multi-tier layer stacks, wherein a first subset of the support pillar structures vertically extends through the at least one second-tier dielectric material portion and a respective first-tier alternating stack within the neighboring pair of first-tier alternating stacks.

5. The semiconductor structure of claim 1, further comprising:
first-tier retro-stepped dielectric material portions embedded within a respective one of the first-tier alternating stacks; and
first layer contact via structures vertically extend through a respective one of the first-tier retro-stepped dielectric material portions and contacting a respective one of the first electrically conductive layers in the first-tier alternating stacks.

6. The semiconductor structure of claim 5, wherein:
a first subset of the first layer contact via structures vertically extends through a respective second-tier dielectric material portion of the at least one second-tier material portion; and
a second subset of the first layer contact via structures vertically extends through a respective one of the second-tier alternating stacks, and is laterally spaced from each of the at least one second-tier dielectric material portions.

7. The semiconductor structure of claim 1, wherein the dielectric wall structure comprises a dielectric liner embedding an electrically conductive source local interconnect.

8. The semiconductor structure of claim 1, wherein:
bottommost surfaces of the first-tier alternating stacks are located in a first horizontal plane;
bottommost surfaces of the second-tier alternating stacks are located in a second horizontal plane; and
the dielectric wall structure comprises at least one horizontal surface segment located in the second horizontal plane and contacting each of the at least one second-tier dielectric material portions.

9. The semiconductor structure of claim 8, wherein:
top surfaces of the second-tier alternating stacks are located in a third horizontal plane; and
each of the at least one second-tier dielectric material portion has a respective top surface located in the third horizontal plane.

10. The semiconductor structure of claim 8, wherein second-tier portions of the dielectric wall structure located between the second horizontal plane and a third horizontal plane including top surfaces of the second-tier alternating stacks are laterally spaced apart from each other by the at least one second-tier lateral gap.

11. The semiconductor structure of claim 10, wherein each of the at least one second-tier lateral gap vertically extends from the second horizontal plane to the third horizontal plane.

12. The semiconductor structure of claim 10, wherein each of the at least one second-tier dielectric material portion contacts end segments of lengthwise sidewalls and an end sidewall of each second-tier portion within a respective laterally neighboring pair of the second-tier portions of the dielectric wall structure, the lengthwise sidewalls of each of the second-tier portions being parallel to the first horizontal direction, and the end sidewalls of each of the second-tier portions being parallel to the second horizontal direction.

13. The semiconductor structure of claim 1, wherein the at least one second-tier dielectric material portion comprises a second-tier dielectric pillar structure.

14. The semiconductor structure of claim 13, wherein:
all sidewalls of the second-tier dielectric pillar structure vertically extend straight without any lateral step between a horizontal plane including bottommost surfaces of the second-tier alternating stacks and a horizontal plane including topmost surfaces of the second-tier alternating stacks; and
a width of a bottom of the second-tier dielectric pillar structure along the second horizontal direction is wider than a width along the second horizontal direction of a bottom of the dielectric wall structure in the horizontal plane including bottommost surfaces of the second-tier alternating stacks.

15. The semiconductor structure of claim 13, wherein:
each of the multi-tier layer stacks further comprises a third-tier alternating stack of third insulating layers and third electrically conductive layers that overlies the second-tier alternating stack;
the dielectric wall structure comprises at least one third-tier lateral gap at a third-tier level of the third-tier alternating stacks; and
the first lateral isolation structure further comprises at least one third-tier dielectric pillar structure located in a respective third-tier lateral gap of the at least one third-tier lateral gap.

16. The semiconductor structure of claim 15, wherein:
the at least one third-tier lateral gap comprises a plurality of third-tier lateral gaps; and
a total number of the plurality of third-tier lateral gaps is greater than a total number of the at least one second-tier lateral gap.

17. The semiconductor structure of claim 16, wherein:
bottommost surfaces of the third-tier alternating stacks are located in a third horizontal plane; and
the dielectric wall structure contacts the at least one third-tier dielectric pillar structure within the third horizontal plane.

18. A method of forming a semiconductor structure, comprising:
forming a first-tier structure comprising first-tier alternating stacks of first insulating layers and first sacrificial material layers, wherein the first-tier alternating stacks laterally extend along a first horizontal direction and are laterally spaced apart from each other by sacrificial first-tier wall structures;
forming a second-tier structure comprising second-tier alternating stacks of second insulating layers and second sacrificial material layers over the first-tier structure, wherein the second-tier alternating stacks laterally extend along the first horizontal direction and are laterally spaced apart from each other by a plurality of sacrificial second-tier wall structures comprising at least one second-tier lateral gap therebetween and at least one second-tier dielectric pillar structure located within a respective one of the at least one second-tier lateral gap;
forming memory openings in a first memory array region and in a second memory array region at least through a respective vertical stack of a respective one of the first-tier alternating stacks and through a respective one of the second-tier alternating stacks;
forming memory opening fill structures in the memory openings, wherein each of the memory opening fill structures comprises a vertical semiconductor channel and a vertical stack of memory elements;
forming lateral isolation trenches by removing at least the plurality of sacrificial second-tier wall structures and the sacrificial first-tier wall structure; and
replacing remaining portions of the first sacrificial material layers and remaining portions of the second sacrificial material layers with first electrically conductive layers and second electrically conductive layers, respectively.

19. The method of claim 18, further comprising filling the lateral isolation trenches with at least one dielectric fill material to form a first dielectric wall structure which fills volumes previously occupied by the first sacrificial first-tier wall structure and the plurality of sacrificial second-tier wall structures as a single continuous structure.

20. The method of claim 19, wherein:
bottom surfaces of the first-tier alternating stacks are formed within a first horizontal plane;
bottom surfaces of the second-tier alternating stacks are formed within a second horizontal plane;
top surfaces of the second-tier alternating stacks are formed within a third horizontal plane;
an entire bottom surface of each of the at least one second-tier dielectric pillar structure is formed within the second horizontal plane; and
an entire top surface of each of the at least one second-tier dielectric pillar structure is formed within the third horizontal plane.
